(19) United States
(12) Patent Application Publication
(10) Pub. No.: US 2026/0271270 A1
(43) Pub. Date: Sep. 10, 2026

(54) SEMICONDUCTOR DEVICE AND METHOD FOR MANUFACTURING THE SEMICONDUCTOR DEVICE

(71) Applicant: Semiconductor Energy Laboratory Co., Ltd., Atsugi-shi, Kanagawa-ken (JP)

(72) Inventors: Hideomi SUZAWA, Atsugi (JP); Akihiro KIKUCHI, Isehara (JP)

(21) Appl. No.: 19/164,713

(22) PCT Filed: Mar. 25, 2024
(86) PCT No.: PCT/IB2024/052826

§ 371 Date: Sep. 12, 2025

(30) Foreign Application Priority Data
Mar. 31, 2023 (JP) 2023-057530
Jan. 19, 2024 (JP) 2024-006506

(51) Int. Cl. H10B 12/00

(52) U.S. Cl. CPC H10B 12/33; H10B 12/05

(57) ABSTRACT

A transistor with low parasitic capacitance is provided. A semiconductor device with favorable electrical characteristics is provided. The semiconductor device includes a transistor whose source electrode and drain electrode are positioned at different levels and an insulating layer provided between the source electrode and the drain electrode; the insulating layer includes a first opening reaching one of the source electrode and the drain electrode; the other of the source electrode and the drain electrode is provided over the insulating layer and includes a second opening overlapping with the first opening; a semiconductor layer includes a region provided in the first opening; a gate insulating layer and a gate electrode are provided in this order over the semiconductor layer; the gate electrode has a two-layer structure; the end portion of the lower layer of the gate electrode overlaps with the other of the source electrode and the drain electrode; the upper layer of the gate electrode includes a first region extending outward from the end portion of the lower layer; and a gap is provided between the first region and the other of the source electrode and the drain electrode.

### TECHNICAL FIELD

One embodiment of the present invention relates to a semiconductor device, a memory device, a display device, and an electronic appliance. One embodiment of the present invention also relates to a method for manufacturing the semiconductor device.

Note that one embodiment of the present invention is not limited to the above technical field. Examples of the technical field of one embodiment of the present invention include a semiconductor device, a display device, a light-emitting apparatus, a power storage device, a memory device, an electronic appliance, a lighting device, an input device (e.g., a touch sensor), an input/output device (e.g., a touch panel), driving methods thereof, and manufacturing methods thereof.

In this specification and the like, a semiconductor device means a device that utilizes semiconductor characteristics, and refers to a circuit including a semiconductor element (e.g., a transistor, a diode, or a photodiode), a device including the circuit, and the like. The semiconductor device also means devices that can function by utilizing semiconductor characteristics. For example, an integrated circuit, a chip including an integrated circuit, and an electronic component including a chip in a package are examples of the semiconductor device. In some cases, a memory device, a display device, a light-emitting apparatus, a lighting device, and an electronic appliance themselves are semiconductor devices and also include a semiconductor device.

### BACKGROUND ART

In recent years, semiconductor devices have been developed, and LSIs, CPUs, memories, and the like are mainly used as the semiconductor devices. A CPU is an aggregation of semiconductor elements; the CPU includes a semiconductor integrated circuit (including at least a transistor and a memory) formed into a chip by processing a semiconductor wafer, and is provided with an electrode that is a connection terminal.

A semiconductor circuit (IC chip) of an LSI, a CPU, a memory, or the like is mounted on a circuit board, for example, a printed wiring board, to be used as one of components of a variety of electronic appliances.

A technique by which a transistor is formed using a semiconductor thin film formed over a substrate having an insulating surface has been attracting attention. The transistor is used in a wide range of electronic devices such as an integrated circuit (IC) and a display device. A silicon-based semiconductor material is widely known as a semiconductor thin film that can be used in a transistor. As another material, an oxide semiconductor has been attracting attention.

A transistor including an oxide semiconductor is known to have an extremely low leakage current in an off state. For example, Patent Document 1 discloses a low-power CPU utilizing a characteristic of a low leakage current of the transistor including an oxide semiconductor. Furthermore, for example, Patent Document 2 discloses a memory device that can retain stored data for a long time by utilizing a characteristic of a low leakage current of the transistor including an oxide semiconductor.

In recent years, demand for an integrated circuit with higher density has risen with reductions in size and weight of electronic appliances. In addition, the productivity of a semiconductor device including an integrated circuit is desired to be improved. For example, Patent Document 3 and Non-Patent Document 1 disclose a technique for achieving an integrated circuit with higher density by making a plurality of memory cells overlap with each other by stacking a first transistor including an oxide semiconductor film and a second transistor including an oxide semiconductor film. Patent Document 4 discloses a technique for achieving an integrated circuit with higher density by forming a channel of a transistor including an oxide semiconductor film in the vertical direction.

### REFERENCES

### Patent Documents

[Patent Document 1] Japanese Published Patent Application No. 2012-257187
[Patent Document 2] Japanese Published Patent Application No. 2011-151383
[Patent Document 3] PCT International Publication No. 2021/053473
[Patent Document 4] Japanese Published Patent Application No. 2013-211537

### Non-Patent Document

[Non-Patent Document 1] M. Oota, et. al, “3D-Stacked CAAC—In—Ga—Zn Oxide FETs with Gate Length of 72 nm”, IEDM Tech. Dig., 2019, pp. 50-53

### SUMMARY OF THE INVENTION

### Problems to be Solved by the Invention

An object of one embodiment of the present invention is to provide a transistor with low parasitic capacitance. Another object of one embodiment of the present invention is to provide a transistor with favorable electrical characteristics. Another object of one embodiment of the present invention is to provide a transistor with a high on-state current. Another object of one embodiment of the present invention is to provide a transistor, a semiconductor device, or a memory device that can be miniaturized or highly integrated. Another object of one embodiment of the present invention is to provide a display device with a high resolution or a high aperture ratio. Another object of one embodiment of the present invention is to provide a highly reliable transistor, a highly reliable semiconductor device, a highly reliable display device, or a highly reliable memory device. Another object of one embodiment of the present invention is to provide a semiconductor device with low power consumption, a display device with low power consumption, or a memory device with low power consumption. Another object of one embodiment of the present invention is to provide a memory device with high operation speed.

Another object of one embodiment of the present invention is to provide a method for manufacturing the above-described transistor, semiconductor device, display device, or memory device.

Note that the description of these objects does not preclude the existence of other objects. One embodiment of the present invention does not necessarily achieve all of these objects. Other objects can be derived from the description of the specification, the drawings, and the claims.

### Means for Solving the Problems

One embodiment of the present invention is a semiconductor device which includes a first transistor and a first insulating layer and in which the first transistor includes a first conductive layer, a second conductive layer, a semiconductor layer, a gate insulating layer, and a gate electrode; the first conductive layer is one of a source electrode and a drain electrode of the first transistor and the second conductive layer is the other of the source electrode and the drain electrode of the first transistor; the first conductive layer and the second conductive layer are positioned at different levels; the first insulating layer is provided between the first conductive layer and the second conductive layer and includes a first opening reaching the first conductive layer; the second conductive layer includes a second opening overlapping with the first opening; the second conductive layer is provided over the first insulating layer; the semiconductor layer includes a region in contact with a top surface of the first conductive layer in the first opening, a region in contact with a side surface of the first insulating layer in the first opening, a region in contact with a side surface of the second conductive layer in the second opening, and a region in contact with a top surface of the second conductive layer; the gate insulating layer is provided over and in contact with the semiconductor layer; the gate electrode is provided over the gate insulating layer to include a region overlapping with the semiconductor layer; the gate electrode includes a third conductive layer and a fourth conductive layer stacked over the third conductive layer; an end portion of the third conductive layer is positioned in a region overlapping with the second conductive layer; the fourth conductive layer includes a region extending outward from the end portion of the third conductive layer; and in the region extending outward from the end portion of the third conductive layer, the fourth conductive layer includes a gap between the region and the second conductive layer.

In the above structure, a relative permittivity of the gap is preferably higher than or equal to 0.8 and lower than or equal to 1.2.

Another embodiment of the present invention is a semiconductor device which includes a first transistor, a first insulating layer, and a second insulating layer and in which the first transistor includes a first conductive layer, a second conductive layer, a semiconductor layer, a gate insulating layer, and a gate electrode; the first conductive layer is one of a source electrode and a drain electrode of the first transistor and the second conductive layer is the other of the source electrode and the drain electrode of the first transistor; the first conductive layer and the second conductive layer are positioned at different levels; the first insulating layer is provided between the first conductive layer and the second conductive layer and includes a first opening reaching the first conductive layer; the second conductive layer includes a second opening overlapping with the first opening; the second conductive layer is provided over the first insulating layer; the semiconductor layer includes a region in contact with a top surface of the first conductive layer in the first opening, a region in contact with a side surface of the first insulating layer in the first opening, a region in contact with a side surface of the second conductive layer in the second opening, and a region in contact with a top surface of the second conductive layer; the gate insulating layer is provided over and in contact with the semiconductor layer; the gate electrode is provided over the gate insulating layer to include a region overlapping with the semiconductor layer; the gate electrode includes a third conductive layer and a fourth conductive layer stacked over the third conductive layer; an end portion of the third conductive layer is positioned in a region overlapping with the second conductive layer; the fourth conductive layer includes a region extending outward from the end portion of the third conductive layer; the second insulating layer covers a top surface and a side surface of the fourth conductive layer; and in the region where the fourth conductive layer extends outward from the end portion of the third conductive layer, the second insulating layer includes a region covering a bottom surface of the fourth conductive layer.

In the above structure, the fourth conductive layer preferably includes, in the region extending outward from the end portion of the third conductive layer, the second insulating layer between the region and the second conductive layer. Alternatively, in the above structure, the third conductive layer is preferably one selected from tantalum nitride, titanium nitride, ruthenium nitride, a nitride containing molybdenum, a nitride containing tungsten, titanium, and aluminum, and a nitride containing tantalum and aluminum.

In the above structure, the third conductive layer is preferably one selected from tantalum nitride, titanium nitride, ruthenium nitride, a nitride containing molybdenum, a nitride containing tungsten, titanium, and aluminum, and a nitride containing tantalum and aluminum, and the fourth conductive layer is preferably tungsten.

Another embodiment of the present invention is a method for manufacturing a semiconductor device, the method including the steps of: forming a first insulating layer over a first conductive layer; forming a second conductive layer over the first insulating layer; removing part of the second conductive layer and part of the first insulating layer to form a first opening reaching the first conductive layer and to expose a top surface of the first conductive layer; forming a first semiconductor layer in contact with the top surface of the first conductive layer, a side surface of the first insulating layer in the first opening, a side surface of the second conductive layer in the first opening, and a top surface of the second conductive layer; forming a second insulating layer in contact with a top surface of the first semiconductor layer and a top surface of the first insulating layer; stacking and forming a third conductive layer and a fourth conductive layer sequentially over the second insulating layer; forming a first mask by a photolithography method and removing part of the fourth conductive layer with the first mask to form a fifth conductive layer; and removing part of the third conductive layer with the fifth conductive layer as a mask to form a sixth conductive layer. The part of the third conductive layer is removed by wet etching, and the part of the fourth conductive layer is removed by dry etching.

In the above structure, when the part of the third conductive layer is removed, a region extending outward from an end portion of the sixth conductive layer is preferably formed in the fifth conductive layer; after the sixth conductive layer is formed, a third insulating layer is preferably formed in contact with a top surface of the fifth conductive layer, a side surface of the fifth conductive layer, and a top surface of the second insulating layer; and in the region where the fifth conductive layer extends outward from the end portion of the sixth conductive layer, the third insulating layer is preferably provided to include a region in contact with a bottom surface of the fifth conductive layer.

### Effect of the Invention

According to one embodiment of the present invention, a transistor with low parasitic capacitance can be provided. According to another embodiment of the present invention, a transistor with favorable electrical characteristics can be provided. According to another embodiment of the present invention, a transistor with a high on-state current can be provided. According to another embodiment of the present invention, a transistor, a semiconductor device, or a memory device that can be miniaturized or highly integrated can be provided. According to another embodiment of the present invention, a display device with a high resolution or a high aperture ratio can be provided. According to another embodiment of the present invention, a highly reliable transistor, a highly reliable semiconductor device, a highly reliable display device, or a highly reliable memory device can be provided. According to another embodiment of the present invention, a semiconductor device with low power consumption, a display device with low power consumption, or a memory device with low power consumption can be provided. According to another embodiment of the present invention, a memory device with high operation speed can be provided. According to another embodiment of the present invention, a method for manufacturing the above-described transistor, semiconductor device, display device, or memory device can be provided.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1A is a plan view illustrating an example of a semiconductor device. FIG. 1B and FIG. 1C are cross-sectional views illustrating the example of the semiconductor device.

FIG. 2A and FIG. 2C are cross-sectional views illustrating an example of a semiconductor device.

FIG. 2B is a plan view illustrating the example of the semiconductor device.

FIG. 3A and FIG. 3B are cross-sectional views illustrating an example of a semiconductor device.

FIG. 4A and FIG. 4B are cross-sectional views illustrating an example of a semiconductor device.

FIG. 5A to FIG. 5C are cross-sectional views illustrating an example of a method for manufacturing a semiconductor device.

FIG. 6A to FIG. 6C are cross-sectional views illustrating an example of a method for manufacturing a semiconductor device.

FIG. 7A to FIG. 7C are cross-sectional views illustrating an example of a method for manufacturing a semiconductor device.

FIG. 8A and FIG. 8B are cross-sectional views illustrating an example of a semiconductor device.

FIG. 9A and FIG. 9B are cross-sectional views illustrating examples of a semiconductor device.

FIG. 10A is a plan view illustrating an example of a memory device. FIG. 10B and FIG. 10C are cross-sectional views illustrating the example of the memory device.

FIG. 11A is a plan view illustrating an example of a memory device. FIG. 11B is a cross-sectional view illustrating the example of the memory device.

FIG. 12 is a cross-sectional view illustrating an example of a memory device.

FIG. 13 is a cross-sectional view illustrating an example of a memory device.

FIG. 14 is a block diagram illustrating a structure example of a semiconductor device.

FIG. 15A to FIG. 15H are diagrams each illustrating an example of a circuit structure of a memory cell.

FIG. 16A and FIG. 16B are perspective views illustrating structure examples of a semiconductor device.

FIG. 17 is a block diagram illustrating a CPU.

FIG. 18A and FIG. 18B are perspective views of a semiconductor device.

FIG. 19A and FIG. 19B are perspective views of a semiconductor device.

FIG. 20A and FIG. 20B are diagrams illustrating hierarchies of a variety of memory devices.

FIG. 21A and FIG. 21B are perspective views illustrating an example of a display device.

FIG. 22 is a cross-sectional view illustrating an example of a display device.

FIG. 23 is a cross-sectional view illustrating an example of a display device.

FIG. 24A to FIG. 24C are diagrams illustrating structure examples of a display device.

FIG. 25A and FIG. 25B are diagrams illustrating examples of electronic components.

FIG. 26A to FIG. 26C are diagrams illustrating an example of a large computer. FIG. 26D is a diagram illustrating an example of a device for space. FIG. 26E is a diagram illustrating an example of a storage system that can be used for a data center.

FIG. 27A to FIG. 27F are diagrams illustrating examples of electronic appliances.

FIG. 28A to FIG. 28G are diagrams illustrating examples of electronic appliances.

FIG. 29A to FIG. 29F are diagrams illustrating examples of electronic appliances.

FIG. 30 is a cross-sectional view illustrating an example of a display device.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in the structures of the invention described below, the same portions or portions having similar functions are denoted by the same reference numerals in different drawings, and description of such portions is not repeated. The same hatching pattern is used for portions having similar functions, and the portions are not denoted by specific reference numerals in some cases.

The position, size, range, and the like of each component illustrated in drawings do not represent the actual position, size, range, and the like in some cases for easy understanding. Therefore, the disclosed invention is not necessarily limited to the position, size, range, and the like disclosed in the drawings.

Note that ordinal numbers such as “first” and “second” in this specification and the like are used for convenience and do not limit the number or the order (e.g., the order of steps or the stacking order) of components. The ordinal number added to a component in a part of this specification may be different from the ordinal number added to the component in another part of this specification or the scope of claims.

A transistor is a kind of semiconductor element and enables amplification of a current or a voltage, a switching operation for controlling conduction or non-conduction, and the like. A transistor in this specification includes, in its category, an IGFET (Insulated Gate Field Effect Transistor) and a thin film transistor (TFT).

In this specification and the like, a transistor including an oxide semiconductor or a metal oxide in its semiconductor layer and a transistor including an oxide semiconductor or a metal oxide in its channel formation region are each sometimes referred to as an OS transistor. A transistor including silicon in its channel formation region is sometimes referred to as a Si transistor.

In this specification and the like, a transistor is an element including at least three terminals of a gate, a drain, and a source. The transistor includes a region where a channel is formed (also referred to as a channel formation region) between the drain (a drain terminal, a drain region, or a drain electrode) and the source (a source terminal, a source region, or a source electrode), and a current can flow between the source and the drain through the channel formation region. Note that in this specification and the like, a channel formation region refers to a region through which a current mainly flows.

The functions of a “source” and a “drain” are sometimes replaced with each other when a transistor of different polarity is used or when the direction of current flow is changed in circuit operation, for example. Thus, the terms “source” and “drain” can be used interchangeably in this specification.

Note that impurities in a semiconductor refer to, for example, elements other than the main components of the semiconductor. For example, an element with a concentration lower than 0.1 atomic % can be regarded as an impurity. When a semiconductor contains an impurity, an increase in density of defect states or a reduction in crystallinity of the semiconductor may occur, for example. In the case where the semiconductor is an oxide semiconductor, examples of an impurity that changes the characteristics of the semiconductor include Group 1 elements, Group 2 elements, Group 13 elements, Group 14 elements, Group 15 elements, and transition metals other than the main components of the oxide semiconductor. Specific examples include hydrogen, lithium, sodium, silicon, boron, phosphorus, carbon, and nitrogen. Note that water also serves as an impurity in some cases. In addition, oxygen vacancies (also referred to as Vo) are formed in an oxide semiconductor in some cases by entry of impurities, for example.

Note that in this specification and the like, an oxynitride refers to a material having a composition in which the oxygen content is higher than the nitrogen content. A nitride oxide refers to a material having a composition in which the nitrogen content is higher than the oxygen content.

The contents of elements such as hydrogen, oxygen, carbon, and nitrogen in a film can be analyzed by secondary ion mass spectrometry (SIMS) or X-ray photoelectron spectroscopy (XPS), for example. XPS is suitable when the content percentage of a target element is high (e.g., higher than or equal to 0.5 atomic %, or higher than or equal to 1 atomic %). By contrast, SIMS is suitable when the content percentage of a target element is low (e.g., lower than or equal to 0.5 atomic %, or lower than or equal to 1 atomic %). To compare the contents of elements, a combined analysis using both SIMS and XPS is further preferably performed.

Note that the terms “film” and “layer” can be used interchangeably depending on the case or the circumstances. For example, the term “conductive layer” can be replaced with the term “conductive film”. For another example, the term “insulating film” can be replaced with the term “insulating layer”.

In this specification and the like, “parallel” indicates a state where two straight lines are placed at an angle greater than or equal to −10° and less than or equal to 10°. Thus, the case where the angle is greater than or equal to −5° and less than or equal to 5° is also included. Furthermore, “substantially parallel” indicates a state where two straight lines are placed at an angle greater than or equal to −30° and less than or equal to 30°. Moreover, “perpendicular” indicates a state where two straight lines are placed at an angle greater than or equal to 80° and less than or equal to 100°. Thus, the case where the angle is greater than or equal to 85° and less than or equal to 95° is also included. Furthermore, “substantially perpendicular” indicates a state where two straight lines are placed at an angle greater than or equal to 60° and less than or equal to 120°.

In this specification and the like, the term “electrically connected” includes the case where components are connected to each other through an “object having any electric action”. Here, there is no particular limitation on the “object having any electric function” as long as electric signals can be transmitted and received between the components that are connected through the object. Examples of the “object having any electric function” include a switching element such as a transistor, a resistor, a coil, and other elements with a variety of functions as well as an electrode or a wiring.

Unless otherwise specified, an off-state current in this specification and the like refers to a leakage current between a source and a drain generated when a transistor is in an off state (also referred to as a non-conducting state or a cutoff state). Unless otherwise specified, an off state of an n-channel transistor refers to a state where a voltage Vgs between its gate and source is lower than a threshold voltage Vth (in a p-channel transistor, higher than Vth).

In this specification and the like, normally-on characteristics mean a state where a channel exists without application of a voltage to a gate and a current flows through a transistor. Furthermore, normally-off characteristics mean a state where a current does not flow through a transistor when no potential or a ground potential is applied to a gate.

Note that in this specification and the like, a top-view shape of a component means an outline shape of the component in a plan view. A plan view means that the component is observed from a normal direction of a surface where the component is formed or from a normal direction of a surface of a support (e.g., a substrate) where the component is formed.

In this specification and the like, the expression “having substantially the same top-view shapes” means that the outlines of stacked layers at least partly overlap with each other. For example, the case of processing an upper layer and a lower layer with the use of the same mask pattern or mask patterns that are partly the same is included. However, in some cases, the outlines do not completely overlap with each other and the upper layer is positioned inward from the lower layer or the upper layer is positioned outward from the lower layer; such a case is also represented by the expression “having substantially the same top-view shapes”. In the case where the top-view shapes are the same or substantially the same, it can be said that end portions match or substantially match each other or side end portions are aligned or substantially aligned with each other.

In this specification and the like, a tapered shape refers to such a shape that at least part of the side surface of a component is inclined with respect to a substrate surface or a formation surface. For example, a tapered shape preferably includes a region where the angle between the inclined side surface and the substrate surface or the formation surface (such an angle is also referred to as a taper angle) is greater than 0° and less than 90°. Note that the side surface, the substrate surface, and the formation surface of the component are not necessarily completely flat, and may have a substantially planar shape with a small curvature or a substantially planar shape with slight unevenness.

In this specification and the like, when the expression “A is in contact with B” is used, at least part of A is in contact with B. In other words, A includes a region in contact with B, for example.

In this specification and the like, when the expression “A is positioned over B” is used, at least part of A is positioned over B. In other words, A includes a region positioned over B, for example.

In this specification and the like, when the expression “A covers B” is used, at least part of A covers B. In other words, A includes a region covering B, for example.

In this specification and the like, when the expression “A overlaps with B” is used, at least part of A overlaps with B. In other words, A includes a region overlapping with B, for example.

In this specification and the like, a device formed using a metal mask or an FMM (fine metal mask, high-resolution metal mask) may be referred to as a device having an MM (metal mask) structure. In this specification and the like, a device fabricated without using a metal mask or an FMM is sometimes referred to as a device having an MML (metal maskless) structure.

In this specification and the like, a structure in which light-emitting layers of light-emitting elements (also referred to as light-emitting devices) having different emission wavelengths are separately formed is sometimes referred to as an SBS (Side By Side) structure. The SBS structure can optimize materials and structures of light-emitting elements and thus can extend the freedom of choice of materials and structures, whereby the luminance and the reliability can be easily improved.

In this specification and the like, a hole or an electron is sometimes referred to as a “carrier”. Specifically, a hole-injection layer or an electron-injection layer may be referred to as a “carrier-injection layer”, a hole-transport layer or an electron-transport layer may be referred to as a “carrier-transport layer”, and a hole-blocking layer or an electron-blocking layer may be referred to as a “carrier-blocking layer”. Note that the above-described carrier-injection layer, carrier-transport layer, and carrier-blocking layer cannot be clearly distinguished from each other in some cases. One layer may have two or three functions of the carrier-injection layer, the carrier-transport layer, and the carrier-blocking layer in some cases.

In this specification and the like, the light-emitting element includes an EL layer between a pair of electrodes. The EL layer includes at least a light-emitting layer. Here, examples of layers (also referred to as functional layers) included in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer). In this specification and the like, a light-receiving element (also referred to as a light-receiving device) includes at least an active layer functioning as a photoelectric conversion layer between a pair of electrodes. In this specification and the like, one of the pair of electrodes may be referred to as a pixel electrode and the other may be referred to as a common electrode.

In this specification and the like, a sacrificial layer (which may be referred to as a mask layer) is positioned above at least a light-emitting layer (specifically, a layer processed into an island shape among layers included in an EL layer) and has a function of protecting the light-emitting layer in the manufacturing process.

In this specification and the like, disconnection refers to a phenomenon in which a layer, a film, or an electrode is split because of the shape of its formation surface (e.g., a step).

In the drawings for this specification and the like, arrows indicating an X direction, a Y direction, and a Z direction are illustrated in some cases. In this specification and the like, the “X direction” is a direction along the X axis, and unless otherwise specified, the forward direction and the reverse direction are not distinguished in some cases. The same applies to the “Y direction” and the “Z direction”. The X direction, the Y direction, and the Z direction are directions intersecting with each other. For example, the X direction, the Y direction, and the Z direction are directions orthogonal to each other.

### Embodiment 1

In this embodiment, a semiconductor device of one embodiment of the present invention is described.

The semiconductor device of one embodiment of the present invention includes a first conductive layer, a second conductive layer, a third conductive layer, an oxide semiconductor layer, a first insulating layer, and a second insulating layer.

The first insulating layer is positioned over the first conductive layer, and the second conductive layer is positioned over the first insulating layer. The first insulating layer and the second conductive layer include an opening reaching the first conductive layer. The oxide semiconductor layer is in contact with at least the top surface of the first conductive layer, the side surface of the first insulating layer, and the side surface of the second conductive layer in the opening. The second insulating layer is positioned over the oxide semiconductor layer in the opening. The third conductive layer overlaps with the oxide semiconductor layer with the second insulating layer positioned therebetween in the opening.

The first conductive layer functions as one of a source electrode and a drain electrode of a transistor. The second conductive layer functions as the other of the source electrode and the drain electrode of the transistor. The third conductive layer functions as a gate electrode of the transistor, and the second insulating layer functions as a gate insulating layer.

Note that in this specification and the like, a simple expression “in a cross-sectional view” is replaced with a specific expression “in a cross-sectional view from the same direction” in some cases. For example, in the case where the relation between a plurality of components is described, a relation in a cross-sectional view from the same direction is described. In this case, the relation between the plurality of components can be described using one cross-sectional view.

In the transistor of one embodiment of the present invention, the source electrode and the drain electrode are positioned at different levels, so that a current flows in the semiconductor layer in the height direction. In other words, the channel length direction includes a component of the height direction (vertical direction); accordingly, the transistor of one embodiment of the present invention can also be referred to as a VFET (Vertical Field Effect Transistor), a vertical transistor, a vertical-channel transistor, a vertical-channel-type transistor, or the like.

In the transistor of one embodiment of the present invention, the source electrode, the semiconductor layer, and the drain electrode can be provided to overlap with each other. Thus, the footprint of the transistor can be significantly smaller than the footprint of what is called a planar transistor in which a planar semiconductor layer is provided.

Note that in this specification and the like, the expression “end portions are aligned” means that outlines of stacked layers at least partly overlap with each other in a plan view. For example, the case of processing an upper layer and a lower layer with the use of the same mask pattern or mask patterns that are partly the same is included. Note that, in some cases, the outlines do not exactly overlap with each other and the outline of the upper layer is positioned inward from the outline of the lower layer or the outline of the upper layer is positioned outward from the outline of the lower layer; such a case is also represented by the expression “end portions are aligned”.

In general, it is sometimes difficult to clearly differentiate “completely aligned” from “substantially aligned”. Thus, in this specification and the like, the expression “aligned” includes both “completely aligned” and “substantially aligned”, in some cases.

### Structure Example 1 of Semiconductor Device

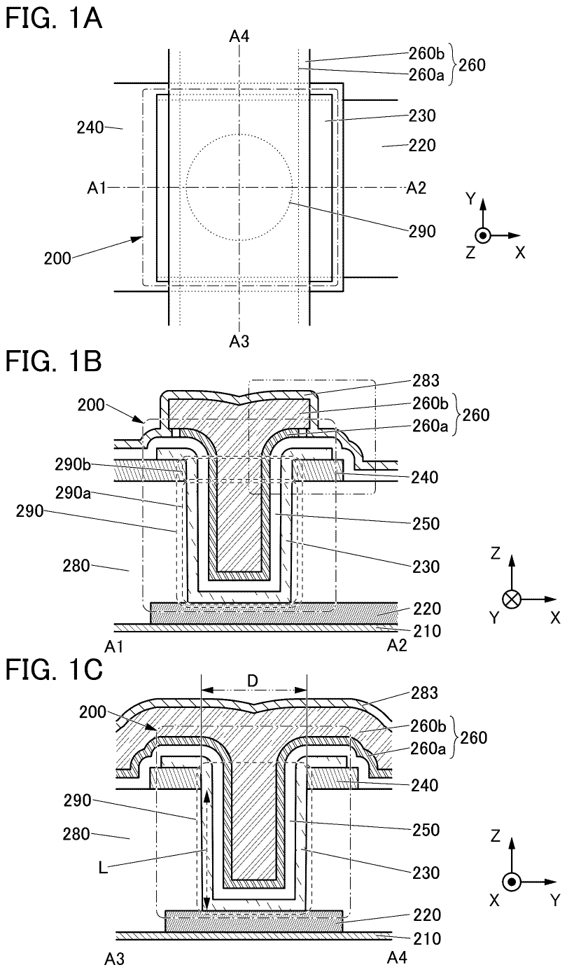

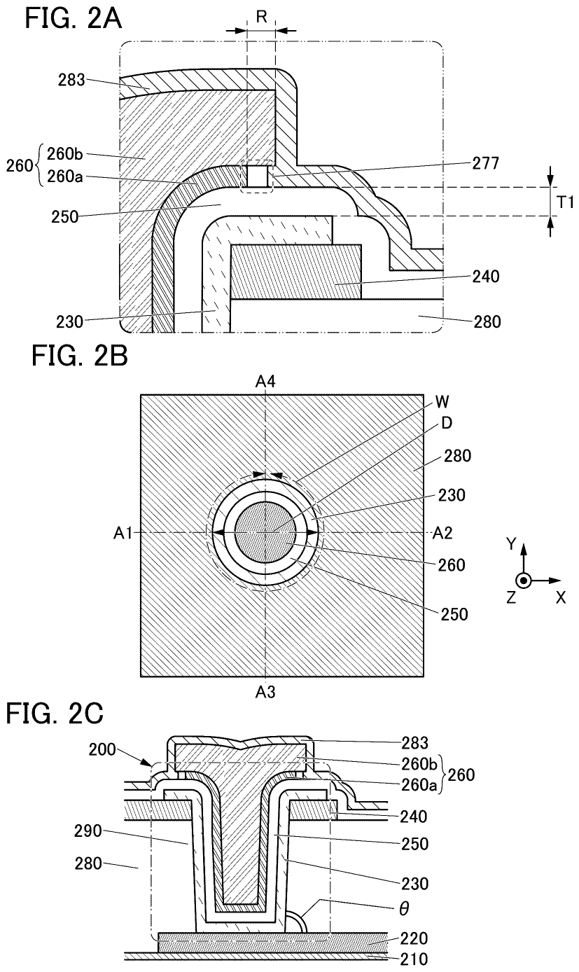

Structures of the semiconductor device of one embodiment of the present invention are described with reference to FIG. 1A to FIG. 3B. FIG. 1A is a plan view of the semiconductor device including a transistor 200. FIG. 1B is a cross-sectional view taken along dashed-dotted line A1-A2 in FIG. 1A. FIG. 1C is a cross-sectional view taken along dashed-dotted line A3-A4 in FIG. 1A. FIG. 2A is an enlarged view of a region surrounded by a dashed-dotted line in FIG. 1B. Note that some components are omitted in the plan view in FIG. 1A for clarity of the drawing. Some components may be omitted also in the following plan views.

The semiconductor device illustrated in FIG. 1A to FIG. 1C, FIG. 2A, and FIG. 2B includes an insulating layer 210 over a substrate (not illustrated), the transistor 200 over the insulating layer 210, an insulating layer 280 over the insulating layer 210, and an insulating layer 283 over the transistor 200. The insulating layer 210, the insulating layer 280, and the insulating layer 283 function as interlayer films.

The transistor 200 includes a conductive layer 220, a conductive layer 240 over the insulating layer 280, an oxide semiconductor layer 230, an insulating layer 250 over the oxide semiconductor layer 230, and a conductive layer 260 over the insulating layer 250. The conductive layer 260 includes a conductive layer 260a and a conductive layer 260b stacked over the conductive layer 260a. The conductive layer 220 and the conductive layer 240 are positioned at different levels. The insulating layer 283 covers the top surface and the side surface of the conductive layer 260b.

As illustrated in FIG. 1B and FIG. 1C, an opening 290 reaching the conductive layer 220 is provided in the insulating layer 280 and the conductive layer 240. Here, the bottom portion of the opening 290 is the top surface of the conductive layer 220, and the sidewall of the opening 290 is the side surface of the insulating layer 280 and the side surface of the conductive layer 240. The opening 290 includes an opening of the insulating layer 280 and an opening of the conductive layer 240. In other words, the opening of the insulating layer 280 in a region overlapping with the conductive layer 220 is part of the opening 290, and the opening of the conductive layer 240 in a region overlapping with the conductive layer 220 is another part of the opening 290. Note that the opening 290 provided in the insulating layer 280 is referred to as an opening 290a, and the opening 290 provided in the conductive layer 240 is referred to as an opening 290b.

At least part of the components of the transistor 200 is placed in the opening 290. Specifically, at least part of each of the oxide semiconductor layer 230, the insulating layer 250, and the conductive layer 260 is positioned in the opening 290. The oxide semiconductor layer 230 is in contact with the top surface of the conductive layer 220, the side surface of the insulating layer 280, and the side surface of the conductive layer 240 in the opening 290.

The portions of the oxide semiconductor layer 230 and the insulating layer 250 that are placed in the opening 290 reflect the shape of the opening 290. Specifically, the oxide semiconductor layer 230 is provided to cover the bottom portion and the sidewall of the opening 290, and the insulating layer 250 is provided to cover the oxide semiconductor layer 230. The conductive layer 260 is provided to fill a depressed portion of the insulating layer 250 that reflects the shape of the opening 290.

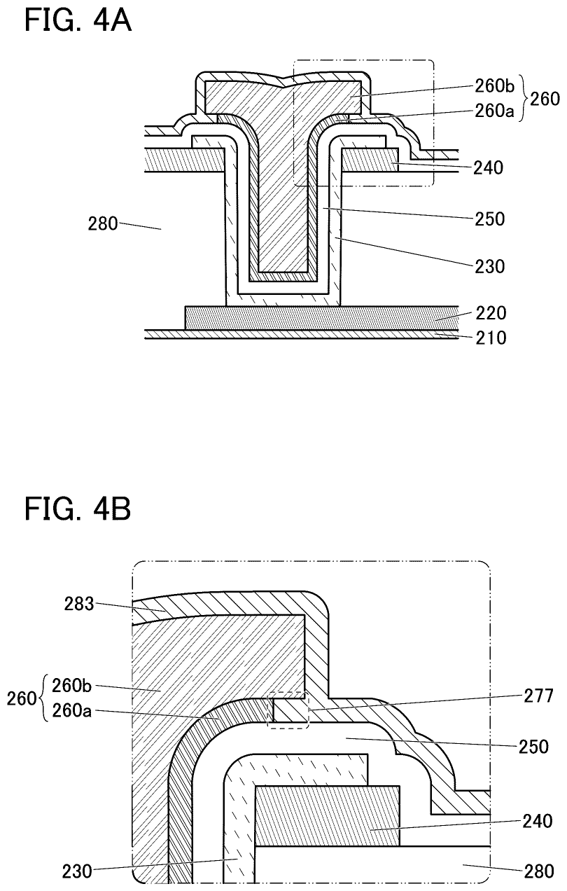

The transistor of one embodiment of the present invention includes a region 277 between the conductive layer 260b and the insulating layer 250, so that the breakdown voltage of the insulating layer 250 can be increased. The region 277 is a gap, for example. Providing the gap can keep the conductive layer 260b and the conductive layer 240 away from each other and can inhibit a leakage current from flowing through the insulating layer 250 between the conductive layer 260b and the conductive layer 240. As described later with reference to FIG. 4A and FIG. 4B, the gap can also be filled with the insulating layer 283.

The width of the opening 290 is referred to as a width D. The width D varies in the depth direction, in some cases. For example, the width D can be the width of an upper end of the opening 290 of the insulating layer 280. Alternatively, the width D can be the width of a lower end of the opening 290 of the insulating layer 280. Alternatively, the width D can be the width at half of the depth of the opening 290 in the insulating layer 280. Alternatively, the width of the opening 290 in the conductive layer 240 can be used.

The region of the oxide semiconductor layer 230 that is in contact with the conductive layer 240 sometimes functions as a low-resistance region.

In the transistor 200, the oxide semiconductor layer 230 functions as a semiconductor layer, the conductive layer 260 functions as a gate electrode, the insulating layer 250 functions as a gate insulating layer, the conductive layer 220 functions as one of a source electrode and a drain electrode, and the conductive layer 240 functions as the other of the source electrode and the drain electrode.

As described above, the oxide semiconductor layer 230 is provided inside the opening 290 of the insulating layer 280. The transistor 200 has a structure in which a current flows in the vertical direction since the one of the source electrode and the drain electrode (here, the conductive layer 220) is positioned below and the other of the source electrode and the drain electrode (here, the conductive layer 240) is positioned above. That is, a channel is formed along the side surface of the opening of the insulating layer 280.

The oxide semiconductor layer 230 is in contact with the top surface of the conductive layer 220 and the side surface of the conductive layer 240 in the opening 290. The oxide semiconductor layer 230 is also in contact with part of the top surface of the conductive layer 240. When the oxide semiconductor layer 230 is in contact with not only the side surface of the conductive layer 240 but also the top surface of the conductive layer 240 in this manner, the area where the oxide semiconductor layer 230 and the conductive layer 240 are in contact with each other can be increased as compared with the case where the oxide semiconductor layer 230 is not in contact with the top surface of the conductive layer 240 but in contact with the side surface of the conductive layer 240, for example. Thus, the contact resistance between the oxide semiconductor layer 230 and the conductive layer 240 can be reduced.

The sidewall of the opening 290 is preferably perpendicular to the top surface of the insulating layer 210. Such a structure enables miniaturization or high integration of the semiconductor device. In that case, each of the films provided inside the opening 290 is preferably formed by an atomic layer deposition (ALD) method. The ALD method enables atomic layers to be deposited one by one, and has advantages such as formation of an extremely thin film, formation of a film on a component with a high aspect ratio, formation of a film with few defects such as pinholes, formation of a film with excellent coverage, and low-temperature film formation. Thus, the film can be formed on the side surface of the opening 290 with favorable coverage. For example, the oxide semiconductor layer 230, the insulating layer 250, and the conductive layer 260 can each be formed by an ALD method. Here, between the conductive layer 260a and the conductive layer 260b, the conductive layer 260a is particularly preferably formed by an ALD method, for example.

Although the opening 290 is provided such that the sidewall of the opening 290 is perpendicular to the top surface of the insulating layer 210 in FIG. 1B and FIG. 1C, the present invention is not limited thereto. The sidewall of the opening 290 may have a tapered shape, for example. FIG. 2C illustrates an example in which the sidewall of the opening 290 has a tapered shape in FIG. 1B. When the sidewall of the opening 290 has a tapered shape, the coverage with the oxide semiconductor layer 230, the insulating layer 250, and the like can be improved, so that defects such as voids can be reduced. In the case where the sidewall of the opening 290 has a tapered shape, an angle θ between the side surface of the insulating layer 280 in the opening 290 and the top surface of the insulating layer 210 is preferably greater than or equal to 45° and less than 90°, for example. Specifically, the angle θ is preferably greater than or equal to 80° and less than 90°, in which case the semiconductor device can be miniaturized or highly integrated as described above. Alternatively, the angle θ is preferably greater than or equal to 45° and less than or equal to 60°, in which case the coverage with a film to be formed in the opening 290 is improved. Specifically, for example, the angle θ is preferably greater than or equal to 45° or greater than or equal to 50° and less than 80°, less than or equal to 75°, less than or equal to 70°, less than or equal to 65°, or less than or equal to 60°.

Alternatively, for example, the sidewall of the opening 290 may have an inverse tapered shape. In other words, the angle between the side surface of the insulating layer 280 in the opening 290 and the top surface of the insulating layer 210 may be greater than 90°.

The conductive layer 240 includes the opening in a region overlapping with the conductive layer 220. Furthermore, it is preferable that the conductive layer 240 not be provided inside the opening of the insulating layer 280. That is, it is preferable that the conductive layer 240 not include a region in contact with the side surface of the insulating layer 280 in the opening 290. When such a structure is employed, the opening of the conductive layer 240 and the opening of the insulating layer 280 can be collectively formed. When the side surface of the conductive layer 240 in the opening 290 is aligned or substantially aligned with the side surface of the insulating layer 280 in the opening 290, the thickness distribution of the oxide semiconductor layer 230 provided inside the opening 290 can be uniform. In addition, the oxide semiconductor layer 230 can be inhibited from being divided by a step between the conductive layer 240 and the insulating layer 280.

Although the side surface of the conductive layer 240 in the opening 290 is aligned or substantially aligned with the side surface of the insulating layer 280 in the opening 290 in the structure illustrated in FIG. 1B and FIG. 1C, the present invention is not limited thereto. For example, the side surface of the conductive layer 240 in the opening 290 and the side surface of the insulating layer 280 in the opening 290 may be discontinuous. The inclination of the side surface of the conductive layer 240 in the opening 290 and the inclination of the side surface of the insulating layer 280 in the opening 290 may be different from each other. In that case, for example, the angle between the side surface of the conductive layer 240 in the opening 290 and the top surface of the insulating layer 210 is preferably smaller than the angle between the side surface of the insulating layer 280 in the opening 290 and the top surface of the insulating layer 210. With such a structure, the coverage of the side surface of the conductive layer 240 in the opening 290 with the oxide semiconductor layer 230 is improved, so that the number of defects such as voids can be reduced.

Here, outside the opening 290, the end portion of the oxide semiconductor layer 230 is positioned inward from the end portion of the conductive layer 240 in the structure illustrated in FIGS. 1B and 1C. Note that the present invention is not limited thereto. For example, in the X direction, the end portion of the oxide semiconductor layer 230 and the end portion of the conductive layer 240 are aligned with each other in some cases. Alternatively, the end portion of the oxide semiconductor layer 230 is positioned outward from the end portion of the conductive layer 240 in some cases.

Outside the opening 290, the end portion of the conductive layer 240 is positioned outward from the end portion of the conductive layer 260 in the structure illustrated in FIG. 1B. With such a structure, a plug or the like can be provided over the region of the conductive layer 240 that extends outward from the conductive layer 260, so as to electrically connect the conductive layer 240 and a conductive layer such as a wiring, an electrode, or the like positioned above the conductive layer 260 to each other.

The insulating layer 250 is provided in contact with the top surface of the oxide semiconductor layer 230. The insulating layer 250 preferably includes a region in contact with the top surface of the conductive layer 240, a region in contact with the side surface of the conductive layer 240, and a region in contact with the insulating layer 280.

As illustrated in FIG. 1B and FIG. 1C, part of the insulating layer 250 is positioned outside the opening 290, that is, over the conductive layer 240 and the insulating layer 280. Here, the insulating layer 250 preferably covers the end portion of the oxide semiconductor layer 230. In that case, a short circuit between the conductive layer 260 and the oxide semiconductor layer 230 can be prevented. The insulating layer 250 preferably covers the end portion of the conductive layer 240. In that case, a short circuit between the conductive layer 260 and the conductive layer 240 can be prevented.

The region of the insulating layer 250 outside the end portion of the conductive layer 260 is exposed to an etching atmosphere at the time of forming the conductive layer 260 and might thus be damaged by the etching. The damage due to the etching might reduce the breakdown voltage of the insulating layer 250. In particular, when dry etching is used in the step of forming the conductive layer 260, the damage due to the etching is sometimes more noticeable.

The thickness of the insulating layer 250 in a region outside the end portion of the conductive layer 260 is sometimes reduced by overetching in the step of forming the conductive layer 260. In particular, when dry etching is used in the step of forming the conductive layer 260, the reduction in the thickness of the insulating layer 250 due to the overetching is sometimes more noticeable. In the region of the insulating layer 250 where the thickness is reduced, the breakdown voltage might be reduced.

In the region of the insulating layer 250 where the breakdown voltage is reduced, for example, a gate leakage current that flows owing to the electric field between the conductive layer 260 and the conductive layer 240 might increase. In the case where the damage to the insulating layer 250 or the reduction in the thickness of the insulating layer 250 is noticeable, a short circuit between the conductive layer 260 and the conductive layer 240 might occur, for example.

Here, in the semiconductor device of one embodiment of the present invention, as illustrated in FIG. 1B, FIG. 2A, and the like, the conductive layer 260 includes the conductive layer 260a and the conductive layer 260b, and the conductive layer 260b includes a region extending outward from the end portion of the conductive layer 260a.

The end portion of the conductive layer 260b is positioned outward from the end portion of the conductive layer 260a. In the cross section illustrated in FIG. 1B, the conductive layer 260b and the conductive layer 260a extend from the opening 290 in both the positive direction and the negative direction of X. It can also be expressed that the side surface of the conductive layer 260b extending in the positive direction (negative direction) of X is positioned outward, with respect to the opening 290, from the side surface of the conductive layer 260a extending in the positive direction (negative direction) of X.

In the top view in FIG. 1A and the like, the outline of the conductive layer 260b is positioned outward from the outline of the conductive layer 260a.

The structure of the conductive layer 260a as illustrated in FIG. 1B, FIG. 2A, and the like can be formed by wet etching, for example.

When isotropic etching is used as the wet etching condition, a structure in which the end portion of the conductive layer 260a is positioned inward from the end portion of the conductive layer 260b can be obtained at the time of forming the conductive layer 260a using the conductive layer 260b as a mask.

Furthermore, when wet etching is used and the selectivity of the etching rate of the conductive layer 260 with respect to the etching rate of the insulating layer 250 is high, it is possible to inhibit a reduction in the thickness of the insulating layer 250 due to overetching in the step of forming the conductive layer 260. In addition, wet etching causes less damage than dry etching in some cases and can reduce damage to the insulating layer 250 in some cases. Here, high selectivity of the etching rate of the conductive layer 260 with respect to the etching rate of the insulating layer 250 means that the etching rate of the conductive layer 260 is higher than that of the insulating layer 250.

In the transistor 200 illustrated in FIG. 1B, FIG. 2A, and the like, the conductive layer 260a is positioned over the insulating layer 250, and in the region extending outward from the end portion of the conductive layer 260a, the conductive layer 260b includes the region 277 between the region extending outward from the end portion of the conductive layer 260a and the insulating layer 250. The region 277 is a gap, for example.

The region 277 provided between the conductive layer 260b and the insulating layer 250 can prevent the region of the conductive layer 260 that is in contact with the insulating layer 250, e.g., the conductive layer 260a here, from overlapping with the region of the insulating layer 250 that might be damaged, so that the breakdown voltage of the insulating layer 250 can be increased. Alternatively, the region of the conductive layer 260 that is in contact with the insulating layer 250, e.g., the conductive layer 260a here, can be prevented from overlapping with the region of the insulating layer 250 where the thickness might be reduced.

The region 277 is, for example, a gap, i.e., an empty space. The region 277 includes one or more selected from air, nitrogen, oxygen, carbon dioxide, and a Group 18 element, for example. The region 277 has substantially the same relative permittivity as air, for example. In the case where the region 277 includes air, the relative permittivity of the region 277 is one or a value in the neighborhood thereof, for example. One or a value in the neighborhood thereof is, for example, greater than or equal to 0.8 and less than or equal to 1.2. Alternatively, the relative permittivity of the region 277 is greater than or equal to 1 and less than or equal to 1.2. When the region 277 is air, a gap can be provided between the conductive layer 260 and the conductive layer 240, so that a leakage current can be inhibited from flowing through the insulating layer 250 between the conductive layers.

In the case where the region 277 is a gap, for example, the relative permittivity of the region 277 is lower than that of the insulating layer 250. The relative permittivity of the region 277 is lower than that of the insulating layer 283, for example. The film density of the region 277 is lower than that of the insulating layer 250, for example. The film density of the region 277 is lower than that of the insulating layer 283, for example. When the region 277 is provided as a region with low relative permittivity, the parasitic capacitance between the conductive layer 260 and the conductive layer 240 can be low, for example.

The region 277 may be filled with the insulating layer 283, which is formed after the formation of the conductive layer 260. FIG. 4A illustrates an example in which the region 277 in FIG. 1B is filled with the insulating layer 283. FIG. 4B is an enlarged view of the region surrounded by the dashed double-dotted line in FIG. 4A.

In the case where the region 277 is filled with the insulating layer 283, for example, the relative permittivity of the region 277 is the same as, or has a value in the neighborhood of, the relative permittivity of the insulating layer 283. For example, the relative permittivity of the region 277 is greater than or equal to 0.8 times and less than or equal to 1.2 times the relative permittivity of the insulating layer 283.

In FIG. 4A and FIG. 4B, the insulating layer 283 includes a region covering the bottom surface of the conductive layer 260b in the region where the conductive layer 260b extends outward from the conductive layer 260a.

The insulating layer 283 includes a region positioned between the region of the conductive layer 260b that extends outward from the conductive layer 260a and the insulating layer 250.

Note that only part of the region 277 may be filled with the insulating layer 283.

Here, the width of the region where the end portion of the conductive layer 260b extends outward from the end portion of the conductive layer 260a is a width R. The width R corresponds to, for example, the distance between the end portion of the conductive layer 260b and the end portion of the conductive layer 260a. It is also possible to use the expression “the outline of the conductive layer 260b in the top view is positioned outward from the outline of the conductive layer 260a by the width R”.

The thickness of the insulating layer 250 is a thickness T1. As the thickness T1, for example, the thickness of the region of the insulating layer 250 that covers the top surface of the conductive layer 240 can be used. The thickness T1 can be the thickness of the region covering the top surface of the conductive layer 240 and being covered with the conductive layer 260b. As the thickness T1, for example, the thickness of the region sandwiched between the oxide semiconductor layer 230 and the conductive layer 260 can be used. As the thickness T1, for example, the thickness of the region positioned in the opening 290 may be used.

The width R is preferably greater than or equal to 10% and less than or equal to 25% of the width D, for example.

The thickness T1 is greater than or equal to 0.5 nm and less than or equal to 200 nm, for example, and is greater than or equal to 1 nm and less than or equal to 50 nm, for example.

The width R is, for example, greater than or equal to 0.3 times and less than or equal to 10 times the thickness T1, or greater than or equal to 0.5 times and less than or equal to 5 times the thickness T1.

In the transistor 200, the oxide semiconductor layer 230 including a channel formation region includes a metal oxide functioning as a semiconductor (such a metal oxide is also referred to as an oxide semiconductor). That is, the transistor 200 can be regarded as an OS transistor.

When oxygen vacancies (Vo) and impurities are in a channel formation region in an oxide semiconductor in an OS transistor, electrical characteristics of the OS transistor easily vary and the reliability thereof might worsen. In some cases, hydrogen in the vicinity of an oxygen vacancy forms a defect that is an oxygen vacancy into which hydrogen enters (hereinafter sometimes referred to as VoH), which generates an electron serving as a carrier. Thus, when the channel formation region in the oxide semiconductor includes oxygen vacancies, the OS transistor tends to have normally-on characteristics. Therefore, the oxygen vacancies and the impurities are preferably reduced as much as possible in the channel formation region in the oxide semiconductor. In other words, the channel formation region in the oxide semiconductor is preferably an i-type (intrinsic) or substantially i-type region with a reduced carrier concentration.

Meanwhile, preferably, the source region and the drain region of the OS transistor include more oxygen vacancies, more VoH, or a higher concentration of an impurity such as hydrogen, nitrogen, or a metal element than the channel formation region, and thus are low-resistance regions with high carrier concentrations. In other words, the source region and the drain region of the OS transistor are preferably n-type regions having higher carrier concentrations and lower resistances than the channel formation region.

The region of the oxide semiconductor layer 230 that is in contact with the insulating layer 280 and the vicinity of the region function as the channel formation region of the transistor 200. One of the region of the oxide semiconductor layer 230 that is in contact with the conductive layer 220 and the region of the oxide semiconductor layer 230 that is in contact with the conductive layer 240 functions as a source region, and the other functions as a drain region. That is, the channel formation region is sandwiched between the source region and the drain region.

Since the oxide semiconductor layer 230 and the conductive layer 220 are in contact with each other, a metal compound or oxygen vacancies are formed, so that the resistance of the region of the oxide semiconductor layer 230 that is in contact with the conductive layer 220 is reduced. Accordingly, the contact resistance between the oxide semiconductor layer 230 and the conductive layer 220 can be reduced. Similarly, since the oxide semiconductor layer 230 and the conductive layer 240 are in contact with each other, the resistance of the region of the oxide semiconductor layer 230 that is in contact with the conductive layer 240 is reduced. Accordingly, the contact resistance between the oxide semiconductor layer 230 and the conductive layer 240 can be reduced.

As illustrated in FIG. 2B, the insulating layer 280 is in contact with the entire outer circumference of the oxide semiconductor layer 230. Thus, the channel formation region of the transistor 200 can be formed in the entire outer circumference of the portion of the oxide semiconductor layer 230 that is formed in the same layer as the insulating layer 280. Note that FIG. 2B can be regarded as a cross-sectional view along the XY plane including the channel formation region of the oxide semiconductor layer 230.

The channel length of the transistor 200 is the distance between the source region and the drain region. In other words, the channel length of the transistor 200 is determined by the thickness of the insulating layer 280 over the conductive layer 220. In FIG. 1C, a channel length L of the transistor 200 is indicated by a dashed double-headed arrow. The channel length L is the distance between the end portion of the region where the oxide semiconductor layer 230 and the conductive layer 220 are in contact with each other and the end portion of the region where the oxide semiconductor layer 230 and the conductive layer 240 are in contact with each other in the cross-sectional view. That is, the channel length L corresponds to the length of the side surface of the insulating layer 280 on the opening 290 side in the cross-sectional view.

Further miniaturization of a conventional transistor, e.g., a planar transistor, has been difficult since the channel length thereof is restricted by the light exposure limit of photolithography; however, in the present invention, the channel length can be set by the thickness of the insulating layer 280. Thus, the transistor 200 can have an extremely small channel length less than or equal to the light exposure limit of photolithography (e.g., less than or equal to 60 nm, less than or equal to 50 nm, less than or equal to 40 nm, less than or equal to 30 nm, less than or equal to 20 nm, or less than or equal to 10 nm, and greater than or equal to 0.1 nm, greater than or equal to 1 nm, or greater than or equal to 5 nm). Accordingly, the transistor 200 can have a higher on-state current and higher frequency characteristics.

In addition, as described above, the channel formation region, the source region, and the drain region can be formed in the opening 290. Thus, the footprint of the transistor 200 can be reduced as compared with a lateral transistor, in which the channel formation region, the source region, and the drain region are provided separately on the XY plane. Thus, the semiconductor device can be highly integrated. In the case where the semiconductor device of one embodiment of the present invention is used in a memory device, the storage capacity per unit area can be increased.

As illustrated in FIG. 2B, the oxide semiconductor layer 230, the insulating layer 250, and the conductive layer 260 are provided concentrically. Therefore, the side surface of the conductive layer 260 provided at the center faces the side surface of the oxide semiconductor layer 230 with the insulating layer 250 therebetween. That is, in the plan view, the entire circumference of the oxide semiconductor layer 230 serves as the channel formation region. In this case, for example, the channel width of the transistor 200 is determined by the length of the outer circumference of the oxide semiconductor layer 230. In other words, the channel width of the transistor 200 is determined by the width of the opening 290 (the diameter in the case where the opening 290 is circular in the plan view). In FIG. 1C and FIG. 2B, the width D of the opening 290 is indicated by a dashed double-dotted double-headed arrow. In FIG. 2B, a channel width W of the transistor 200 is indicated by a dashed-dotted double-headed arrow. By increasing the width D of the opening 290, the channel width per unit area can be increased and the on-state current can be increased.

In the case where the opening 290 is formed by a photolithography method, the width D of the opening 290 is restricted by the light exposure limit of photolithography. In addition, the width D of the opening 290 is set by the thicknesses of the oxide semiconductor layer 230, the insulating layer 250, and the conductive layer 260 provided in the opening 290. The width D of the opening 290 is preferably, for example, greater than or equal to 5 nm, greater than or equal to 10 nm, or greater than or equal to 20 nm and less than or equal to 100 nm, less than or equal to 60 nm, less than or equal to 50 nm, less than or equal to 40 nm, or less than or equal to 30 nm. In the case where the opening 290 is circular in the plan view, the width D of the opening 290 corresponds to the diameter of the opening 290, and the channel width W can be calculated to be “D×π”.

The channel length L of the transistor 200 is preferably smaller than at least the channel width W of the transistor 200. The channel length L of the transistor 200 is preferably greater than or equal to 0.1 times and less than or equal to 0.99 times the channel width W of the transistor 200, further preferably greater than or equal to 0.5 times and less than or equal to 0.8 times the channel width W of the transistor 200. This structure enables the transistor to have favorable electrical characteristics and high reliability.

In the case where the opening 290 is formed to be circular in the plan view, the oxide semiconductor layer 230, the insulating layer 250, and the conductive layer 260 are provided concentrically. This makes the distance between the conductive layer 260 and the oxide semiconductor layer 230 substantially uniform, so that a gate electric field can be substantially uniformly applied to the oxide semiconductor layer 230.

Although an example where the opening 290 is circular in the plan view is described in this embodiment, the present invention is not limited thereto. For example, the opening 290 may have, in the plan view, a substantially circular shape such as an elliptical shape, a polygonal shape such as a quadrangular shape, or a polygonal shape such as a quadrangular shape with rounded corners.

### <Materials of Components of Semiconductor Device>

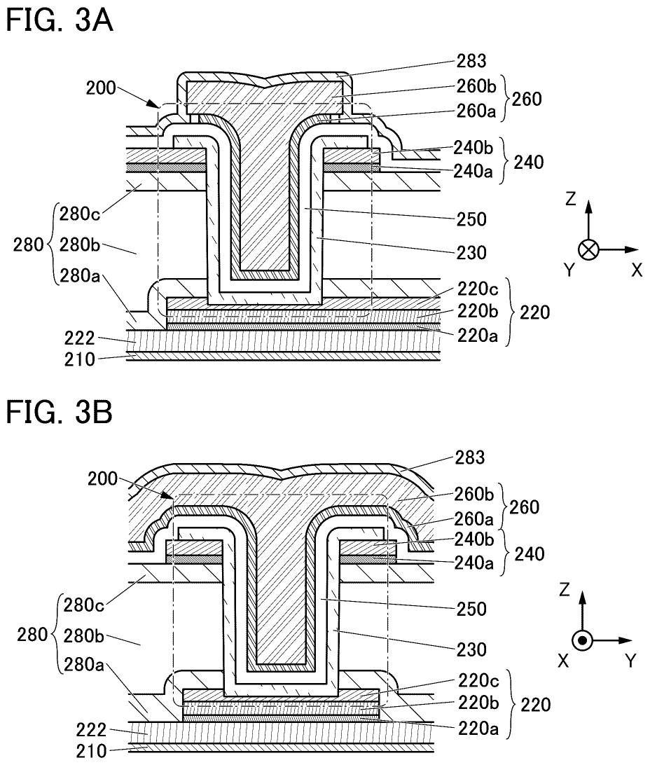

Materials that can be used for the semiconductor device of this embodiment are described below. Note that the layers included in the semiconductor device of this embodiment may have a single-layer structure or a stacked-layer structure. The conductive layer 220, the oxide semiconductor layer 230, the conductive layer 240, and the insulating layer 250 each have a single-layer structure in the example illustrated in FIG. 1B and FIG. 1C. FIG. 3A and FIG. 3B illustrate an example in which the conductive layer 220 and the conductive layer 240 each have a stacked-layer structure.

### [Oxide Semiconductor Layer 230]

As described above, the oxide semiconductor layer 230 includes the channel formation region. The channel formation region is an i-type (intrinsic) or substantially i-type region. The oxide semiconductor layer 230 further includes the source region and the drain region. The source region and the drain region are n-type regions (low-resistance regions) having a higher carrier concentration than the channel formation region.

There is no particular limitation on the crystallinity of the semiconductor material used for the oxide semiconductor layer 230, and any of an amorphous semiconductor, a single crystal semiconductor, and a semiconductor having other crystallinity than single crystal (a microcrystalline semiconductor, a polycrystalline semiconductor, or a semiconductor partly including crystal regions) may be used. A single crystal semiconductor or a semiconductor having crystallinity is preferably used, in which case deterioration of the transistor characteristics can be inhibited.

The band gap of the metal oxide functioning as a semiconductor is preferably wider than or equal to 2.0 eV, further preferably wider than or equal to 2.5 eV. The use of such a metal oxide having a wide band gap can reduce the off-state current of the transistor. The off-state current of the OS transistor is low, so that power consumption of the semiconductor device can be sufficiently reduced. The OS transistor has high frequency characteristics, which enables the semiconductor device to operate at high speed.

Examples of the metal oxide that can be used for the oxide semiconductor layer 230 include indium oxide, gallium oxide, and zinc oxide. The metal oxide preferably contains at least indium (In) or zinc (Zn). The metal oxide preferably contains two or three selected from indium, an element M, and zinc. The element M is a metal element or metalloid element that has a high bonding energy with oxygen and is, for example, a metal element or metalloid element whose bonding energy with oxygen is higher than that of indium. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M included in the metal oxide is preferably one or more of the above elements, further preferably one or more selected from aluminum, gallium, tin, and yttrium, and still further preferably gallium. In this specification and the like, a metal element and a metalloid element may be collectively referred to as a “metal element”, and a “metal element” in this specification and the like may refer to a metalloid element.

For example, the oxide semiconductor layer 230 can be formed using indium oxide (In oxide), indium zinc oxide (also referred to as In—Zn oxide or IZO (registered trademark)), indium tin oxide (In—Sn oxide), indium titanium oxide (In—Ti oxide), indium gallium oxide (In—Ga oxide), indium gallium aluminum oxide (In—Ga—Al oxide), indium gallium tin oxide (also referred to as In—Ga—Sn oxide or IGTO), gallium zinc oxide (also referred to as Ga—Zn oxide or GZO), aluminum zinc oxide (also referred to as Al—Zn oxide or AZO), indium aluminum zinc oxide (also referred to as In—Al—Zn oxide or IAZO), indium tin zinc oxide (also referred to as In—Sn—Zn oxide or ITZO (registered trademark)), indium titanium zinc oxide (In—Ti—Zn oxide), indium gallium zinc oxide (also referred to as In—Ga—Zn oxide or IGZO), indium gallium tin zinc oxide (also referred to as In—Ga—Sn—Zn oxide or IGZTO), or indium gallium aluminum zinc oxide (also referred to as In—Ga—Al—Zn oxide, IGAZO, IGZAO, or IAGZO). Alternatively, indium tin oxide containing silicon, gallium tin oxide (Ga—Sn oxide), aluminum tin oxide (Al—Sn oxide), or the like can be used.

By increasing the proportion of the number of indium atoms in the total number of atoms of all the metal elements included in the metal oxide, the field-effect mobility of the transistor can be increased. In addition, the transistor can have a high on-state current.

Note that the metal oxide may contain, instead of indium or in addition to indium, one or more metal elements with large period numbers. The larger the overlap between orbits of metal elements is, the more likely it is that the metal oxide will have high carrier conductivity. Thus, a transistor containing a metal element with a large period number can have high field-effect mobility in some cases. Examples of the metal element with a large period number include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more nonmetallic elements. By containing a nonmetallic element, the metal oxide sometimes has an increased carrier concentration, a reduced band gap, or the like, so that the transistor can have increased field-effect mobility in some cases. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements contained in the metal oxide, the metal oxide has high crystallinity, so that diffusion of impurities in the metal oxide can be inhibited. Consequently, a change in electrical characteristics of the transistor is inhibited, and the transistor can have higher reliability.

By increasing the proportion of the number of element M atoms in the total number of atoms of all the metal elements contained in the metal oxide, the metal oxide can have a wide band gap. In addition, formation of oxygen vacancies in the metal oxide can be inhibited. Accordingly, generation of carriers due to oxygen vacancies is inhibited, which makes the off-state current of the transistor low. Furthermore, a shift in the threshold voltage of the transistor can be inhibited. Furthermore, a change in electrical characteristics of the transistor is inhibited, and the transistor can have higher reliability.

The composition of the metal oxide used for the oxide semiconductor layer 230 affects the electrical characteristics and reliability of the transistor. Thus, by varying the composition of the metal oxide in accordance with the electrical characteristics and reliability required for the transistor, the semiconductor device can have both good electrical characteristics and high reliability.

When the metal oxide is an In-M-Zn oxide, the proportion of the number of In atoms is preferably higher than or equal to that of the number of M atoms in the In-M-Zn oxide. Examples of the atomic ratio of the metal elements of such an In-M-Zn oxide include In:M:Zn=1:1:0.5, In:M:Zn=1:1:1, In:M:Zn=1:1:1.2, In:M:Zn=1:1:2, In:M:Zn=2:1:3, In:M:Zn=3:1:1, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=6:1:6, In:M:Zn=5:2:5, and a composition in the neighborhood of any of the above atomic ratios. Note that the neighborhood of the atomic ratio includes ±30% of an intended atomic ratio. By increasing the proportion of the number of indium atoms in the metal oxide, the on-state current, field-effect mobility, or the like of the transistor can be increased.

The proportion of the number of In atoms may be less than that of the number of element M atoms in an In-M-Zn oxide. Examples of the atomic ratio of the metal elements of such an In-M-Zn oxide include In:M:Zn=1:3:2, In:M:Zn=1:3:3, In:M:Zn=1:3:4, and a composition in the neighborhood of any of these atomic ratios. By increasing the proportion of the number of M atoms in the metal oxide, generation of oxygen vacancies can be suppressed.

In the case where a plurality of metal elements are contained as the element M, the sum of the proportions of the numbers of atoms of these metal elements can be used as the proportion of the number of element M atoms.

In this specification and the like, the proportion of the number of indium atoms in the total number of atoms of all the metal elements contained is sometimes referred to as indium content percentage. The same applies to other metal elements.

In the case where the metal oxide is In—Zn oxide, examples of the atomic ratio of metal elements in the In—Zn oxide include In:Zn=1:1, In:Zn=2:1, In:Zn=4:1, and a composition in the neighborhood of any of these atomic ratios. In addition, the In—Zn oxide may contain a slight amount of the element M. For example, in the case where Sn is contained as the element M, examples of the atomic ratio of metal elements in the metal oxide include In:Sn:Zn=2:0.1:1, In:Sn:Zn=4:0.1:1, and a composition in the neighborhood of any of these atomic ratios.

Analysis of the composition of the metal oxide used for the oxide semiconductor layer 230 can be performed by energy dispersive X-ray spectrometry (EDX), X-ray photoelectron spectrometry (XPS), inductively coupled plasma-mass spectrometry (ICP-MS), or inductively coupled plasma-atomic emission spectrometry (ICP-AES), for example. Alternatively, two or more of these methods may be combined for the analysis. As for an element whose content percentage is low, the actual content percentage may be different from the content percentage obtained by analysis because of the influence of the analysis accuracy. In the case where the content percentage of the element Mis low, for example, the content percentage of the element M obtained by analysis may be lower than the actual content percentage.

A sputtering method or an ALD method can be suitably used for forming the metal oxide. Note that in the case where the metal oxide is formed by a sputtering method, the composition of the formed metal oxide film may be different from the composition of a target. In particular, the zinc content percentage of the formed metal oxide film may be reduced to approximately 50% of that of the target. The metal oxide film may be formed by a chemical vapor deposition (CVD) method, a molecular beam epitaxy (MBE) method, a pulsed laser deposition (PLD) method, or the like.

The oxide semiconductor layer 230 may have a stacked-layer structure including two or more metal oxide layers. The two or more metal oxide layers included in the oxide semiconductor layer 230 may have the same composition or substantially the same compositions. When the compositions of the stacked metal oxide layers are the same, they can be formed using the same sputtering target, for example, and the manufacturing cost can thus be reduced.

The two or more metal oxide layers included in the oxide semiconductor layer 230 may have different compositions.

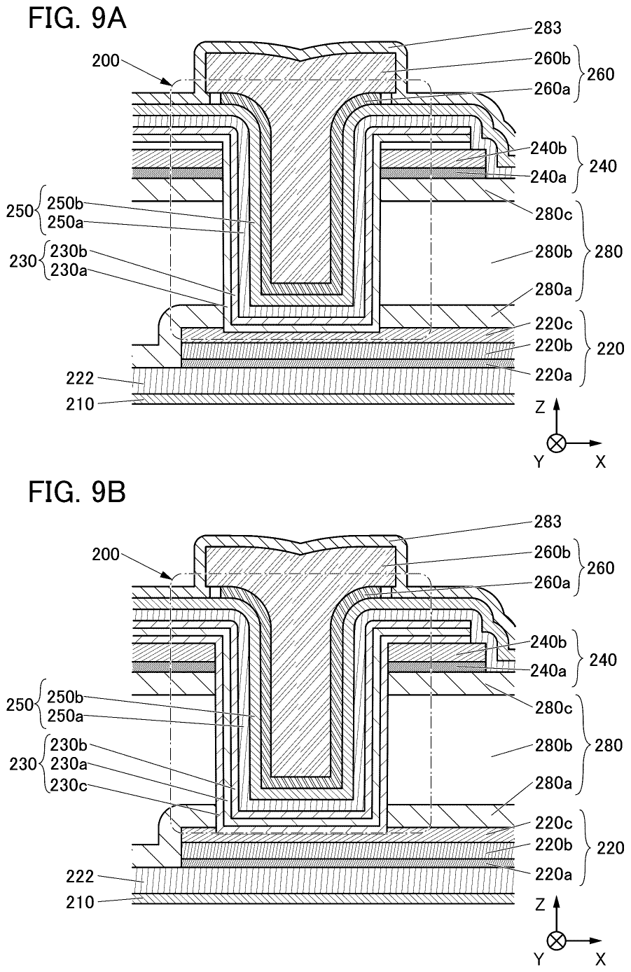

The oxide semiconductor layer 230 can have a two-layer structure, for example. FIG. 9A illustrates an example where the oxide semiconductor layer 230 has a two-layer structure of an oxide layer 230a and an oxide layer 230b over the oxide layer 230a in the structure illustrated in FIG. 1B.

The oxide layer 230a is preferably formed using a material having higher conductivity than the oxide layer 230b, for example. When a material having high conductivity is used for the oxide layer 230a, which is in contact with the source electrode and the drain electrode (the conductive layer 220 and the conductive layer 240), the contact resistance between the oxide semiconductor layer 230 and the conductive layer 220 and the contact resistance between the oxide semiconductor layer 230 and the conductive layer 240 can be reduced, so that the transistor can have a high on-state current.

Here, when a material having high conductivity is used for the oxide layer 230b, which is provided closer to the conductive layer 260 functioning as the gate electrode, the threshold voltage of the transistor 200 is shifted and a drain current flowing at the time when the gate voltage is 0 V (hereinafter also referred to as a cutoff current) becomes high in some cases. Specifically, the threshold voltage might be low when the transistor 200 is an n-channel transistor. Thus, the oxide layer 230b is preferably formed using a material having lower conductivity than the oxide layer 230a. Accordingly, in the case where the transistor 200 is an n-channel transistor, the transistor can have a high threshold voltage and a low cutoff current. Note that a low cutoff current is sometimes referred to as normally-off.

When the oxide semiconductor layer 230 has a stacked-layer structure and the oxide layer 230a is formed using a material having higher conductivity than the oxide layer 230b, as described above, the transistor can have normally-off characteristics and a high on-state current. Consequently, the semiconductor device can have both low power consumption and high performance.

The carrier concentration of the oxide layer 230a is preferably higher than that of the oxide layer 230b. When the carrier concentration of the oxide layer 230a is increased, the conductivity is increased and the contact resistance between the oxide semiconductor layer 230 and the conductive layer 220 and the contact resistance between the oxide semiconductor layer 230 and the conductive layer 240 can be reduced, so that the transistor can have a high on-state current. When the carrier concentration of the oxide layer 230b is reduced, the conductivity is reduced, so that the transistor can have normally-off characteristics.

Note that the structure of the oxide semiconductor layer 230 is not limited to the above-described structure, and the oxide layer 230a may be formed using a material having lower conductivity than the oxide layer 230b. The carrier concentration of the oxide layer 230a may be lower than that of the oxide layer 230b.

The band gap of a first metal oxide used for the oxide layer 230a is preferably different from the band gap of a second metal oxide used for the oxide layer 230b. For example, the difference between the band gap of the first metal oxide and the band gap of the second metal oxide is preferably greater than or equal to 0.1 eV, further preferably greater than or equal to 0.2 eV, still further preferably greater than or equal to 0.3 eV.

The band gap of the first metal oxide used for the oxide layer 230a is preferably narrower than the band gap of the second metal oxide used for the oxide layer 230b. In that case, the contact resistance between the oxide semiconductor layer 230 and the conductive layer 220 and the contact resistance between the oxide semiconductor layer 230 and the conductive layer 240 can be reduced, so that the transistor can have a high on-state current. In the case where the transistor 200 is an n-channel transistor, the transistor can have a high threshold voltage and normally-off characteristics. Furthermore, when the second metal oxide has a wide band gap, carriers can be inhibited from being generated and induced in the oxide layer 230b and at the interface between the oxide layer 230b and the insulating layer 250. This can improve the reliability of the transistor.

For example, the content percentage of the element M in the first metal oxide is preferably lower than that of the element M in the second metal oxide. Specifically, for example, it is preferable that the oxide layer 230a be formed using a metal oxide with a composition of In:M:Zn=1:1:1 [atomic ratio] or in the neighborhood thereof and the oxide layer 230b be formed using a metal oxide with a composition of In:M:Zn=1:3:2 [atomic ratio] or in the neighborhood thereof. In that case, it is particularly preferable to use one or more of gallium, aluminum, and tin as the element M.

Note that the structure of the oxide semiconductor layer 230 is not limited to the above-described structure, and the band gap of the first metal oxide may be wider than that of the second metal oxide.

The content percentage of the element M in the first metal oxide is preferably lower than that of the element M in the second metal oxide. The first metal oxide may contain no or a slight amount of the element M. For example, the first metal oxide used for the oxide layer 230a is preferably In—Zn oxide, and the second metal oxide used for the oxide layer 230b is preferably an In-M-Zn oxide. Specifically, the first metal oxide can be In—Zn oxide, and the second metal oxide can be In—Ga—Zn oxide.

For example, for the oxide layer 230a, it is preferable to use a metal oxide with a composition of In:Zn=1:1 [atomic ratio] or in the neighborhood thereof, a metal oxide with a composition of In:Zn=2:1 [atomic ratio] or in the neighborhood thereof, a metal oxide with a composition of In:Sn:Zn=2:0.1:1 [atomic ratio] or in the neighborhood thereof, a metal oxide with a composition of In:Zn=4:1 [atomic ratio] or in the neighborhood thereof, a metal oxide with a composition of In:Sn:Zn=4:0.1:1 [atomic ratio] or in the neighborhood thereof, or indium oxide. For the oxide layer 230b, it is preferable to use a metal oxide with a composition of In:Ga:Zn=1:1:1 [atomic ratio] or in the neighborhood thereof, a metal oxide with a composition of In:Ga:Zn=1:3:2 [atomic ratio] or in the neighborhood thereof, or a metal oxide with a composition of In:Ga:Zn=1:3:4 [atomic ratio] or in the neighborhood thereof. In that case, the transistor 200 can have a high on-state current and high reliability with small variations.

Note that the structure of the oxide semiconductor layer 230 is not limited to the above-described structure, and the content percentage of the element M in the first metal oxide may be higher than that of the element M in the second metal oxide.

It is preferable that the oxide semiconductor layer 230 include a metal oxide layer having crystallinity. Examples of the structure of a metal oxide having crystallinity include a CAAC (c-axis aligned crystal) structure, a polycrystalline structure, and a nano-crystal (nc) structure. By using a metal oxide layer having crystallinity as the oxide semiconductor layer 230, the density of defect states in the oxide semiconductor layer 230 can be reduced, which enables the semiconductor device to have high reliability.

The higher the crystallinity of the metal oxide layer used as the oxide semiconductor layer 230 is, the lower the density of defect states in the oxide semiconductor layer 230 can be. By contrast, the use of a metal oxide layer having low crystallinity achieves a transistor through which a large amount of current can flow.

In the case where the metal oxide layer is formed by a sputtering method, the higher the substrate temperature (the stage temperature) in the formation is, the higher the crystallinity of the formed metal oxide layer can be. Furthermore, the higher the proportion of the flow rate of an oxygen gas to the flow rate of the whole film formation gas (hereinafter, also referred to as an oxygen flow rate ratio) used in the formation is, the higher the crystallinity of the formed metal oxide layer can be.

The crystallinity of the oxide semiconductor layer 230 can be analyzed with X-ray diffraction (XRD), a transmission electron microscope (TEM), or electron diffraction (ED), for example. Alternatively, two or more of these methods may be combined for the analysis.

The oxide semiconductor layer 230 may have a stacked-layer structure of two or more metal oxide layers having different crystallinities. For example, in a stacked-layer structure of a first metal oxide layer and a second metal oxide layer over the first metal oxide layer, the second metal oxide layer can include a region having higher crystallinity than the first metal oxide layer. Alternatively, the second metal oxide layer can include a region having lower crystallinity than the first metal oxide layer. In that case, the composition of the first metal oxide layer may be different from, the same as, or substantially the same as that of the second metal oxide layer.

For example, it is preferable that the oxide layer 230a be formed using a metal oxide with a composition of In:M:Zn=1:3:2 [atomic ratio] or in the neighborhood thereof or a metal oxide with a composition of In:M:Zn=1:3:4 [atomic ratio] or in the neighborhood thereof, and that the oxide layer 230b be formed using a metal oxide with a composition of In:M:Zn=1:1:1 [atomic ratio] or in the neighborhood thereof. When the oxide layer 230a is formed using a metal oxide in which the ratio of Zn to In is high, the crystallinity of the oxide layer 230a can be increased. Furthermore, when the oxide layer 230b is formed over the oxide layer 230a with high crystallinity, the crystallinity of the oxide layer 230b can be easily increased. This can increase the crystallinity of the whole oxide semiconductor layer 230, which is preferable. In this case, it is particularly preferable to use gallium, aluminum, or tin as the element M. For example, two IGZO layers having different compositions may be stacked. For another example, a stacked-layer structure of one selected from indium oxide, indium gallium oxide, and IGZO, and one selected from IAZO, IAGZO, and ITZO (registered trademark) may be employed.

As illustrated in FIG. 9B, the oxide semiconductor layer 230 can also have a three-layer structure of an oxide layer 230c, the oxide layer 230a over the oxide layer 230c, and the oxide layer 230b over the oxide layer 230a.

The above-described structure can be applied to each of the oxide layer 230a and the oxide layer 230b. The structure of the oxide layer 230c can be similar to the structure that can be applied to the oxide layer 230b.

For example, for the oxide layer 230a, it is preferable to use a metal oxide with a composition of In:Zn=1:1 [atomic ratio] or in the neighborhood thereof, a metal oxide with a composition of In:Zn=2:1 [atomic ratio] or in the neighborhood thereof, a metal oxide with a composition of In:Sn:Zn=2:0.1:1 [atomic ratio] or in the neighborhood thereof, a metal oxide with a composition of In:Zn=4:1 [atomic ratio] or in the neighborhood thereof, a metal oxide with a composition of In:Sn:Zn=4:0.1:1 [atomic ratio] or in the neighborhood thereof, or indium oxide. For each of the oxide layer 230b and the oxide layer 230c, it is preferable to use a metal oxide with a composition of In:Ga:Zn=1:1:1 [atomic ratio] or in the neighborhood thereof, a metal oxide with a composition of In:Ga:Zn=1:3:2 [atomic ratio] or in the neighborhood thereof, or a metal oxide with a composition of In:Ga:Zn=1:3:4 [atomic ratio] or in the neighborhood thereof.

The oxide layer 230b and the oxide layer 230c each preferably have a wider band gap than the oxide layer 230a. In that case, the oxide layer 230a is sandwiched between the oxide layer 230b and the oxide layer 230c each having a wide band gap, and the oxide layer 230a mainly functions as a current path (channel). When the oxide layer 230a is sandwiched between the oxide layer 230b and the oxide layer 230c, the trap states at the interfaces with the oxide layer 230a and the vicinity thereof can be reduced. Accordingly, a buried-channel transistor where the channel is away from the interface with an insulating layer can be achieved, whereby the field-effect mobility can be increased. Furthermore, the influence of interface states that might be formed on the back channel side is reduced, so that light deterioration (e.g., light negative bias deterioration) of the transistor can be inhibited and the reliability of the transistor can be increased.

The thickness of the oxide semiconductor layer 230 is preferably greater than or equal to 3 nm and less than or equal to 200 nm, further preferably greater than or equal to 3 nm and less than or equal to 100 nm, still further preferably greater than or equal to 5 nm and less than or equal to 100 nm, yet still further preferably greater than or equal to 10 nm and less than or equal to 100 nm, yet still further preferably greater than or equal to 10 nm and less than or equal to 70 nm, yet still further preferably greater than or equal to 15 nm and less than or equal to 70 nm, yet still further preferably greater than or equal to 15 nm and less than or equal to 50 nm, yet still further preferably greater than or equal to 20 nm and less than or equal to 50 nm. In a transistor used for a miniaturized semiconductor device, the thickness of the oxide semiconductor layer 230 is preferably greater than or equal to 1 nm, greater than or equal to 3 nm, or greater than or equal to 5 nm and less than or equal to 20 nm, less than or equal to 15 nm, less than or equal to 12 nm, or less than or equal to 10 nm.

Hydrogen contained in the oxide semiconductor reacts with oxygen bonded to a metal atom to be water, and thus sometimes forms an oxygen vacancy (Vo) in the oxide semiconductor. A defect where hydrogen enters an oxygen vacancy (hereinafter, referred to as VoH) serves as a donor and generates an electron serving as a carrier in some cases. In other cases, bonding of part of hydrogen to oxygen bonded to a metal atom generates an electron serving as a carrier. Thus, a transistor including an oxide semiconductor that contains a large amount of hydrogen is likely to have normally-on characteristics (i.e., a negative threshold voltage value). Moreover, hydrogen in an oxide semiconductor is easily transferred by a stress such as heat or an electric field; thus, a large amount of hydrogen in an oxide semiconductor might degrade the reliability of a transistor.

The amount of VoH in the oxide semiconductor layer 230 is preferably reduced as much as possible so that the oxide semiconductor layer 230 becomes a highly purified intrinsic or substantially highly purified intrinsic oxide semiconductor layer. In order to obtain such an oxide semiconductor with sufficiently reduced VoH, it is important to remove impurities such as water and hydrogen in the oxide semiconductor (which is sometimes described as dehydration or dehydrogenation treatment) and to repair oxygen vacancies by supplying oxygen to the oxide semiconductor. When an oxide semiconductor with a sufficiently reduced amount of impurities such as VoH is used for the channel formation region of the transistor, the transistor can have stable electrical characteristics. Note that repairing oxygen vacancies by supplying oxygen to an oxide semiconductor is sometimes referred to as oxygen adding treatment.

The carrier concentration of the oxide semiconductor in a region functioning as the channel formation region is preferably lower than or equal to 1×10¹⁸ cm⁻³, further preferably lower than 1×10¹⁷ cm⁻³, still further preferably lower than 1× 10¹⁶ cm⁻³, yet still further preferably lower than 1×10¹³ cm⁻³, and yet still further preferably lower than 1×10¹² cm⁻³. Note that the lower limit of the carrier concentration of the oxide semiconductor in the region functioning as the channel formation region is not particularly limited and can be, for example, 1×10⁻⁹ cm⁻³.

The influence of impurities in the metal oxide (oxide semiconductor) will be described here.

When an oxide semiconductor contains silicon or carbon, which is a Group 14 element, defect states are formed in the oxide semiconductor. Thus, the carbon concentration in the channel formation region of the oxide semiconductor, which is obtained by SIMS, is lower than or equal to 1×10²⁰ atoms/cm³, preferably lower than or equal to 5×10¹⁹ atoms/cm³, further preferably lower than or equal to 3×10¹⁹ atoms/cm³, still further preferably lower than or equal to 1×10¹⁹ atoms/cm³, yet still further preferably lower than or equal to 3× 10¹⁸ atoms/cm³, yet still further preferably lower than or equal to 1×10¹⁸ atoms/cm³. The silicon concentration in the channel formation region of the oxide semiconductor, which is obtained by SIMS, is lower than or equal to 1×10²⁰ atoms/cm³, preferably lower than or equal to 5×10¹⁹ atoms/cm³, further preferably lower than or equal to 3×10¹⁹ atoms/cm³, still further preferably lower than or equal to 1×10¹⁹ atoms/cm³, yet still further preferably lower than or equal to 3×10¹⁸ atoms/cm³, yet still further preferably lower than or equal to 1×10¹⁸ atoms/cm³.

Furthermore, when the oxide semiconductor contains nitrogen, the oxide semiconductor easily becomes n-type by generation of electrons serving as carriers and an increase in carrier concentration. As a result, a transistor including, as a semiconductor, an oxide semiconductor that contains nitrogen tends to have normally-on characteristics. When nitrogen is contained in the oxide semiconductor, a trap state is sometimes formed. This might make the electrical characteristics of the transistor unstable. Thus, the nitrogen concentration in the channel formation region of the oxide semiconductor, which is obtained by SIMS, is lower than or equal to 1×10²⁰ atoms/cm³, preferably lower than or equal to 5×10¹⁹ atoms/cm³, further preferably lower than or equal to 1×10¹⁹ atoms/cm³, still further preferably lower than or equal to 5×10¹⁸ atoms/cm³, yet still further preferably lower than or equal to 1× 10¹⁸ atoms/cm³, yet still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. In other cases, bonding of part of hydrogen to oxygen bonded to a metal atom generates an electron serving as a carrier. Thus, a transistor including an oxide semiconductor that contains hydrogen tends to have normally-on characteristics. For this reason, hydrogen in the channel formation region of the oxide semiconductor is preferably reduced as much as possible. Specifically, the hydrogen concentration in the channel formation region of the oxide semiconductor, which is obtained by SIMS, is lower than 1×10²⁰ atoms/cm³, preferably lower than 5×10¹⁹ atoms/cm³, further preferably lower than 1×10¹⁹ atoms/cm³, still further preferably lower than 5×10¹⁸ atoms/cm³, yet still further preferably lower than 1×10¹⁸ atoms/cm³.

When the oxide semiconductor contains an alkali metal or an alkaline earth metal, defect states are formed and carriers are generated in some cases. Accordingly, a transistor including an oxide semiconductor that contains an alkali metal or an alkaline earth metal tends to have normally-on characteristics. Thus, the concentration of an alkali metal or an alkaline earth metal in the channel formation region of the oxide semiconductor, which is obtained by SIMS, is lower than or equal to 1× 10¹⁸ atoms/cm³, preferably lower than or equal to 2× 10¹⁶ atoms/cm³.

When an oxide semiconductor with sufficiently reduced impurities is used for a channel formation region of a transistor, the transistor can have stable electrical characteristics.

Note that for the semiconductor device of this embodiment, a transistor including a different semiconductor material in its channel formation region may be used. Examples of the different semiconductor material include a single-element semiconductor and a compound semiconductor. Examples of the single-element semiconductor include silicon and germanium. Examples of the compound semiconductor include gallium arsenide and silicon germanium. Other examples of the compound semiconductor include an organic semiconductor and a nitride semiconductor. Note that the above-described oxide semiconductor is also a kind of compound semiconductor. These semiconductor materials may contain an impurity as a dopant.

Examples of silicon that can be used as a semiconductor material of the transistor include single crystal silicon, polycrystalline silicon, microcrystalline silicon, and amorphous silicon. An example of polycrystalline silicon is low-temperature polysilicon (LTPS).

The semiconductor layer of the transistor may include a layered substance that functions as a semiconductor. The layered substance generally refers to a group of materials having a layered crystal structure. In the layered crystal structure, layers formed by covalent bonding or ionic bonding are stacked with bonding such as the van der Waals force, which is weaker than covalent bonding or ionic bonding. The layered substance has high electrical conductivity in a unit layer, that is, high two-dimensional electrical conductivity. When a material that functions as a semiconductor and has high two-dimensional electrical conductivity is used for the channel formation region, the transistor can have a high on-state current.

Examples of the layered substance include graphene, silicene, and chalcogenide. Chalcogenide is a compound containing chalcogen (an element belonging to Group 16). Examples of chalcogenide include transition metal chalcogenide and chalcogenide of Group 13 elements. Specific examples of the transition metal chalcogenide which can be used for a semiconductor layer of a transistor include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

### [Insulating Layer]

An inorganic insulating film is preferably used for each of the insulating layers (the insulating layer 210, the insulating layer 250, the insulating layer 280, the insulating layer 283, an insulating layer 285, and the like) included in the semiconductor device. Examples of the inorganic insulating film include an oxide insulating film, a nitride insulating film, an oxynitride insulating film, and a nitride oxide insulating film. Examples of the oxide insulating film include a silicon oxide film, an aluminum oxide film, a magnesium oxide film, a gallium oxide film, a germanium oxide film, an yttrium oxide film, a zirconium oxide film, a lanthanum oxide film, a neodymium oxide film, a hafnium oxide film, a tantalum oxide film, a cerium oxide film, a gallium zinc oxide film, and a hafnium aluminate film. Examples of the nitride insulating film include a silicon nitride film and an aluminum nitride film. Examples of the oxynitride insulating film include a silicon oxynitride film, an aluminum oxynitride film, a gallium oxynitride film, an yttrium oxynitride film, and a hafnium oxynitride film. Examples of the nitride oxide insulating film include a silicon nitride oxide film and an aluminum nitride oxide film. An organic insulating film may be used for the insulating layer included in the semiconductor device.

As miniaturization and high integration of transistors progress, for example, a problem such as a leakage current may arise because of a thinner gate insulating layer. When a high-k material is used for the gate insulating layer, the voltage at the time of operation of the transistor can be reduced while the physical thickness is maintained. In addition, the equivalent oxide thickness (EOT) of the gate insulating layer can be reduced. By contrast, when a material with low relative permittivity is used for the insulating layer functioning as an interlayer film, parasitic capacitance generated between wirings can be reduced. Thus, a material is preferably selected in accordance with the function of an insulating layer. Note that a material with low relative permittivity is a material with high dielectric strength.

Examples of a high relative permittivity (high-k) material include aluminum oxide, gallium oxide, hafnium oxide, tantalum oxide, zirconium oxide, hafnium zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of a material with low relative permittivity include inorganic insulating materials such as silicon oxide, silicon oxynitride, and silicon nitride oxide, and resins such as polyester, polyolefin, polyamide (e.g., nylon and aramid), polyimide, polycarbonate, and an acrylic resin. Other examples of an inorganic insulating material with low relative permittivity include silicon oxide to which fluorine is added, silicon oxide to which carbon is added, and silicon oxide to which carbon and nitrogen are added. Another example is porous silicon oxide. Note that these silicon oxides may contain nitrogen.

A material that can have ferroelectricity may be used for the insulating layer included in the semiconductor device. Examples of the material that can have ferroelectricity include metal oxides such as hafnium oxide, zirconium oxide, and HfZrO_{X} (X is a real number greater than 0). Examples of the material that can have ferroelectricity also include a material in which an element J1 (the element J1 here is one or more selected from zirconium, silicon, aluminum, gadolinium, yttrium, lanthanum, strontium, and the like) is added to hafnium oxide. Here, the ratio of the number of hafnium atoms to the number of element J1 atoms can be set as appropriate; the ratio of the number of hafnium atoms to the number of element J1 atoms is, for example, 1:1 or in the neighborhood thereof. Examples of the material that can have ferroelectricity also include a material in which an element J2 (the element J2 here is one or more selected from hafnium, silicon, aluminum, gadolinium, yttrium, lanthanum, strontium, and the like) is added to zirconium oxide. The ratio of the number of zirconium atoms to the number of element J2 atoms can be set as appropriate; the ratio of the number of zirconium atoms to the number of element J2 atoms is, for example, 1:1 or in the neighborhood thereof. As the material that can have ferroelectricity, a piezoelectric ceramic having a perovskite structure, such as lead titanate (PbTiO_{X}), barium strontium titanate (BST), strontium titanate, lead zirconate titanate (PZT), strontium bismuth tantalate (SBT), bismuth ferrite (BFO), or barium titanate, may be used.

Examples of the material that can have ferroelectricity also include a metal nitride containing an element M1, an element M2, and nitrogen. Here, the element M1 is one or more selected from aluminum, gallium, indium, and the like. The element M2 is one or more selected from boron, scandium, yttrium, lanthanum, cerium, neodymium, europium, titanium, zirconium, hafnium, vanadium, niobium, tantalum, chromium, and the like. Note that the ratio of the number of element M1 atoms to the number of element M2 atoms can be set as appropriate. A metal oxide containing the element M1 and nitrogen has ferroelectricity in some cases even though the metal oxide does not contain the element M2. Examples of the material that can have ferroelectricity also include a material in which an element M3 is added to the above metal nitride. Note that the element M3 is one or more selected from magnesium, calcium, strontium, zinc, cadmium, and the like. Here, the ratio of the number of element M1 atoms to the number of element M2 atoms to the number of element M3 atoms can be set as appropriate.

Examples of the material that can have ferroelectricity also include a perovskite-type oxynitride such as SrTaO₂N or BaTaO₂N, GaFeO₃ with a K-alumina-type structure, and the like.

In the above description, metal oxides and metal nitrides are presented as non-limiting examples. For example, a metal oxynitride in which nitrogen is added to any of the above metal oxides, a metal nitride oxide in which oxygen is added to any of the above metal nitrides, or the like may be used.

The material that can have ferroelectricity can be, for example, a mixture or a compound formed of a plurality of materials selected from the above-listed materials. Alternatively, the insulating layer can have a stacked-layer structure of a plurality of materials selected from the above-listed materials. As a side note, since the crystal structures (properties) of the above-listed materials and the like can be changed depending on the processes as well as the film formation conditions, only a material that exhibits ferroelectricity is referred to as a material that can have ferroelectricity as well as a ferroelectric in this specification and the like.

A metal oxide containing one or both of hafnium and zirconium can have ferroelectricity even when being processed into a thin film of several nanometers. A metal oxide containing one or both of hafnium and zirconium can have ferroelectricity even with a minute area. Accordingly, the use of a metal oxide containing one or both of hafnium and zirconium enables miniaturization of the semiconductor device.

Note that in this specification and the like, a layer of the material that can have ferroelectricity is referred to as a ferroelectric layer, a metal oxide film, or a metal nitride film in some cases. Furthermore, a device including such a ferroelectric layer, metal oxide film, or metal nitride film is sometimes referred to as a ferroelectric device in this specification and the like.

It is considered that ferroelectricity is exhibited by displacement of oxygen or nitrogen of a crystal included in a ferroelectric layer due to an external electric field. Ferroelectricity is presumably exhibited depending on a crystal structure of a crystal included in a ferroelectric layer. Thus, in order that the insulating layer can exhibit ferroelectricity, the insulating layer needs to include a crystal. It is particularly preferable that the insulating layer include a crystal having an orthorhombic crystal structure to exhibit ferroelectricity. Note that a crystal structure of a crystal included in the insulating layer may be one or more selected from a cubic crystal structure, a tetragonal crystal structure, an orthorhombic crystal structure, a monoclinic crystal structure, and a hexagonal crystal structure. Alternatively, the insulating layer may have an amorphous structure. In that case, the insulating layer may have a composite structure including an amorphous structure and a crystal structure.

A transistor including a metal oxide can have stable electrical characteristics when surrounded by an insulating layer having a function of inhibiting passage of impurities and oxygen. As the insulating layer having a function of inhibiting passage of impurities and oxygen, a single insulating layer or stacked insulating layers including one or more selected from boron, carbon, nitrogen, oxygen, fluorine, magnesium, aluminum, silicon, phosphorus, chlorine, argon, gallium, germanium, yttrium, zirconium, lanthanum, neodymium, hafnium, and tantalum can be used, for example. Specifically, as a material for the insulating layer having a function of inhibiting passage of impurities and oxygen, a metal oxide such as aluminum oxide, magnesium oxide, gallium oxide, germanium oxide, yttrium oxide, zirconium oxide, lanthanum oxide, neodymium oxide, hafnium oxide, or tantalum oxide or a metal nitride such as aluminum nitride, silicon nitride oxide, or silicon nitride can be used.

Specific examples of the insulating layer having a function of inhibiting passage of oxygen and impurities such as water and hydrogen include metal oxides such as aluminum oxide, magnesium oxide, gallium oxide, germanium oxide, yttrium oxide, zirconium oxide, lanthanum oxide, neodymium oxide, hafnium oxide, and tantalum oxide. Other examples of the insulating layer having a function of inhibiting passage of oxygen and impurities such as water and hydrogen include oxides containing aluminum and hafnium (hafnium aluminate). Other examples of the insulating layer having a function of inhibiting passage of oxygen and impurities such as water and hydrogen include metal nitrides such as aluminum nitride, silicon nitride oxide, and silicon nitride.

An insulating layer in contact with an oxide semiconductor layer, such as a gate insulating layer, or an insulating layer provided in the vicinity of the oxide semiconductor layer preferably includes a region containing oxygen that is released by heating (hereinafter, sometimes referred to as excess oxygen). For example, when an insulating layer including a region containing excess oxygen is in contact with an oxide semiconductor layer or positioned in the vicinity of the oxide semiconductor layer, oxygen vacancies in the oxide semiconductor layer can be reduced. Examples of an insulating layer in which a region containing excess oxygen is easily formed include silicon oxide, silicon oxynitride, and porous silicon oxide.

Since the insulating layer 210 functions as an interlayer film, the insulating layer 210 preferably has low relative permittivity. When a material with low relative permittivity is used for an interlayer film, parasitic capacitance generated between wirings can be reduced. Silicon oxide and silicon oxynitride are thermally stable, and thus are suitable for the insulating layer 210.

The concentration of impurities such as water and hydrogen in the insulating layer 210 is preferably reduced. In that case, entry of impurities such as water and hydrogen into the channel formation region of the oxide semiconductor layer 230 can be inhibited.

As the insulating layer 210, a barrier insulating layer against hydrogen is preferably used. When the insulating layer 210 provided outside the oxide semiconductor layer 230 has a barrier property against hydrogen, diffusion of hydrogen into the oxide semiconductor layer 230 can be inhibited.

Examples of a material for the barrier insulating layer against hydrogen include aluminum oxide, magnesium oxide, hafnium oxide, gallium oxide, indium gallium zinc oxide, silicon nitride, and silicon nitride oxide.

Note that in this specification and the like, a barrier insulating layer refers to an insulating layer having a barrier property. In addition, the barrier property refers to a property that does not easily allow diffusion of a target substance (also referred to as a property that does not easily allow passage of a target substance, a property with low permeability to a target substance, or a function of inhibiting diffusion of a target substance). Note that hydrogen described as a target substance refers to at least one of a hydrogen atom, a hydrogen molecule, and a substance bonded to hydrogen, such as a water molecule or OH⁻, for example. Unless otherwise specified, an impurity described as a target substance refers to an impurity in a channel formation region or a semiconductor layer, and for example, refers to at least one of a hydrogen atom, a hydrogen molecule, a water molecule, a nitrogen atom, a nitrogen molecule, a nitrogen oxide molecule (e.g., N₂O, NO, or NO₂), and a copper atom. Oxygen described as a target substance refers to, for example, at least one of an oxygen atom and an oxygen molecule.

For example, a silicon nitride film is preferably used for the insulating layer 210.

The insulating layer 280 preferably includes the above-described barrier insulating layer against hydrogen. The insulating layer 280 is provided to surround the oxide semiconductor layer 230. When the insulating layer 280 provided outside the oxide semiconductor layer 230 has a barrier property against hydrogen, diffusion of hydrogen into the oxide semiconductor layer 230 can be inhibited. For example, the insulating layer 280 preferably includes a silicon nitride film.

Note that silicon nitride also has a barrier property against oxygen. Thus, using silicon nitride for the insulating layer 280 can inhibit extraction of oxygen from the oxide semiconductor layer 230 and formation of an excess amount of oxygen vacancies in the oxide semiconductor layer 230.

Furthermore, when silicon nitride is used for the insulating layer 280, excess oxygen can be prevented from being supplied to the oxide semiconductor layer 230. Thus, the channel formation region of the oxide semiconductor layer 230 can be prevented from containing excess oxygen, whereby the reliability of the transistor 200 can be improved.

The insulating layer 280 preferably includes any of an oxide insulating film, an oxynitride insulating film, and an insulating layer including a region containing excess oxygen, which are described above.

For example, the insulating layer including a region containing excess oxygen can be formed by a sputtering method in an oxygen-containing atmosphere. With the use of a sputtering method, which does not need to use a molecule containing hydrogen in a film formation gas, the hydrogen concentration in the insulating layer 280 can be reduced. When the insulating layer 280 is formed in this manner, oxygen can be supplied from the insulating layer 280 to the channel formation region of the oxide semiconductor layer 230, so that oxygen vacancies and VoH therein can be reduced.

The concentration of impurities such as water and hydrogen in the insulating layer 280 is preferably reduced. In that case, entry of impurities such as water and hydrogen into the channel formation region of the oxide semiconductor layer 230 can be inhibited.

Note that since the thickness of the insulating layer 280 over the conductive layer 220 corresponds to the channel length of the transistor 200, the thickness of the insulating layer 280 is set as appropriate in accordance with the design value of the channel length of the transistor 200.

For example, a single-layer structure of a silicon nitride film is preferably used for the insulating layer 280. Alternatively, for example, a three-layer structure where a silicon nitride film, a silicon oxide film, and a silicon nitride film are stacked in this order is preferably used for the insulating layer 280.

The insulating layer 250 preferably has a function of trapping hydrogen and fixing hydrogen. In that case, the hydrogen concentration of the oxide semiconductor layer 230 (in particular, the hydrogen concentration in the channel formation region of the transistor) can be reduced. Accordingly, VoH in the channel formation region can be reduced, so that the channel formation region can be an i-type or substantially i-type region.

Examples of a material for an insulating layer having a function of capturing or fixing hydrogen include metal oxides such as an oxide containing hafnium, an oxide containing magnesium, an oxide containing aluminum, and an oxide containing aluminum and hafnium (hafnium aluminate). These metal oxides may further contain zirconium, and an example of such a metal oxide is an oxide containing hafnium and zirconium. In a metal oxide having an amorphous structure, some oxygen atoms have a dangling bond, which allows the metal oxide to have a high capability of capturing or fixing hydrogen. Thus, these metal oxides preferably have an amorphous structure. For example, these oxides may have an amorphous structure by containing silicon. For example, an oxide containing hafnium and silicon (hafnium silicate) is preferably used. Note that the metal oxide includes one or both of a crystal region and a crystal grain boundary in some cases.

Note that a function of capturing or fixing a target substance can be rephrased as a property that does not easily allow diffusion of a target substance. Thus, a function of capturing or fixing a target substance can be rephrased as a barrier property.

The insulating layer 250 can have a two-layer structure. In each of the examples illustrated in FIG. 9A and FIG. 9B, the insulating layer 250 in the structure illustrated in FIG. 1B has a two-layer structure of an insulating layer 250a and an insulating layer 250b over the insulating layer 250a.

In the case where the insulating layer 250 has a stacked-layer structure, a layer that is in contact with the oxide semiconductor layer 230 preferably has a function of capturing hydrogen and fixing hydrogen. That is, in FIG. 2A and FIG. 2B, the insulating layer 250a preferably has a function of capturing hydrogen and fixing hydrogen. As the insulating layer 250b, the above-described barrier insulating layer against hydrogen is preferably used.

When the insulating layer 250a has a function of capturing or fixing hydrogen, hydrogen contained in the oxide semiconductor layer 230 can be captured or fixed more effectively. Thus, the hydrogen concentration in the oxide semiconductor layer 230 can be lowered. For the insulating layer 250a, for example, hafnium silicate or the like is preferably used. The insulating layer 250a preferably has an amorphous structure.

When the insulating layer 250a has an amorphous structure, formation of a crystal grain boundary can be inhibited. Inhibiting formation of a crystal grain boundary results in higher film planarity of the insulating layer 250a. This enables the insulating layer 250a to have uniform thickness distribution and a reduced number of extremely thin portions, so that the breakdown voltage of the insulating layer 250a can be increased. Furthermore, the thickness distribution of the film provided over the insulating layer 250a can be uniform.

Furthermore, inhibiting formation of a crystal grain boundary in the insulating layer 250a can reduce a leakage current due to the defect states in the crystal grain boundary. Thus, the insulating layer 250a can function as an insulating film with a low leakage current.

Since hafnium oxide is a high-permittivity (high-k) material, hafnium silicate is a high-permittivity (high-k) material depending on the content of silicon. Accordingly, in the case of using the insulating layer 250a as the gate insulating layer, a gate potential applied during operation of the transistor can be reduced while the physical thickness of the gate insulating layer is maintained. In addition, the equivalent oxide thickness (EOT) of the gate insulating layer can be reduced.

When a barrier insulating layer against hydrogen is used as the insulating layer 250b, diffusion of impurities contained in the conductive layer 260 into the oxide semiconductor layer 230 can be inhibited. Silicon nitride is suitable for the insulating layer 250b because of its high hydrogen barrier property.

With such a structure, a semiconductor device having favorable electrical characteristics can be provided. A highly reliable semiconductor device can be provided. A semiconductor device with a small variation in electrical characteristics of transistors can be provided. A semiconductor device that has a high on-state current can be provided.

A high-permittivity (high-k) material is preferably used for the insulating layer 250. An example of the high-k material is an oxide containing one or both of aluminum and hafnium. With the use of the high-k material for the insulating layer 250, a gate potential applied during operation of the transistor can be reduced while the physical thickness of the gate insulating layer is maintained. In addition, the equivalent oxide thickness (EOT) of the insulating layer functioning as the gate insulating layer can be reduced.

As described above, for the insulating layer 250a, an oxide containing one or both of aluminum and hafnium is preferably used, an oxide that has an amorphous structure and contains one or both of aluminum and hafnium is further preferably used, and aluminum oxide having an amorphous structure is still further preferably used.

Furthermore, the insulating layer 250 may include an insulating layer with a thermally stable structure, such as silicon oxide or silicon oxynitride.

The insulating layer 250 may include, between a pair of insulating layers having a function of capturing hydrogen and fixing hydrogen, an insulating layer with a thermally stable structure.

The insulating layer 250 preferably includes a barrier insulating layer against oxygen. In that case, oxidation of the conductive layer 240, the conductive layer 260, and the like can be inhibited. In the case where the insulating layer 250 has a stacked-layer structure, a layer in contact with the conductive layer 240 and a layer in contact with the conductive layer 260 are each preferably a barrier insulating layer against oxygen.

When a barrier insulating layer against hydrogen and oxygen is used as the above-described insulating layer 250b, for example, oxidation of the conductive layer 260 can be inhibited. Moreover, diffusion of oxygen included in the oxide semiconductor layer 230 into the conductive layer 260 and formation of oxygen vacancies in the oxide semiconductor layer 230 can be inhibited.

Examples of the barrier insulating layer against oxygen include an oxide containing one or both of aluminum and hafnium, magnesium oxide, gallium oxide, gallium zinc oxide, indium gallium zinc oxide, silicon nitride, and silicon nitride oxide. Examples of the oxide containing one or both of aluminum and hafnium include aluminum oxide, hafnium oxide, an oxide containing aluminum and hafnium (hafnium aluminate), and an oxide containing hafnium and silicon (hafnium silicate).

The layer that is included in the insulating layer 250 and is in contact with the conductive layer 240 is preferably less likely to transmit oxygen than at least the insulating layer 280. When the layer has a barrier property against oxygen, oxidation of the side surface of the conductive layer 240 and formation of an oxide film on the side surface can be inhibited. It is thus possible to inhibit a reduction in the on-state current or field-effect mobility of the transistor 200.

The thickness of the insulating layer 250 is preferably greater than or equal to 0.1 nm and less than or equal to 30 nm, further preferably greater than or equal to 0.1 nm and less than or equal to 20 nm, still further preferably greater than or equal to 0.1 nm and less than or equal to 10 nm, yet still further preferably greater than or equal to 0.1 nm and less than or equal to 5.0 nm, yet still further preferably greater than or equal to 0.5 nm and less than or equal to 5.0 nm, yet still further preferably greater than or equal to 1.0 nm and less than 5.0 nm, yet still further preferably greater than or equal to 1.0 nm and less than or equal to 3.0 nm.

The insulating layer 250 preferably has a three-layer structure in which a first insulating layer including a material with low relative permittivity, a second insulating layer having a function of capturing or fixing hydrogen, and a third insulating layer having a barrier property against hydrogen and oxygen are stacked in this order from the oxide semiconductor layer 230 side. As the material with low relative permittivity included in the first insulating layer, silicon oxide or silicon oxynitride is preferably used. The first insulating layer is in contact with the oxide semiconductor layer 230. When an oxide is used for the first insulating layer, oxygen can be supplied to the oxide semiconductor layer 230. Providing the third insulating layer can inhibit oxygen included in the first insulating layer from diffusing into the conductive layer 260 and inhibit the conductive layer 260 from being oxidized. Furthermore, a reduction in the amount of oxygen supplied from the first insulating layer to the oxide semiconductor layer 230 can be inhibited.

The insulating layer 250 preferably has a four-layer structure in which a fourth insulating layer having a barrier property against oxygen, a first insulating layer including a material with low relative permittivity, a second insulating layer having a function of capturing or fixing hydrogen, and a third insulating layer having a barrier property against hydrogen and oxygen are stacked in this order from the oxide semiconductor layer 230 side. The first insulating layer to the third insulating layer can have a structure similar to that of the layers used in the above three-layer structure. The fourth insulating layer is in contact with the oxide semiconductor layer 230. When the fourth insulating layer has a barrier property against oxygen, release of oxygen from the oxide semiconductor layer 230 can be inhibited. For the fourth insulating layer, aluminum oxide is preferably used, for example. Aluminum oxide has a function of capturing or fixing hydrogen, and thus is suitable for the fourth insulating layer in contact with the oxide semiconductor layer 230.

The thickness of each layer included in the insulating layer 250 is preferably thin for miniaturization of the transistor. The thickness of each layer included in the insulating layer 250 is preferably greater than or equal to 0.1 nm and less than or equal to 10 nm, further preferably greater than or equal to 0.1 nm and less than or equal to 5 nm, still further preferably greater than or equal to 0.5 nm and less than or equal to 5 nm, yet still further preferably greater than or equal to 1 nm and less than 5 nm, yet still further preferably greater than or equal to 1 nm and less than or equal to 3 nm. Note that each layer included in the insulating layer 250 at least partly includes a region with the above-described thickness.

Typically, the thicknesses of the fourth insulating layer, the first insulating layer, the second insulating layer, and the third insulating layer are 1 nm, 2 nm, 2 nm, and 1 nm, respectively. Such a structure enables the transistor to have favorable electrical characteristics even when the transistor is miniaturized or highly integrated.

As the insulating layer 283, a barrier insulating layer against hydrogen is preferably used. In that case, diffusion of hydrogen from above the insulating layer 283 into the oxide semiconductor layer 230 can be inhibited. A silicon nitride film and a silicon nitride oxide film can be suitably used for the insulating layer 283 because they release few impurities (e.g., water and hydrogen) and are less likely to transmit oxygen and hydrogen.

A silicon nitride film formed by a sputtering method is particularly preferably used for the insulating layer 283. Since a sputtering method does not need to use a molecule containing hydrogen in a film formation gas, the hydrogen concentration of the insulating layer 283 can be reduced. When the insulating layer 283 is formed by a sputtering method, high-density silicon nitride can be formed.

As the insulating layer 283, an insulating layer having a function of capturing or fixing hydrogen may be used. With such a structure, diffusion of hydrogen from above the insulating layer 283 into the oxide semiconductor layer 230 can be inhibited, and hydrogen included in the oxide semiconductor layer 230 can be captured or fixed. Thus, the hydrogen concentration of the oxide semiconductor layer 230 can be reduced. For the insulating layer 283, hafnium silicate or the like can be used.

The insulating layer 283 may have a stacked-layer structure of an insulating layer having a function of capturing or fixing hydrogen and a barrier insulating layer against hydrogen. For example, a stacked-layer film of aluminum oxide and silicon nitride over the aluminum oxide may be used for the insulating layer 283.

### [Conductive Layer]

For the conductive layers (e.g., the conductive layer 220, the conductive layer 240, and the conductive layer 260) included in the semiconductor device, it is preferable to use a metal element selected from tungsten, copper, aluminum, chromium, silver, gold, platinum, zinc, tantalum, nickel, titanium, iron, cobalt, molybdenum, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. As an alloy containing any of the above metal elements, a nitride of the alloy or an oxide of the alloy may be used. For example, it is preferable to use tantalum nitride, titanium nitride, ruthenium nitride, a nitride containing molybdenum, a nitride containing tungsten, titanium, and aluminum, a nitride containing tantalum and aluminum, ruthenium oxide, an oxide containing strontium and ruthenium, an oxide containing lanthanum and nickel, or the like. Alternatively, a semiconductor having high electric conductivity, typified by polycrystalline silicon containing an impurity element such as phosphorus, or silicide such as nickel silicide may be used.

A conductive material containing nitrogen, such as a nitride containing tantalum, a nitride containing titanium, a nitride containing molybdenum, a nitride containing tungsten, a nitride containing ruthenium, a nitride containing tantalum and aluminum, or a nitride containing titanium and aluminum; a conductive material containing oxygen, such as ruthenium oxide, an oxide containing strontium and ruthenium, or an oxide containing lanthanum and nickel; or a material containing a metal element such as titanium, tantalum, or ruthenium is preferable because it is a conductive material that is not easily oxidized, a conductive material having a function of inhibiting oxygen diffusion, or a material maintaining its conductivity even after absorbing oxygen. Examples of the conductive material containing oxygen include indium oxide containing tungsten oxide, indium oxide containing titanium oxide, indium tin oxide (also referred to as ITO), indium tin oxide containing titanium oxide, indium tin oxide to which silicon is added (also referred to as ITSO), indium zinc oxide (also referred to as IZO (registered trademark)), and indium zinc oxide containing tungsten oxide. In this specification and the like, a conductive film formed using the conductive material containing oxygen may be referred to as an oxide conductive film.

A conductive material containing tungsten, copper, or aluminum as its main component is preferable because it has high conductivity.

A stack of a plurality of conductive layers formed of any of the above-described materials may be used. For example, a stacked-layer structure combining a material containing any of the above metal elements and a conductive material containing oxygen may be employed. Alternatively, a stacked-layer structure combining a material containing any of the above metal elements and a conductive material containing nitrogen may be employed. Further alternatively, a stacked-layer structure combining a material containing any of the above metal elements, a conductive material containing oxygen, and a conductive material containing nitrogen may be employed.

In the case where a metal oxide is used for the channel formation region of the transistor, the conductive layer functioning as the gate electrode preferably employs a stacked-layer structure combining a material containing any of the above metal elements and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

For the conductive layer 260, any of the above metal elements, an alloy containing any of the above metal elements as a component, an alloy containing a combination of the above metal elements, or the like can be used. For example, a material having high conductivity, such as tungsten, is preferably used. For the conductive layer 260, a conductive material that is not easily oxidized, a conductive material having a function of inhibiting diffusion of oxygen, or the like is preferably used. As described above, examples of the conductive material include a conductive material containing nitrogen and a conductive material containing oxygen. Thus, a decrease in conductivity of the conductive layer 260 can be inhibited.

It is particularly preferable to use, for the conductive layer 260, a conductive material containing oxygen and a metal element contained in the metal oxide where the channel is formed. One or more of indium tin oxide, indium oxide containing tungsten oxide, indium zinc oxide containing tungsten oxide, indium oxide containing titanium oxide, indium tin oxide containing titanium oxide, indium zinc oxide, and indium tin oxide to which silicon is added may be used. Indium gallium zinc oxide containing nitrogen may be used. With the use of such a material, hydrogen contained in the metal oxide where the channel is formed can be captured in some cases. Alternatively, hydrogen entering from an external insulating layer or the like can be captured in some cases.

The conductive layer 260 is greater than or equal to 3 nm and less than or equal to 500 nm, for example. The thickness of the conductive layer 260 is, for example, larger than or equal to the thickness of the insulating layer 250. When the conductive layer 260 has a large thickness, the resistance of the conductive layer 260 can be reduced.

In the semiconductor device of one embodiment of the present invention, a two-layer structure of the conductive layer 260a and the conductive layer 260b over the conductive layer 260a is preferably used for the conductive layer 260.

The conductive layer 260a is preferably formed using a material that can be processed by wet etching. The conductive layer 260a is preferably a material having high selectivity with respect to the conductive layer 260b in wet etching. That is, the etching rate of the conductive layer 260a is preferably sufficiently higher than the etching rate of the conductive layer 260b. The conductive layer 260a is preferably a material having high selectivity with respect to the insulating layer 250 in wet etching. That is, the etching rate of the conductive layer 260a is preferably sufficiently higher than the etching rate of the insulating layer 250.

When the conductive layer 260a is formed using a conductive material having a function of inhibiting diffusion of oxygen, release of oxygen from the oxide semiconductor layer 230 can be inhibited and formation of oxygen vacancies in the oxide semiconductor layer 230 can be inhibited, for example.

Furthermore, when the conductive layer 260a is formed using a conductive material that is not easily oxidized, the conductive layer 260a can be inhibited from being oxidized and thereby having a reduced conductivity owing to release of oxygen from the oxide semiconductor layer 230 or release of oxygen from the insulating layer 250, for example.

The material used for the conductive layer 260b preferably has higher conductivity than the material used for the conductive layer 260a, for example. When the conductive layer 260b has a large thickness, the amount of current flowing through the conductive layer 260b can be further increased.

It is preferable that the conductive layer 260a be isotropically etched by a method such as wet etching. In this specification and the like, etching that makes the end portion of the conductive layer 260a recede inward from the end portion of the conductive layer 260b in the etching is referred to as side etching. In the case of using isotropic etching, the larger the thickness of the conductive layer to be etched is, the larger the width of the inward recess of the end portion of the conductive layer 260a from the end portion of the conductive layer 260b by side etching is. A large width of the side etching might impair coverage with the insulating layer 283, for example. When the region 277 is too large, the end portion of the conductive layer 260b might be in direct contact with the insulating layer 250, which might reduce the effect of improving the insulation resistance of the insulating layer 250. It is thus preferable that the conductive layer 260a be moderately thin.

Thus, for example, the thickness of the conductive layer 260b is preferably larger than the thickness of the conductive layer 260a. The thickness of the conductive layer 260a is preferably less than or equal to 50%, further preferably less than or equal to 30% of the sum of the thickness of the conductive layer 260a and the thickness of the conductive layer 260b, for example. When the thickness of the conductive layer 260a is small, the width R can be a minute width. The region 277 can be formed by isotropic etching. The width R of the region 277 is formed depending on the thickness of the conductive layer 260a. When the thickness of the conductive layer 260a is larger than or equal to a desired thickness, a leakage current between the conductive layer 260 and the conductive layer 240 can be favorably reduced. The thickness of the conductive layer 260a is greater than or equal to 5% or greater than or equal to 10% of the sum of the thickness of the conductive layer 260a and the thickness of the conductive layer 260b, for example.

Alternatively, the conductivity of the material used for the conductive layer 260a may be higher than the conductivity of the material used for the conductive layer 260b.

When the sum of the thickness of the conductive layer 260a and the thickness of the conductive layer 260b (i.e., the thickness of the conductive layer 260) is large, the opening 290 can be filled with the conductive layer 260. When the opening 290 is filled with the conductive layer 260, a conductive layer (e.g., a plug, an electrode, or a wiring) above the conductive layer 260 is easily formed in the region of the conductive layer 260 that overlaps with the opening 290.

When the sum of the thickness of the conductive layer 260a and the thickness of the conductive layer 260b is greater than or equal to 50% of the width D of the opening 290, the opening 290 can be filled with the conductive layer 260, for example.

When a film formation method achieving excellent coverage is used for the conductive layer 260a, the conductive layer 260a can be favorably formed along the sidewall of the opening 290.

For the conductive layer 260a, a conductive material containing nitrogen, a conductive material containing oxygen, or the like can be used, for example. For the conductive layer 260a, a conductive material containing oxygen and a metal element contained in the metal oxide where the channel is formed can be used, for example.

For the conductive layer 260a, for example, a conductive material containing the above metal element and nitrogen can be used; tantalum nitride, titanium nitride, ruthenium nitride, a nitride containing molybdenum, a nitride containing tungsten, titanium, and aluminum, a nitride containing tantalum and aluminum, or the like can be used, for example.

For the conductive layer 260a, for example, a conductive material containing the above metal element and oxygen can be used; ruthenium oxide, an oxide containing strontium and ruthenium, an oxide containing lanthanum and nickel, or the like can be used, for example.

One or more of indium tin oxide, indium oxide containing tungsten oxide, indium zinc oxide containing tungsten oxide, indium oxide containing titanium oxide, indium tin oxide containing titanium oxide, indium zinc oxide, and indium tin oxide to which silicon is added may be used. Indium gallium zinc oxide containing nitrogen may be used.

For the conductive layer 260a, titanium, tantalum, ruthenium, or a material containing one or more selected from the metal elements is preferable because of being a conductive material that is not easily oxidized, a conductive material having a function of inhibiting diffusion of oxygen, or a material that maintains the conductivity even after absorbing oxygen.

For the conductive layer 260b, any of the above metal elements, an alloy containing any of the above metal elements as a component, an alloy containing a combination of the above metal elements, or the like can be used, for example. For example, tungsten can be used. Tungsten is preferable because it may be highly resistant to a chemical solution used in wet etching.

Furthermore, the conductive layer 260a may have a stacked-layer structure. Moreover, the conductive layer 260b may have a stacked-layer structure. In the case where the conductive layer 260a has a stacked-layer structure, a plurality of materials that can be used for the conductive layer 260a are stacked, for example. Alternatively, a plurality of materials selected from materials that can be used for the conductive layer of one embodiment of the present invention may be stacked. In the case where the conductive layer 260b has a stacked-layer structure, a plurality of materials that can be used for the conductive layer 260b are stacked, for example. Alternatively, a plurality of materials selected from materials that can be used for the conductive layer of one embodiment of the present invention may be stacked.

Each of the conductive layer 220 and the conductive layer 240 is in contact with the oxide semiconductor layer 230, and thus is preferably formed using a conductive material that is not easily oxidized, a conductive material that maintains its low electrical resistance even after being oxidized, an oxide conductive material, or a conductive material that has a function of inhibiting diffusion of oxygen. Examples of the conductive material include a conductive material containing nitrogen and a conductive material containing oxygen. Thus, a decrease in conductivity of the conductive layer 220 and the conductive layer 240 can be inhibited.

When the conductive layer 220 or the conductive layer 240 is formed using a conductive material containing oxygen, the conductive layer 220 or the conductive layer 240 can maintain its conductivity even after absorbing oxygen. In addition, also in the case of using an insulating layer containing oxygen, e.g., hafnium oxide, as the insulating layer 210, the conductive layer 220 can maintain its conductivity, which is preferable. Each of the conductive layer 220 and the conductive layer 240 is preferably formed using ITO, ITSO, or IZO (registered trademark), for example.

In the example illustrated in FIG. 3A and FIG. 3B, the conductive layer 220 in FIG. 1B and FIG. 1C has a three-layer structure of a conductive layer 220a, a conductive layer 220b over the conductive layer 220a, and a conductive layer 220c over the conductive layer 220b, the conductive layer 240 in FIG. 1B and FIG. 1C has a two-layer structure of a conductive layer 240a and a conductive layer 240b over the conductive layer 240a, and the insulating layer 280 in FIG. 1B and FIG. 1C has a three-layer structure of an insulating layer 280a, an insulating layer 280b over the insulating layer 280a, and an insulating layer 280c over the insulating layer 280b. FIG. 3A and FIG. 3B are different from FIG. 1B and FIG. 1C in that an insulating layer 222 is provided.

For example, a conductive material that is not easily oxidized or a conductive material that has a function of inhibiting diffusion of oxygen is preferably used for the conductive layer 220a, a material having high conductivity is preferably used for the conductive layer 220b, and a conductive material containing oxygen is preferably used for the conductive layer 220c. Specifically, for example, titanium nitride is preferably used for the conductive layer 220a, tungsten is preferably used for the conductive layer 220b, and ITO or ITSO is preferably used for the conductive layer 220c. In that case, titanium nitride is in contact with the insulating layer 210, and ITO or ITSO is in contact with the oxide semiconductor layer 230. Such a structure can maintain conductivity even when the conductive layer 220 is in contact with the oxide semiconductor layer 230. In the case of using an oxide insulating layer as the insulating layer 210, the conductive layer 220 can be inhibited from being excessively oxidized by the insulating layer 210. When tungsten with high conductivity is used for the conductive layer 220b, the conductivity of the conductive layer 220 can be increased.

Although the top surface of the conductive layer 220 is flat in the structure illustrated in FIG. 1B and FIG. 1C, the present invention is not limited thereto. For example, as illustrated in FIG. 3A and FIG. 3B, a depressed portion overlapping with the opening 290 may be formed on the top surface of the conductive layer 220. When at least parts of the oxide semiconductor layer 230, the insulating layer 250, and the conductive layer 260 are formed to fill the depressed portion, the gate electric field of the conductive layer 260 can be easily applied to the oxide semiconductor layer 230 in the vicinity of the conductive layer 220.

In FIG. 3A and FIG. 3B, the conductive layer 240 has the two-layer structure of the conductive layer 240a and the conductive layer 240b over the conductive layer 240a. Here, for example, the conductive layer 240a is preferably formed using a material having higher conductivity than the conductive layer 240b, and the conductive layer 240b is preferably formed using a conductive material containing oxygen. Specifically, for example, the conductive layer 240a is preferably formed using ruthenium, tungsten, titanium nitride, or tantalum nitride, and the conductive layer 240b is preferably formed using ITO or ITSO. In that case, ITO or ITSO is in contact with the oxide semiconductor layer 230. Such a structure can maintain conductivity even when the conductive layer 240 is in contact with the oxide semiconductor layer 230. When the conductive layer 240a is formed using a material having higher conductivity than the conductive layer 240b, the conductivity of the conductive layer 240 can be increased.

### [Substrate]

As a substrate where the transistor is formed, an insulator substrate, a semiconductor substrate, or a conductor substrate can be used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate of silicon or germanium and a compound semiconductor substrate of silicon carbide, silicon germanium, gallium arsenide, indium phosphide, zinc oxide, or gallium oxide. Another example is the above-described semiconductor substrate in which an insulator region is included, e.g., an SOI (Silicon On Insulator) substrate or the like. Examples of the conductor substrate include a graphite substrate, a metal substrate, an alloy substrate, and a conductive resin substrate. Other examples include a substrate including a nitride of a metal and a substrate including an oxide of a metal. Other examples include an insulator substrate provided with a conductor or a semiconductor, a semiconductor substrate provided with a conductor or an insulator, and a conductor substrate provided with a semiconductor or an insulator. Alternatively, these substrates provided with elements may be used. Examples of the element provided over the substrate include a capacitor, a resistor, a switching element, a light-emitting element, and a memory element.

In the semiconductor device illustrated in FIG. 3A and FIG. 3B, the insulating layer 222 is provided over the insulating layer 210, and the conductive layer 220 and the insulating layer 280 are provided over the insulating layer 222.

As the insulating layer 222, an insulating layer having a function of capturing or fixing hydrogen is preferably used. In that case, hydrogen in the oxide semiconductor layer 230 can be diffused into the insulating layer 222 through the conductive layer 220, and the hydrogen can be captured or fixed. Thus, the hydrogen concentration in the oxide semiconductor layer 230 can be lowered.

For example, a silicon nitride film is preferably used for the insulating layer 210 and an oxide film including hafnium and silicon (hafnium silicate film) is preferably used for the insulating layer 222.

In the semiconductor device illustrated in FIG. 3A and FIG. 3B, the insulating layer 280 includes the insulating layer 280a, the insulating layer 280b over the insulating layer 280a, and the insulating layer 280c over the insulating layer 280b.

The insulating layer 280a includes a region in contact with the top surface of the insulating layer 222, a region in contact with the side surface of the conductive layer 220, and a region in contact with the top surface of the conductive layer 220. The insulating layer 280c includes a region in contact with the bottom surface of the conductive layer 240.

The insulating layer 280b is in contact with the channel formation region of the oxide semiconductor layer 230. When an insulating layer including oxygen is used as the insulating layer 280b, oxygen can be supplied to the oxide semiconductor layer 230.

The insulating layer 280b preferably includes a region having a higher oxygen content than at least one of the insulating layer 280a and the insulating layer 280c. In particular, the insulating layer 280b preferably includes a region having a higher oxygen content than each of the insulating layer 280a and the insulating layer 280c. When the insulating layer 280b has a high oxygen content, an i-type region can be easily formed in the oxide semiconductor layer 230 in the vicinity of the insulating layer 280b.

It is further preferable that a film from which oxygen is released by heating be used for the insulating layer 280b. When the insulating layer 280b releases oxygen by being heated during the manufacturing process of the transistor 200, the oxygen can be supplied to the oxide semiconductor layer 230. The oxygen supply from the insulating layer 280b to the oxide semiconductor layer 230, particularly to the channel formation region of the oxide semiconductor layer 230, can reduce the amount of oxygen vacancies and VoH in the oxide semiconductor layer 230, so that the transistor can have favorable electrical characteristics and high reliability.

In order to improve the electrical characteristics and reliability of the OS transistor, it is important to sufficiently reduce the hydrogen concentration in the oxide semiconductor and optimize the amount of oxygen supplied to the oxide semiconductor.

For example, the amount of oxygen molecules released from the insulating layer 280b is preferably greater than or equal to 1.0×10¹⁴ molecules/cm² and less than 1.0×10¹⁵ molecules/cm². Note that the amount of released oxygen molecules can be measured by thermal desorption spectrometry.

Particularly in the case where the channel length of the transistor 200 is short, oxygen vacancies and VoH in the channel formation region significantly affect the electrical characteristics and reliability. Accordingly, when the hydrogen concentration in the oxide semiconductor layer 230 is sufficiently reduced and the amount of oxygen supplied to the oxide semiconductor layer 230 is optimized, the transistor can have a short channel length, excellent electrical characteristics, and high reliability.

The insulating layer 280b is preferably formed by a film formation method such as a sputtering method or a plasma-enhanced chemical vapor deposition (PECVD) method. In particular, using a sputtering method, which does not need to use a hydrogen gas as a film formation gas, enables a film having an extremely low hydrogen content. This can inhibit supply of hydrogen to the oxide semiconductor layer 230 and stabilize the electrical characteristics of the transistor 200.

In the case where a large amount of oxygen is supplied to the oxide semiconductor layer 230, heat treatment in an oxygen-containing atmosphere or plasma treatment in an oxygen-containing atmosphere is preferably performed after formation of the insulating layer 280b, for example. Alternatively, an oxide film may be formed over the top surface of the insulating layer 280b by a sputtering method in an oxygen atmosphere to supply oxygen. After that, the oxide film may be removed. Such treatment can supply oxygen to the insulating layer 280b and increase the amount of oxygen supplied to the oxide semiconductor layer 230.

The region of the oxide semiconductor layer 230 that is in contact with the insulating layer 280a and the region of the oxide semiconductor layer 230 that is in contact with the insulating layer 280c are supplied with a smaller amount of oxygen than the region of the oxide semiconductor layer 230 that is in contact with the insulating layer 280b. Thus, the region of the oxide semiconductor layer 230 that is in contact with the insulating layer 280a and the region of the oxide semiconductor layer 230 that is in contact with the insulating layer 280c each have a lower resistance in some cases. That is, by adjusting the thickness of the insulating layer 280a, the range of a region functioning as one of the source region and the drain region can be controlled. Similarly, by adjusting the thickness of the insulating layer 280c, the range of a region functioning as the other of the source region and the drain region can be controlled. As described above, the thicknesses of the insulating layer 280a and the insulating layer 280c can be set as appropriate in accordance with the characteristics required for the transistor.

A material with low relative permittivity is preferably used for the insulating layer 280b. In that case, parasitic capacitance generated between wirings can be reduced. For example, silicon oxide or silicon oxynitride can be used for the insulating layer 280b.

As each of the insulating layer 280a and the insulating layer 280c, a barrier insulating layer against oxygen is preferably used. Providing the insulating layer 280a between the insulating layer 280b and the conductive layer 220 can inhibit the conductive layer 220 from being oxidized and having a high resistance. Furthermore, providing the insulating layer 280c between the insulating layer 280b and the conductive layer 240 can inhibit the conductive layer 240 from being oxidized and having a high resistance.

As the insulating layer 280a, an insulating layer having a function of capturing or fixing hydrogen may be used. With such a structure, diffusion of hydrogen from below the insulating layer 280a into the oxide semiconductor layer 230 can be inhibited, and hydrogen contained in the oxide semiconductor layer 230 can be captured or fixed. Thus, the hydrogen concentration of the oxide semiconductor layer 230 can be reduced. For the insulating layer 280a, magnesium oxide, aluminum oxide, hafnium oxide, an oxide containing hafnium and silicon, or the like can be used. Alternatively, for example, a stacked-layer film of aluminum oxide and silicon nitride over the aluminum oxide may be used for the insulating layer 280a. Similarly, an insulating layer having a function of capturing or fixing hydrogen may be used as the insulating layer 280c.

For example, silicon nitride can be used for the insulating layer 280a and the insulating layer 280c, and silicon oxide can be used for the insulating layer 280b.

### Manufacturing Method Example 1 of Semiconductor Device

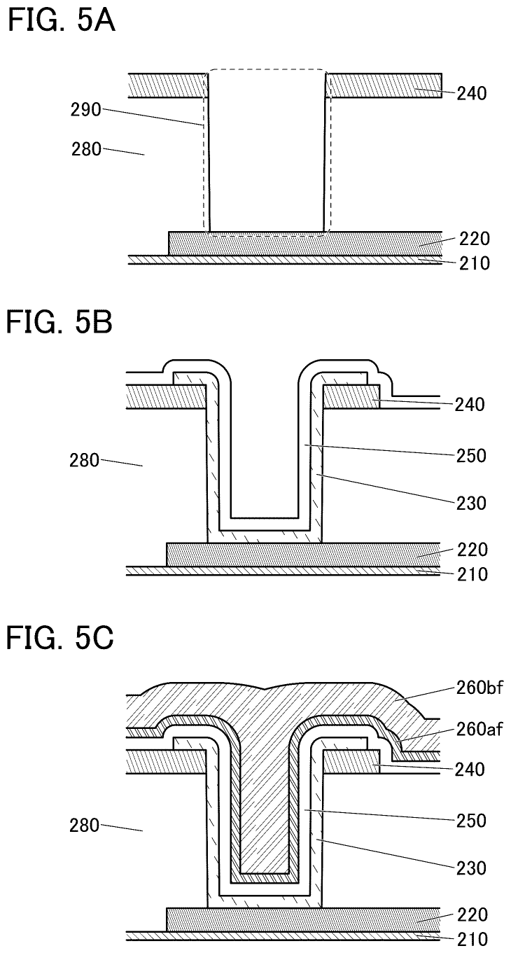

Next, a method for manufacturing the semiconductor device of one embodiment of the present invention will be described with reference to FIG. 5 to FIG. 8. Note that as for a material and a formation method of each component, portions similar to the portions described above are not described in some cases.

Thin films included in the semiconductor device (e.g., insulating films, semiconductor films, and conductive films) can be formed by a sputtering method, a CVD method, a vacuum evaporation method, a PLD method, an ALD method, or the like.

Examples of the sputtering method include an RF sputtering method in which a high-frequency power source is used for a sputtering power source, a DC sputtering method in which a DC power source is used, and a pulsed DC sputtering method in which a voltage is applied to an electrode while being changed in a pulsed manner. An RF sputtering method is mainly used to form an insulating film, and a DC sputtering method is mainly used to form a metal conductive film. A pulsed DC sputtering method is mainly used to form a film of a compound such as an oxide, a nitride, or a carbide by a reactive sputtering method.

Furthermore, CVD methods can be classified into a plasma CVD (PECVD) method using plasma, a thermal CVD (TCVD) method using heat, a photo CVD method using light, and the like. Moreover, CVD methods can be classified into a metal CVD (MCVD) method and a metal organic CVD (MOCVD) method depending on a source gas to be used.

A high-quality film can be obtained at a relatively low temperature by a plasma CVD method. Furthermore, a thermal CVD method is a film formation method that does not use plasma and thus enables less plasma damage to an object. For example, a wiring, an electrode, an element (a transistor, a capacitor, or the like), or the like included in a semiconductor device may be charged up by receiving electric charge from plasma. In that case, accumulated electric charge may break the wiring, the electrode, the element, or the like included in the semiconductor device. By contrast, a thermal CVD method, which does not use plasma, does not cause such plasma damage, and thus can increase the yield of the semiconductor device. In addition, a thermal CVD method does not cause plasma damage during film formation, so that a film with few defects can be obtained.

As an ALD method, a thermal ALD method, in which a precursor and a reactant react with each other only by a thermal energy, a PEALD method, in which a reactant excited by plasma is used, or the like can be used.

A CVD method and an ALD method are different from a sputtering method, in which particles ejected from a target or the like are deposited. Thus, a CVD method and an ALD method are film formation methods that enable good step coverage almost regardless of the shape of an object. In particular, an ALD method enables excellent step coverage and excellent thickness uniformity and thus is suitable for covering a surface of an opening with a high aspect ratio, for example. On the other hand, the ALD method has a relatively low film formation rate, and thus is preferably used in combination with another film formation method with a high film formation rate, such as a CVD method, in some cases.

By a CVD method, a film with a certain composition can be formed by adjusting the flow rate ratio of the source gases. For example, a CVD method enables a film with a gradually-changed composition to be formed by changing the flow rate ratio of the source gases during film formation. In the case where a film is formed while the flow rate ratio of the source gas is changed, the time taken for transfer or pressure adjustment is saved, and thus, the time taken for the film formation can be shortened as compared to the case where a film is formed using a plurality of film formation chambers. Hence, the productivity of the semiconductor device can be improved in some cases.

An ALD method in which different kinds of precursors are introduced at the same time enables formation of a film with a certain composition. In the case where different kinds of precursors are introduced, a film with a certain composition can be formed by controlling the number of cycles for each of the precursors.

Thin films included in the semiconductor device (e.g., insulating films, semiconductor films, and conductive films) can be formed by a wet film-formation method such as spin coating, dipping, spray coating, ink-jetting, dispensing, screen printing, offset printing, doctor blade coating, slit coating, roll coating, curtain coating, or knife coating.

In processing a thin film included in the semiconductor device, a photolithography method or the like can be employed. Alternatively, the thin film may be processed by a nanoimprinting method, a sandblasting method, a lift-off method, or the like. Alternatively, an island-shaped thin film may be directly formed by a film formation method using a shielding mask such as a metal mask.

There are two typical examples of photolithography methods. In one of the methods, a resist mask is formed over a thin film to be processed, the thin film is processed by etching or the like, and then the resist mask is removed. In the other method, a photosensitive thin film is formed and then processed into a desired shape by light exposure and development.

As light for light exposure in a photolithography method, it is possible to use the i-line (wavelength: 365 nm), the g-line (wavelength: 436 nm), the h-line (wavelength: 405 nm), or light in which the i-line, the g-line, and the h-line are mixed. Alternatively, ultraviolet rays, KrF laser light, ArF laser light, or the like can be used. In addition, light exposure may be performed by liquid immersion exposure technique. As the light used for the light exposure, extreme ultraviolet (EUV) light or X-rays may be used. Instead of the light used for the light exposure, an electron beam can be used. Extreme ultraviolet light, X-rays, or an electron beam is preferably used, in which case extremely minute processing can be performed. Note that a photomask is not needed when the light exposure is performed by scanning with a beam such as an electron beam.

For etching of a thin film, a dry etching method, a wet etching method, a sandblast method, or the like can be used.

First, the conductive layer 220 is formed over the insulating layer 210, the insulating layer 280 is formed over the conductive layer 220, and the conductive layer 240 is formed over the insulating layer 280.

Note that the top surface of the insulating layer 280 is preferably planarized by planarization treatment using a chemical mechanical polishing (CMP) method (also referred to as CMP treatment) after the formation of the insulating layer 280. By the planarization treatment of the insulating layer 280, the formation surface of the conductive layer 240 functioning as a wiring can be made flat, whereby disconnection of the conductive layer 240 can be inhibited. It is acceptable that the planarization treatment is not performed, in which case the manufacturing cost can be reduced.

Next, the opening 290 is formed in the conductive layer 240 and the insulating layer 280 at a position overlapping with the conductive layer 220 (FIG. 5A).

Since the opening 290 has a high aspect ratio, part of the conductive layer 240 and part of the insulating layer 280 are preferably processed by anisotropic etching. Processing by a dry etching method is particularly preferable because it is suitable for microfabrication. The processing may be performed under different conditions. Note that the inclination of the side surface of the conductive layer 240 and the inclination of the side surface of the insulating layer 280 may be different from each other in the opening 290 depending on the processing conditions of the conductive layer 240 and the insulating layer 280.

Next, heat treatment may be performed. The heat treatment is performed, for example, at higher than or equal to 250° C. and lower than or equal to 650° C., preferably higher than or equal to 300° C. and lower than or equal to 500° C., further preferably higher than or equal to 320° C. and lower than or equal to 450° C.

The heat treatment is performed in a nitrogen gas atmosphere, an inert gas atmosphere, or an atmosphere containing an oxidizing gas at 10 ppm or more, 1% or more, or 10% or more. For example, in the case where the heat treatment is performed in a mixed atmosphere of a nitrogen gas and an oxygen gas, the proportion of the oxygen gas is preferably approximately 20%. The heat treatment may be performed under a reduced pressure. Alternatively, heat treatment may be performed in an atmosphere of a nitrogen gas or an inert gas, and then another heat treatment may be performed in an atmosphere containing an oxidizing gas at 10 ppm or more, 1% or more, or 10% or more in order to compensate for released oxygen. By the above-described heat treatment, impurities such as water contained in the insulating layer 280, for example, can be reduced before the oxide semiconductor layer 230 is formed.

The gas used in the above heat treatment preferably has high purity. For example, the amount of moisture contained in the gas used in the above heat treatment is preferably 1 ppb or less, further preferably 0.1 ppb or less, still further preferably 0.05 ppb or less. The heat treatment using a highly purified gas can prevent the entry of moisture or the like into the insulating layer 280 as much as possible.

Next, the conductive layer 240 is processed into an island shape. The step of processing the conductive layer 240 into an island shape and the step of providing the opening 290 in the conductive layer 240 can be performed independently of each other, in which case there is no limitation on the order of the steps. Alternatively, after light exposure using a mask for processing into a quadrangular island shape and light exposure using a mask for providing a circular opening are performed, etching may be performed to collectively perform processing into the island shape and formation of the opening. Light exposure using a multi-tone mask (typically a half-tone mask or a gray-tone mask) may be used. The mask used for forming the opening in the conductive layer 240 may be the same as or different from the mask used for forming the opening in the insulating layer 280.

Next, the oxide semiconductor layer 230 is formed to cover the opening 290. Then, the insulating layer 250 is formed over the oxide semiconductor layer 230 (FIG. 5B). The oxide semiconductor layer 230 is provided in contact with the top surface of the conductive layer 220, the side surface of the insulating layer 280, and the top surface and the side surface of the conductive layer 240. The insulating layer 250 is formed in contact with the oxide semiconductor layer 230.

The oxide semiconductor layer 230 can be formed by a sputtering method, a CVD method, an MBE method, a PLD method, or an ALD method, for example.

The formed oxide semiconductor layer 230 is preferably a film having as uniform thickness as possible along the top surface of the conductive layer 220, the side surface of the insulating layer 280, and the side surface of the conductive layer 240, in the opening 290. By an ALD method, a thin film can be formed with good controllability. Therefore, the oxide semiconductor layer 230 is preferably formed by an ALD method.

In addition, when the oxide semiconductor layer 230 has high crystallinity, diffusion of impurities in the oxide semiconductor layer 230 is inhibited, leading to a small variation in electrical characteristics and higher reliability of the transistor. The oxide semiconductor layer 230 is preferably formed by a sputtering method, in which case a layer with high crystallinity can be obtained easily as compared with the case of using an ALD method.

In the case where the oxide semiconductor layer 230 is formed by a sputtering method, oxygen or a mixed gas of oxygen and a noble gas is used as a sputtering gas. Increasing the proportion of oxygen included in the sputtering gas can increase the amount of excess oxygen in the formed oxide film. In the case where the oxide film is formed by a sputtering method, an In-M-Zn oxide target or the like can be used.

In the case where the oxide semiconductor layer 230 is formed by a sputtering method, setting the proportion of oxygen contained in the sputtering gas to higher than 30% and lower than or equal to 100%, preferably higher than or equal to 70% and lower than or equal to 100% allows formation of an oxygen-excess oxide semiconductor. A transistor including an oxygen-excess oxide semiconductor in a channel formation region can have relatively high reliability. However, one embodiment of the present invention is not limited thereto. When the proportion of oxygen contained in the sputtering gas at the time of the film formation is higher than or equal to 1% and lower than or equal to 30%, preferably higher than or equal to 5% and lower than or equal to 20%, an oxygen-deficient oxide semiconductor is formed. A transistor including an oxygen-deficient oxide semiconductor in a channel formation region can have relatively high field-effect mobility. When the film formation is performed while the substrate is heated, the crystallinity of the oxide semiconductor layer can be improved.

Next, heat treatment is preferably performed. The heat treatment is preferably performed in a temperature range where the oxide semiconductor layer 230 does not become polycrystal. The temperature of the heat treatment is preferably higher than or equal to 100° C., higher than or equal to 250° C., or higher than or equal to 350° C. and lower than or equal to 650° C., lower than or equal to 600° C., or lower than or equal to 550° C. For the details of the heat treatment, the above description can be referred to.

The gas used in the above heat treatment preferably has high purity. The heat treatment using a highly purified gas can prevent the entry of moisture or the like into the oxide semiconductor layer 230 as much as possible.

In this embodiment, heat treatment is performed at 450° C. for one hour at a flow rate ratio of a nitrogen gas to an oxygen gas of 4:1. By the heat treatment using the oxygen gas, impurities such as carbon, water, and hydrogen in the oxide semiconductor layer 230 can be reduced. The reduction of impurities in the film improves the crystallinity of the oxide semiconductor layer 230, thereby offering a dense structure with higher density. Accordingly, the crystal region in the oxide semiconductor layer 230 can be expanded, and an in-plane variation of the crystal region in the oxide semiconductor layer 230 can be reduced. Thus, an in-plane variation of electrical characteristics of the transistors can be reduced.

In the case where the insulating layer 280 includes oxygen, oxygen is preferably supplied from the insulating layer 280 to the channel formation region of the oxide semiconductor layer 230 by the heat treatment. Accordingly, oxygen vacancies and VoH can be reduced.

The insulating layer 250 is formed in contact with the oxide semiconductor layer 230 provided in the opening 290 with a high aspect ratio. Thus, the insulating layer 250 is preferably formed by a film formation method achieving favorable coverage, and is further preferably formed by a CVD method, an ALD method, or the like.

When the insulating layer 250 is formed after the oxide semiconductor layer 230 is processed into an island shape, the side end portion of the oxide semiconductor layer 230 is covered with the insulating layer 250. Thus, a short circuit between the oxide semiconductor layer 230 and the conductive layer 260 can be prevented. Furthermore, in the above-described structure, the side end portion of the conductive layer 240 is covered with the insulating layer 250. Thus, a short circuit between the conductive layer 240 and the conductive layer 260 can be prevented.

Next, a conductive layer 260af is formed over the insulating layer 250, and a conductive layer 260bf is formed to be stacked over the conductive layer 260af (FIG. 5C).

The conductive layer 260af is formed in contact with the insulating layer 250 provided in the opening 290 with a high aspect ratio. Thus, the conductive layer 260af is preferably formed by a film formation method achieving favorable coverage, and is further preferably formed by a CVD method, an ALD method, or the like.

When the conductive layer 260bf is formed by a sputtering method, a CVD method, or the like, for example, a film with a large thickness can be favorably formed at a high film formation rate, making the manufacturing process efficient.

Next, a mask 278 is formed over the conductive layer 260bf. A resist mask can be used as the mask 278. Alternatively, as the mask 278, a structure in which an SOC (Spin On Carbon) film, an SOG (Spin On Glass) film, and a resist mask are stacked in this order over the conductive layer 260bf may be used.

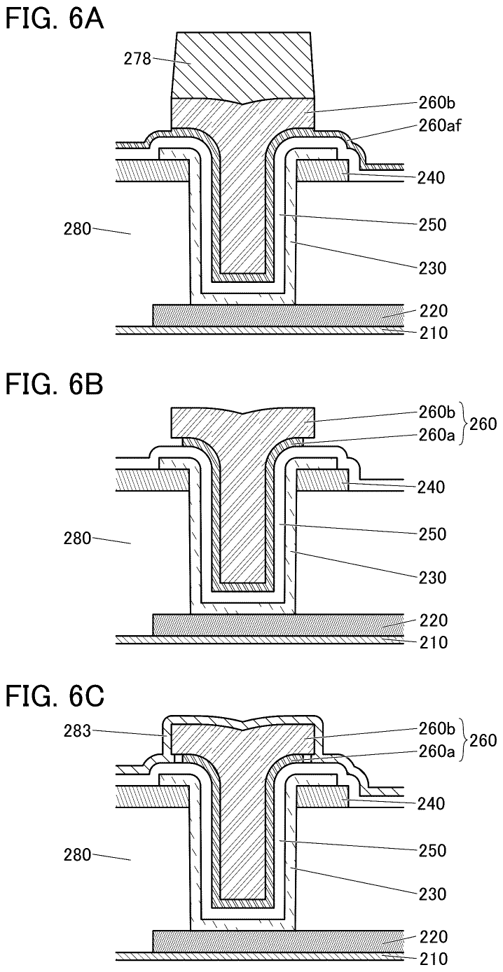

Next, the conductive layer 260bf is partially removed using the mask 278, so that the conductive layer 260b is formed (FIG. 6A). Note that as illustrated in FIG. 6A, in some cases, the conductive layer 260af is partially removed at the time of forming the conductive layer 260b to have a reduced thickness in a region not covered with the conductive layer 260bf.

For the partial removal of the conductive layer 260bf, it is preferable to use a dry etching method, which is suitable for microfabrication.

Next, the conductive layer 260af is partially removed to form the conductive layer 260a (FIG. 6B). Here, the conductive layer 260af is partially removed using the conductive layer 260b as a mask. Here, the mask 278 may remain at the time of forming the conductive layer 260a. In the case where the mask 278 remains, the conductive layer 260af is partially removed using the mask 278 and the conductive layer 260b as masks. In the case where the mask 278 remains, for example, the formation of the conductive layer 260a is followed by removal of the mask 278.

Note that at the time of processing the conductive layer 260a, the region of the conductive layer 260af that is not covered with the conductive layer 260b is removed. At this time, as illustrated in FIG. 6B, the region covered with the conductive layer 260b, e.g., the region receding inward from the end portion of the conductive layer 260b, is also removed. In the method for manufacturing the semiconductor device of one embodiment of the present invention, the conductive layer 260a is preferably formed such that its end portion is positioned inward from the end portion of the conductive layer 260b.

An isotropic etching condition is preferably used for the formation of the conductive layer 260a. A wet etching method, by which isotropic etching can be performed favorably, is preferable. In addition, the use of wet etching can reduce damage to a surface of the insulating layer 250 when the insulating layer 250 is exposed.

As a chemical solution for the wet etching, a chemical solution containing hydrogen peroxide can be used, for example. For example, a mixed solution of ammonia, hydrogen peroxide, and water can be used.

For another example, a chemical solution containing hydrogen peroxide and one or more of sulfuric acid and hydrochloric acid can be used.

As a chemical solution for the wet etching, a developer, an aqueous solution of tetramethylammonium hydroxide (TMAH), or the like can be used, for example.

As a chemical solution for the wet etching, for example, oxalic acid, phosphoric acid, acetic acid, nitric acid, or a chemical solution containing one or more of these acids can be used.

Next, the insulating layer 283 is formed over the insulating layer 250 and the conductive layer 260 (FIG. 6C). By the formation of the insulating layer 283, a gap is formed as the region 277, for example.

Alternatively, the formation of the insulating layer 283 fills the region 277 with the insulating layer 283, in which case the semiconductor device having the structure illustrated in FIG. 4A and FIG. 4B can be formed.

When a sputtering method, a PECVD method, or the like is used as a formation method of the insulating layer 283, the region 277 is likely to be a gap in some cases. When an ALD method, which achieves excellent coverage, is used as a formation method of the insulating layer 283, the region 277 is likely to be filled with the insulating layer 283 in some cases.

Through the above steps, the semiconductor device of one embodiment of the present invention can be manufactured.

### Manufacturing Method Example 2 of Semiconductor Device

Although wet etching is used for the formation of the conductive layer 260a in the manufacturing method example illustrated in FIG. 5 to FIG. 6, the formation of the conductive layer 260a is not limited to only wet etching. An example in which dry etching and wet etching are used in combination is described below.

First, the conductive layer 220, the insulating layer 280, the conductive layer 240, the oxide semiconductor layer 230, the insulating layer 250, the conductive layer 260af, and the conductive layer 260b over the insulating layer 210 are formed by the steps illustrated in FIG. 5A to FIG. 6A.

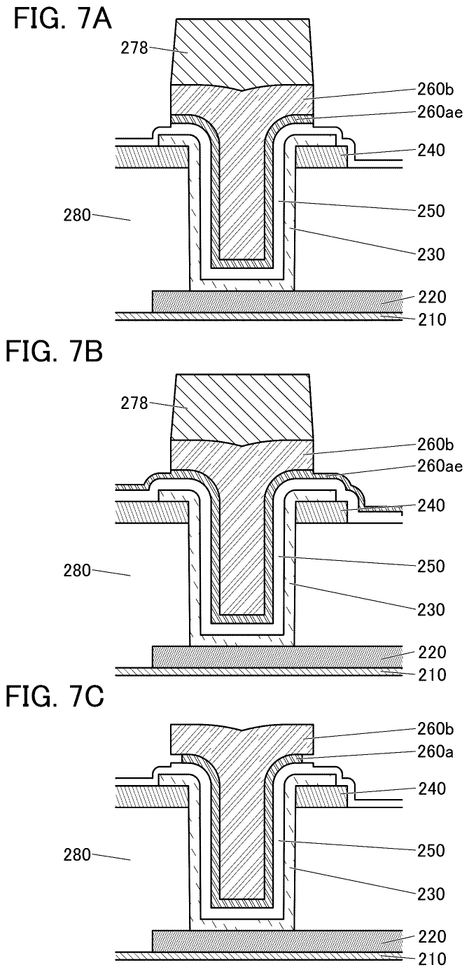

Next, the conductive layer 260af is partially removed using the mask 278 and the conductive layer 260b as masks, so that a conductive layer 260ae is formed (FIG. 7A). Here, dry etching is used for the formation of the conductive layer 260ae.

Note that the dry etching for the formation of the conductive layer 260ae and the dry etching for the formation of the conductive layer 260b may be performed successively.

Note that as illustrated in FIG. 7A, in some cases, the insulating layer 250 is partially removed at the time of forming the conductive layer 260ae to have a reduced thickness in a region not covered with the conductive layer 260ae.

When the conductive layer 260af is partially removed such that the insulating layer 250 is not exposed as illustrated in FIG. 7B, a reduction in the thickness of the insulating layer 250 can be inhibited.

Next, the conductive layer 260ae is partially removed by wet etching, so that the conductive layer 260a is formed (FIG. 7C). Here, the conductive layer 260ae is partially removed using the conductive layer 260b as a mask. Here, the mask 278 may remain at the time of forming the conductive layer 260a. In the case where the mask 278 remains, the conductive layer 260ae is partially removed using the mask 278 and the conductive layer 260b as masks. In the case where the mask 278 remains, for example, the formation of the conductive layer 260a is followed by removal of the mask 278.

For the conditions of the wet etching, the above-described conditions can be referred to. Note that in the case where the etching rate of the conductive layer 260af in the wet etching is low, the manufacturing process can be made efficient by using both dry etching and wet etching for the partial removal of the conductive layer 260af.

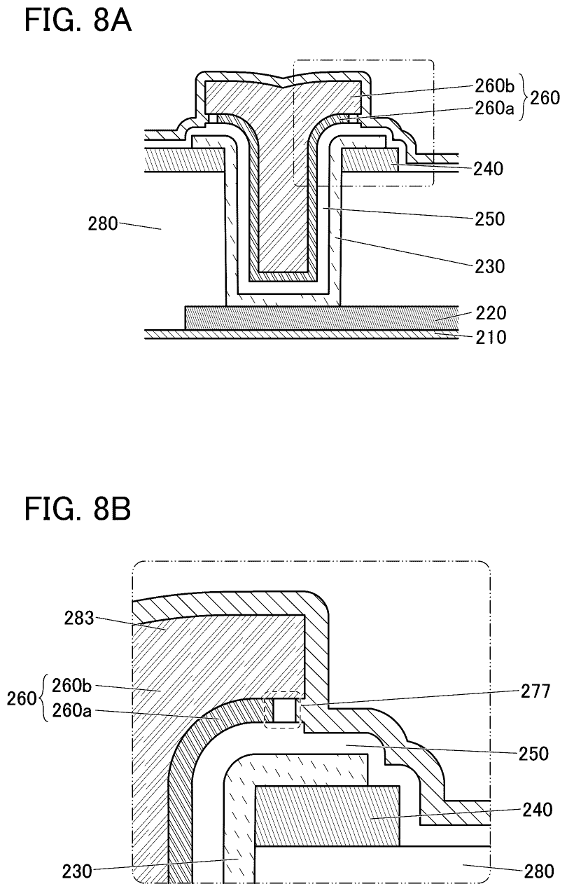

Next, the insulating layer 283 is formed over the insulating layer 250 and the conductive layer 260, whereby the semiconductor device of one embodiment of the present invention can be manufactured (FIG. 8A). FIG. 8B is an enlarged view of the region surrounded by the dashed double-dotted line in FIG. 8A.

Note that in the example illustrated in FIG. 8A and FIG. 8B, the insulating layer 250 has a smaller thickness in the region not overlapping with the conductive layer 260b, e.g., the region outside the region overlapping with the conductive layer 260b, than in the region overlapping with the conductive layer 260b.

This embodiment can be combined with any of the other embodiments as appropriate. In this specification, in the case where a plurality of structure examples are described in one embodiment, the structure examples can be combined as appropriate.

### Embodiment 2

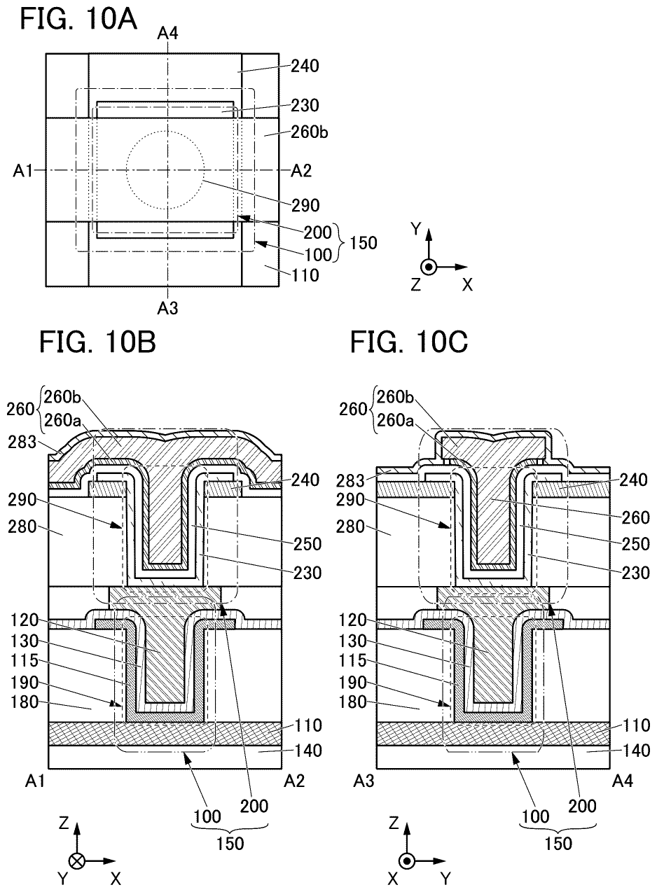

In this embodiment, memory devices of embodiments of the present invention will be described with reference to FIG. 10 to FIG. 13. The memory devices of embodiments of the present invention include a memory cell. The memory cell includes a transistor and a capacitor.

### Structure Example 1 of Memory Device

A structure of a memory device including a transistor and a capacitor is described with reference to FIG. 10A to FIG. 10C. FIG. 10A is a plan view of a memory device including the transistor 200 and a capacitor 100. FIG. 10B is a cross-sectional view taken along dashed-dotted line A1-A2 in FIG. 10A. FIG. 10C is a cross-sectional view taken along dashed-dotted line A3-A4 in FIG. 10A.

The memory device illustrated in FIG. 10A to FIG. 10C includes an insulating layer 140 over a substrate (not illustrated), a conductive layer 110 over the insulating layer 140, a memory cell 150 over the conductive layer 110, an insulating layer 180 over the conductive layer 110, the insulating layer 280, and the insulating layer 283 over the memory cell 150. The insulating layer 140, the insulating layer 180, the insulating layer 280, and the insulating layer 283 function as interlayer films. The conductive layer 110 functions as a wiring.

The memory cell 150 includes the capacitor 100 over the conductive layer 110 and the transistor 200 over the capacitor 100.

The capacitor 100 includes a conductive layer 115 over the conductive layer 110, an insulating layer 130 over the conductive layer 115, and a conductive layer 120 over the insulating layer 130. The conductive layer 120 functions as one of a pair of electrodes (sometimes referred to as an upper electrode), the conductive layer 115 functions as the other of the pair of electrodes (sometimes referred to as a lower electrode), and the insulating layer 130 functions as a dielectric. That is, the capacitor 100 forms a MIM (Metal-Insulator-Metal) capacitor.

As illustrated in FIG. 10B and FIG. 10C, an opening 190 reaching the conductive layer 110 is provided in the insulating layer 180. At least part of the conductive layer 115 is placed in the opening 190. Note that the conductive layer 115 includes a region in contact with the top surface of the conductive layer 110 in the opening 190, a region in contact with the side surface of the insulating layer 180 in the opening 190, and a region in contact with at least part of the top surface of the insulating layer 180. The insulating layer 130 is placed such that at least part of the insulating layer 130 is positioned in the opening 190. The conductive layer 120 is placed such that at least part of the conductive layer 120 is positioned in the opening 190. Note that the conductive layer 120 is preferably provided to fill the opening 190 as illustrated in FIG. 10B and FIG. 10C. Note that the films provided inside the opening 190 are preferably formed by an ALD method. In that case, the coverage with the films is favorable. For example, the conductive layer 115, the insulating layer 130, and the conductive layer 120 are preferably formed by an ALD method.

The upper electrode and the lower electrode of the capacitor 100 face each other with the dielectric therebetween, along the side surface of the opening 190 as well as the bottom surface thereof; thus, the capacitance per unit area can be higher. Accordingly, the deeper the opening 190 is, the higher the capacitance of the capacitor 100 can be. Increasing the capacitance per unit area of the capacitor 100 in this manner allows stable reading operation of the memory device. In addition, further miniaturization or higher integration of the memory device can be promoted.

In the example illustrated in FIG. 10B and FIG. 10C, the sidewall of the opening 190 is perpendicular to the top surface of the conductive layer 110. Here, the opening 190 has a cylindrical shape. Such a structure enables miniaturization or high integration of the memory device.

The conductive layer 115 and the insulating layer 130 are stacked along the sidewall of the opening 190 and the top surface of the conductive layer 110. The conductive layer 120 is provided over the insulating layer 130 to fill the opening 190. The capacitor 100 having such a structure may be referred to as a trench-type capacitor or a trench capacitor.

The insulating layer 280 is provided over the capacitor 100. That is, the insulating layer 280 is positioned over the conductive layer 115, the insulating layer 130, and the conductive layer 120. In other words, the conductive layer 120 is positioned under the insulating layer 280.

The transistor 200 includes the conductive layer 120 (corresponding to the conductive layer 220 in FIG. 1B or the like), the conductive layer 240 over the insulating layer 280, the oxide semiconductor layer 230, the insulating layer 250 over the oxide semiconductor layer 230, and the conductive layer 260 over the insulating layer 250. The oxide semiconductor layer 230 functions as the semiconductor layer, the conductive layer 260 functions as the gate electrode, the insulating layer 250 functions as the gate insulating layer, the conductive layer 120 functions as the one of the source electrode and the drain electrode, and the conductive layer 240 functions as the other of the source electrode and the drain electrode.

The description in Embodiment 1 (FIG. 1 and FIG. 2) can be referred to for the transistor 200; thus, the detailed description thereof is omitted. The transistor included in the memory cell 150 is not limited to the transistor 200, and any of the transistors described as examples in Embodiment 1 can be used.

As illustrated in FIG. 10A to FIG. 10C, the transistor 200 is provided to overlap with the capacitor 100. The opening 290 where part of the components of the transistor 200 is provided includes a region overlapping with the opening 190 where part of the components of the capacitor 100 is provided. Specifically, since the conductive layer 120 has a function of the one of the source electrode and the drain electrode of the transistor 200 and a function of the upper electrode of the capacitor 100, the transistor 200 and the capacitor 100 partly share the structure. With such a structure, the transistor 200 and the capacitor 100 can be provided without an increase in the footprint in a plan view. Thus, the footprint of the memory cell 150 can be reduced, so that the memory cells 150 can be arranged densely and the storage capacity of the memory device can be increased. In other words, the memory device can be highly integrated.

Since the transistor 200 is provided above the capacitor 100, the transistor 200 is not affected by heat treatment in manufacturing the capacitor 100. Thus, in the transistor 200, degradation of the electrical characteristics such as a variation in threshold voltage or an increase in parasitic resistance, an increase in variation in electrical characteristics due to the degradation of the electrical characteristics, and the like can be inhibited.

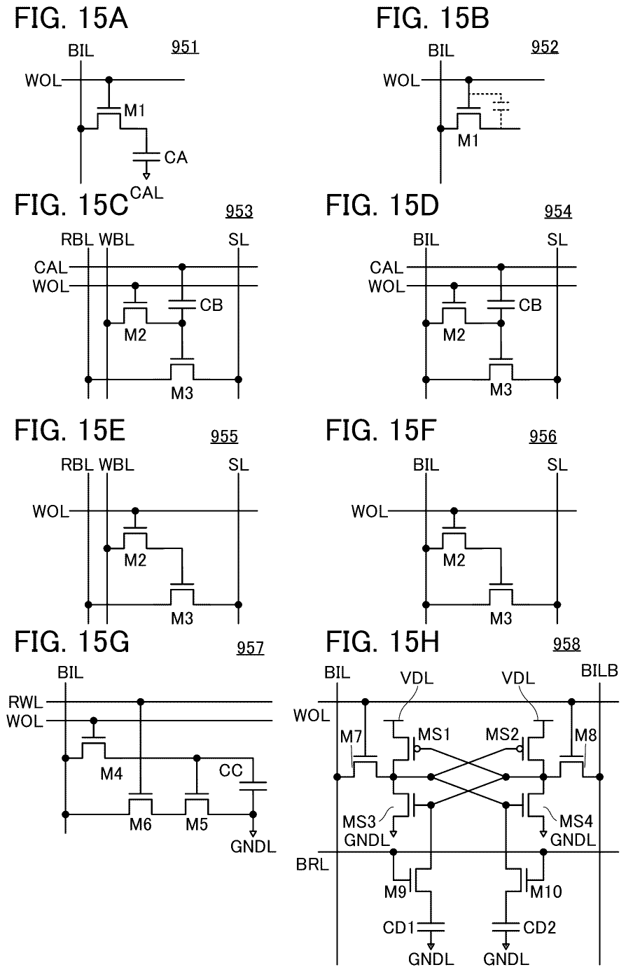

FIG. 15A is a circuit diagram of the memory device described in this embodiment. As illustrated in FIG. 15A, the structure illustrated in FIG. 10A to FIG. 10C functions as a memory cell. A memory cell 951 includes a transistor M1 and a capacitor CA. Here, the transistor M1 corresponds to the transistor 200, and the capacitor CA corresponds to the capacitor 100.

One of a source and a drain of the transistor M1 is connected to one of a pair of electrodes of the capacitor CA. The other of the source and the drain of the transistor M1 is connected to a wiring BIL. A gate of the transistor M1 is connected to a wiring WOL. The other of the pair of electrodes of the capacitor CA is connected to a wiring CAL.

Here, the wiring BIL corresponds to the conductive layer 240, the wiring WOL corresponds to the conductive layer 260, and the wiring CAL corresponds to the conductive layer 110. As illustrated in FIG. 10A to FIG. 10C, it is preferable that the conductive layer 260 be provided to extend in the X direction and the conductive layer 240 be provided to extend in the Y direction. With such a structure, the wiring BIL and the wiring WOL are provided to intersect with each other. Although the wiring CAL (the conductive layer 110) is provided in a planar shape in FIG. 10A, the present invention is not limited thereto. For example, the wiring CAL may be provided parallel to the wiring WOL (the conductive layer 260) or may be provided parallel to the wiring BIL (the conductive layer 240).

Note that the memory cell will be described in detail in a later embodiment.

### [Capacitor 100]

The capacitor 100 includes the conductive layer 115, the insulating layer 130, and the conductive layer 120. The conductive layer 110 is provided below the conductive layer 115. The conductive layer 115 includes a region in contact with the conductive layer 110.

The conductive layer 110 is provided over the insulating layer 140. The conductive layer 110 functions as the wiring CAL and can be provided in a planar shape, for example. The conductive layer 110 can be formed as a single layer or stacked layers using any of the conductive materials described in [Conductive layer] in Embodiment 1. For example, a conductive material with high conductivity such as tungsten can be used for the conductive layer 110. With the use of such a conductive material with high conductivity, the conductive layer 110 can have improved conductivity and can work well as the wiring CAL.

The conductive layer 115 is preferably formed using a single layer or stacked layers of a conductive material that is less likely to be oxidized, a conductive material having a function of inhibiting diffusion of oxygen, or the like. For example, titanium nitride, indium tin oxide to which silicon is added, or the like may be used. Alternatively, a structure where titanium nitride is stacked over tungsten may be used, for example. Alternatively, a structure where tungsten is stacked over first titanium nitride and second titanium nitride is stacked over the tungsten may be used, for example. With such a structure, when an oxide is used for the insulating layer 130, the conductive layer 110 can be inhibited from being oxidized by the insulating layer 130. When an oxide is used for the insulating layer 180, the conductive layer 110 can be inhibited from being oxidized by the insulating layer 180.

The insulating layer 130 is provided over the conductive layer 115. The insulating layer 130 is provided to be in contact with the top surface and the side surface of the conductive layer 115. That is, the insulating layer 130 preferably covers the side end portion of the conductive layer 115. This can prevent a short circuit between the conductive layer 115 and the conductive layer 120.

Alternatively, the side end portion of the insulating layer 130 and the side end portion of the conductive layer 115 may be aligned with each other. With such a structure, the insulating layer 130 and the conductive layer 115 can be formed using the same mask, so that the manufacturing process of the memory device can be simplified.

For the insulating layer 130, a high relative permittivity (high-k) material is preferably used. Using a high-k material for the insulating layer 130 allows the insulating layer 130 to be thick enough to inhibit a leakage current and the capacitor 100 to have sufficiently high capacitance.

For the insulating layer 130, a stack of insulating layers formed of high-k materials is preferably used, and a stacked-layer structure of a high relative permittivity (high-k) material and a material having higher dielectric strength than the high-k material is preferably used. For example, for the insulating layer 130, an insulating film in which zirconium oxide, aluminum oxide, and zirconium oxide are stacked in this order can be used. An insulating film in which zirconium oxide, aluminum oxide, zirconium oxide, and aluminum oxide are stacked in this order can be used, for example. For another example, an insulating film in which hafnium zirconium oxide, aluminum oxide, hafnium zirconium oxide, and aluminum oxide are stacked in this order can be used. The use of stacked insulating layers with relatively high dielectric strength, such as aluminum oxide, can increase the dielectric strength and inhibit electrostatic breakdown of the capacitor 100.

Alternatively, a material that can have ferroelectricity may be used for the insulating layer 130. Description in Embodiment 1 can also be referred to for the details of the material that can have ferroelectricity.

A metal oxide containing one or both of hafnium and zirconium can have ferroelectricity even when being processed into a thin film of several nanometers and is thus preferable for the insulating layer 130. The thickness of the insulating layer 130 is preferably less than or equal to 100 nm, further preferably less than or equal to 50 nm, still further preferably less than or equal to 20 nm, yet still further preferably less than or equal to 10 nm (typically, greater than or equal to 2 nm and less than or equal to 9 nm). For example, the thickness is preferably greater than or equal to 8 nm and less than or equal to 12 nm. When a ferroelectric layer that can be thinned is used, the capacitor 100 can be combined with a semiconductor element such as a miniaturized transistor to form a semiconductor device.

A metal oxide containing one or both of hafnium and zirconium can have ferroelectricity even with a minute area and is thus preferable for the insulating layer 130. For example, the metal oxide can have ferroelectricity even with an area (footprint) of a ferroelectric layer of less than or equal to 100 μm², less than or equal to 10 μm², less than or equal to 1 μm², or less than or equal to 0.1 μm² in a plan view. Furthermore, even with an area of less than or equal to 10000 nm² or less than or equal to 1000 nm², the metal oxide has ferroelectricity in some cases. With a small-area ferroelectric layer, the footprint of the capacitor 100 can be reduced.

The ferroelectric is an insulator and has a property of causing internal polarization by application of an electric field from the outside and maintaining the polarization even after the electric field is made zero. Thus, with a capacitor that includes this material as a dielectric (hereinafter, the capacitor may be referred to as a ferroelectric capacitor), a nonvolatile memory element can be formed. A nonvolatile memory element that includes a ferroelectric capacitor is sometimes referred to as an FeRAM (Ferroelectric Random Access Memory), a ferroelectric memory, or the like. For example, a ferroelectric memory includes a transistor and a ferroelectric capacitor, and one of a source and a drain of the transistor is electrically connected to one terminal of the ferroelectric capacitor. Thus, in the case of using a ferroelectric capacitor as the capacitor 100, the memory device described in this embodiment functions as a ferroelectric memory.

The conductive layer 120 is provided in contact with part of the top surface of the insulating layer 130. The side end portion of the conductive layer 120 is preferably positioned inward from the side end portion of the conductive layer 115 in both the X direction and the Y direction. Note that in the structure where the insulating layer 130 covers the side end portion of the conductive layer 115, the side end portion of the conductive layer 120 may be positioned outward from the side end portion of the conductive layer 115.

The conductive layer 120 can be formed as a single layer or stacked layers using any of the conductive materials described in [Conductive layer] in Embodiment 1. A conductive material that is not easily oxidized, a conductive material having a function of inhibiting diffusion of oxygen, or the like is preferably used for the conductive layer 120. For example, titanium nitride, tantalum nitride, or the like can be used. For example, a structure in which tantalum nitride is stacked over titanium nitride may be used. In that case, titanium nitride is in contact with the insulating layer 130 and tantalum nitride is in contact with the oxide semiconductor layer 230. With such a structure, the conductive layer 120 can be inhibited from being excessively oxidized by the oxide semiconductor layer 230. In the case of using an oxide for the insulating layer 130, the conductive layer 120 can be inhibited from being excessively oxidized by the insulating layer 130. Alternatively, the conductive layer 120 may have a structure in which tungsten is stacked over titanium nitride, for example.

The conductive layer 120 includes a region in contact with the oxide semiconductor layer 230 and thus is preferably formed using a conductive material containing oxygen. When the conductive layer 120 is formed using a conductive material containing oxygen, the conductive layer 120 can maintain its conductivity even after absorbing oxygen. In addition, also in the case of using an insulating layer containing oxygen, e.g., zirconium oxide, as the insulating layer 130, the conductive layer 120 can maintain its conductivity, which is preferable. As the conductive layer 120, a single layer or stacked layers of ITO, ITSO, IZO (registered trademark), or the like can be used, for example.

Since the insulating layer 180 functions as an interlayer film, the insulating layer 180 preferably has low relative permittivity. When a material with low relative permittivity is used for an interlayer film, the parasitic capacitance generated between wirings can be reduced. As the insulating layer 180, a single insulating layer or stacked insulating layers including a material with low relative permittivity can be used. Silicon oxide and silicon oxynitride, which have thermal stability, are preferable.

Although the insulating layer 180 is shown as a single layer in FIG. 10B and FIG. 10C, the present invention is not limited thereto. The insulating layer 180 may have a stacked-layer structure of two layers or a stacked-layer structure of three or more layers.

### Structure Example 2 of Memory Device

The memory cell 150 with the transistor 200 and the capacitor 100 described in this embodiment can be used as a memory cell of a memory device. The transistor 200 is a transistor whose channel is formed in a semiconductor layer including an oxide semiconductor. Since the transistor 200 has a low off-state current, a memory device including the transistor 200 can retain stored data for a long time. In other words, such a memory device does not require refresh operation or has extremely low frequency of the refresh operation, which leads to a sufficient reduction in power consumption of the memory device. The transistor 200 has high frequency characteristics and thus enables the memory device to perform reading and writing at high speed.

A memory cell array can be formed when the memory cells 150 are three-dimensionally arranged in a matrix.

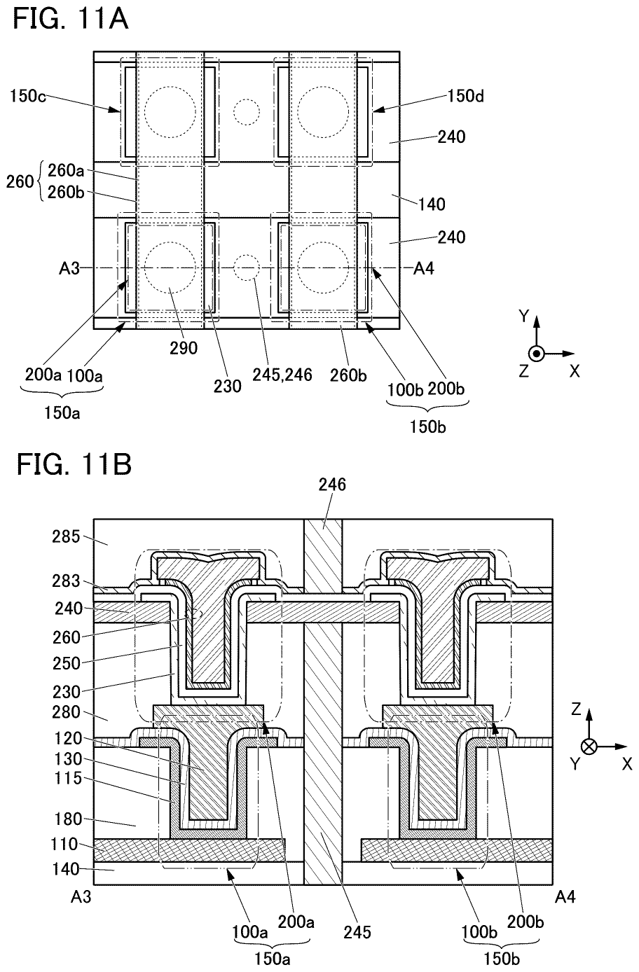

FIG. 11A is a plan view of a memory device. FIG. 11A illustrates an example where 2×2 memory cells (a memory cell 150a to a memory cell 150d) are arranged in the X direction and the Y direction.

FIG. 11B is a cross-sectional view taken along dashed-dotted line A3-A4 in FIG. 11A. In FIG. 11A and FIG. 11B, two memory cells (the memory cell 150a and the memory cell 150b in FIG. 11B) are connected to a common wiring (a conductive layer 246).

Here, the memory cell 150a and the memory cell 150b illustrated in FIG. 11A and FIG. 11B each have a structure similar to that of the memory cell 150. The memory cell 150a includes a capacitor 100a and a transistor 200a, and the memory cell 150b includes a capacitor 100b and a transistor 200b. The memory cell 150c and the memory cell 150d illustrated in FIG. 11A each have a structure similar to that of the memory cell 150. Thus, in the memory device illustrated in FIG. 11A and FIG. 11B, components having the same functions as the components of the memory device illustrated in FIG. 10 are denoted by the same reference numerals. The description of the memory cell 150 in <Structure example 1 of memory device> can be referred to for the details of the memory cell 150a to the memory cell 150d.

As illustrated in FIG. 11A and FIG. 11B, the conductive layer 260 functioning as the wiring WOL is provided in each of the memory cell 150a and the memory cell 150b. As illustrated in FIG. 11A, one conductive layer 260 is shared by the memory cell 150a and the memory cell 150c, and another conductive layer 260 is shared by the memory cell 150b and the memory cell 150d. One conductive layer 240 functioning as part of the wiring BIL is shared by the memory cell 150a and the memory cell 150b. That is, the conductive layer 240 is in contact with the oxide semiconductor layer 230 of the memory cell 150a and the oxide semiconductor layer 230 of the memory cell 150b. Another conductive layer 240 is shared by the memory cell 150c and the memory cell 150d.

Here, the memory device illustrated in FIG. 11A and FIG. 11B includes a conductive layer 245 and the conductive layer 246 electrically connected to the memory cell 150a and the memory cell 150b and functioning as plugs (which can also be referred to as connection electrodes). The conductive layer 245 is placed in an opening formed in the insulating layer 140, the insulating layer 180, the insulating layer 130, and the insulating layer 280, and is in contact with the bottom surface of the conductive layer 240. The conductive layer 246 is placed in an opening formed in the insulating layer 285, the insulating layer 283, and the insulating layer 250, and is in contact with the top surface of the conductive layer 240. Note that a conductive material that can be used for the conductive layer 240, for example, can be used for the conductive layer 245 and the conductive layer 246.

The insulating layer 285 functions as an interlayer film and thus, the insulating layer 285 preferably has low relative permittivity. When a material with low relative permittivity is used for an interlayer film, the parasitic capacitance generated between wirings can be reduced.

The concentration of impurities such as water and hydrogen in the insulating layer 285 is preferably reduced. In that case, entry of impurities such as water and hydrogen into the channel formation region of the oxide semiconductor layer 230 can be inhibited.

The conductive layer 245 and the conductive layer 246 each function as a plug or a wiring for electrically connecting the memory cell 150a and the memory cell 150b to a wiring, an electrode, a terminal, or a circuit element such as a switch, a transistor, a capacitor, an inductor, a resistor, or a diode. For example, the conductive layer 245 can be electrically connected to a sense amplifier (not illustrated) provided below the memory device illustrated in FIG. 11B, and the conductive layer 246 can be electrically connected to a similar memory device (not illustrated) provided above the memory device illustrated in FIG. 11B. In that case, the conductive layer 245 and the conductive layer 246 function as part of the wiring BIL. When the memory device or the like is provided above or below the memory device illustrated in FIG. 11B in this manner, the storage capacity per unit area can be increased.

The memory cell 150a and the memory cell 150b have a line-symmetric structure with a perpendicular bisector of the dashed-dotted line A3-A4 as the symmetric axis. Thus, the transistor 200a and the transistor 200b are also placed symmetrically with the conductive layer 245 and the conductive layer 246 therebetween. Note that the conductive layer 240 has a function of the other of a source electrode and a drain electrode of the transistor 200a and a function of the other of a source electrode and a drain electrode of the transistor 200b. The transistor 200a and the transistor 200b share the conductive layer 245 and the conductive layer 246 functioning as plugs. With the above connection structure between the two transistors and the plugs, a memory device that can be miniaturized or highly integrated can be provided.

Note that the conductive layer 110 functioning as the wiring CAL may be provided in each of the memory cell 150a and the memory cell 150b or may be provided to be shared by the memory cell 150a and the memory cell 150b. However, as illustrated in FIG. 11B, the conductive layer 110 is provided to be apart from the conductive layer 245 so that the conductive layer 110 and the conductive layer 245 are not short-circuited.

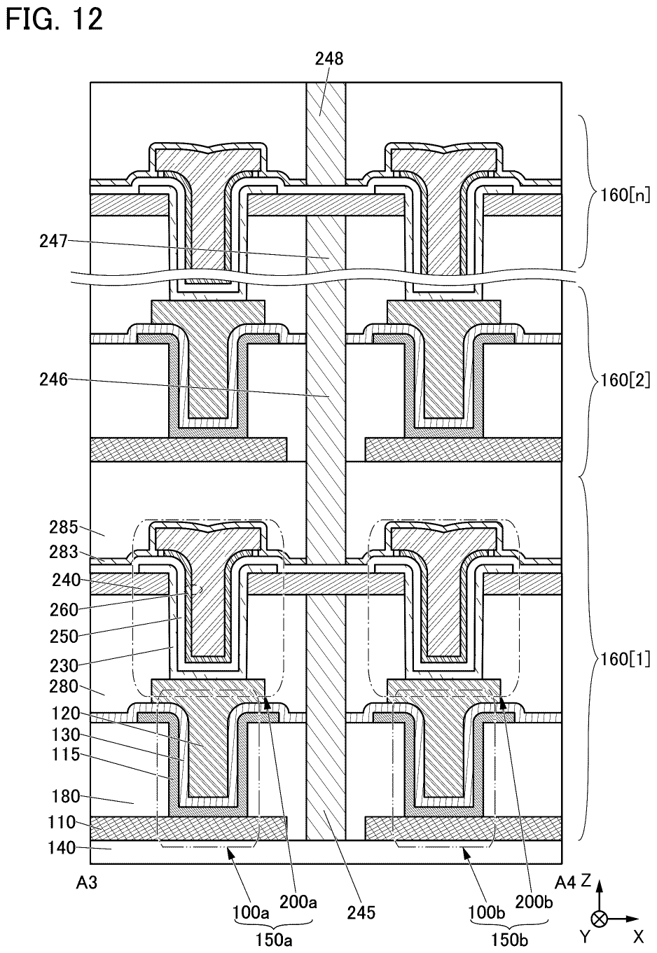

FIG. 12 illustrates an example where four of the memory cells illustrated in FIG. 11A are stacked in n layers (n is an integer greater than or equal to 3) in the Z direction. FIG. 12 is a cross-sectional view taken along dashed-dotted line A3-A4 in FIG. 11A.

The memory device illustrated in FIG. 12 includes n memory layers 160. Specifically, a memory layer 160[2] is provided over a memory layer 160[1], (n−2) memory layers are provided over the memory layer 160[2], and a memory layer 160[n] is provided in the uppermost stage. There is no particular limitation on the number of memory cells included in one memory layer 160, and two or more memory cells can be included. Through the conductive layer 245, the conductive layer 246, a conductive layer 247, a conductive layer 248, and the like, memory cells included in the n memory layers 160 are electrically connected to a sense amplifier (not illustrated) provided below the n memory layers 160.

When a plurality of memory cells are stacked as illustrated in FIG. 12, the cells can be provided in an integrated manner without increasing the footprint of the memory cell array. That is, a 3D memory cell array can be formed.

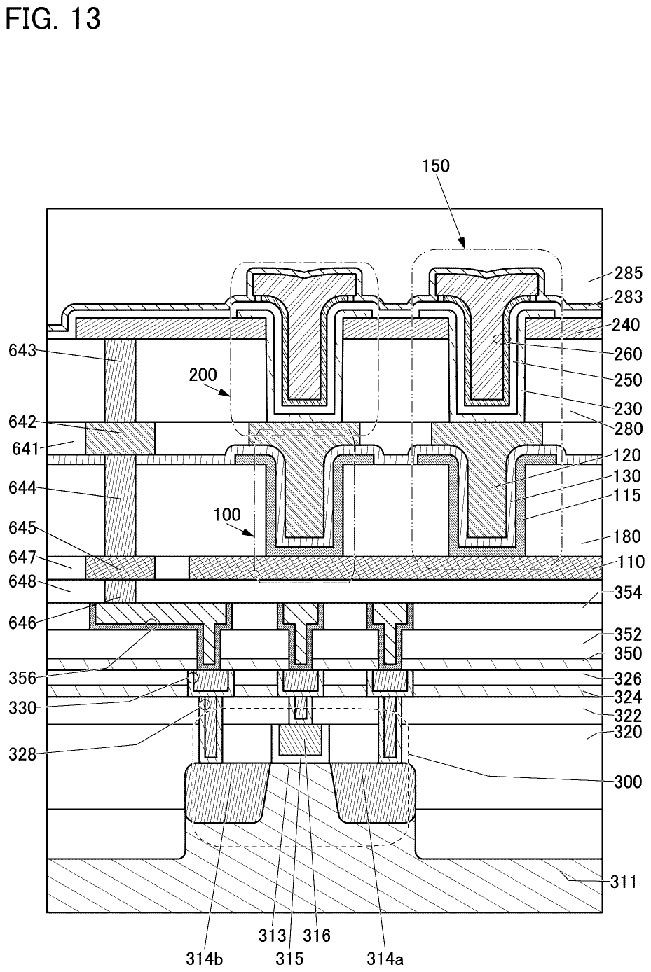

FIG. 13 illustrates a cross-sectional structure example of a memory device in which a layer including a memory cell is stacked over a layer including a driver circuit provided with a sense amplifier.

In FIG. 13, the memory cell 150 (the transistor 200 and the capacitor 100) is provided above a transistor 300.

The transistor 300 is one of the transistors included in the sense amplifier.

For the memory cell 150 illustrated in FIG. 13, the description of the memory cell 150 in <Structure example 1 of memory device> can be referred to.

When the sense amplifier is provided to overlap with the memory cell 150 as illustrated in FIG. 13, a bit line can be shortened. This reduces bit line capacitance, which can reduce the storage capacity of the memory cell. Thus, the memory device can be driven at high speed.

The memory device illustrated in FIG. 13 can correspond to a semiconductor device 900 described in Embodiment 3. Specifically, the transistor 300 corresponds to a transistor included in a sense amplifier 927 in the semiconductor device 900. The memory cell 150 corresponds to a memory cell 950.

The transistor 300 is provided on a substrate 311 and includes a conductive layer 316 functioning as a gate, an insulating layer 315 functioning as a gate insulating layer, a semiconductor region 313 that is part of the substrate 311, and a low-resistance region 314a and a low-resistance region 314b functioning as a source region and a drain region. The transistor 300 may be a p-channel transistor or an n-channel transistor.

Here, in the transistor 300 illustrated in FIG. 13, the semiconductor region 313 (part of the substrate 311) where a channel is formed has a protruding shape. Furthermore, the conductive layer 316 is provided to cover the side surface and the top surface of the semiconductor region 313 with the insulating layer 315 therebetween. Note that the conductive layer 316 may be formed using a material for adjusting the work function. Such a transistor 300 is also referred to as a FIN-type transistor because it utilizes the protruding portion of the semiconductor substrate. Note that an insulating layer functioning as a mask for forming the protruding portion may be provided in contact with an upper portion of the protruding portion. Although the case where the protruding portion is formed by processing part of the semiconductor substrate is described here, a semiconductor film having a protruding shape may be formed by processing an SOI substrate.

Note that the transistor 300 illustrated in FIG. 13 is an example and is not limited to the structure; an appropriate transistor can be used in accordance with a circuit structure or a driving method.

Wiring layers including an interlayer film, a wiring, a plug, and the like may be provided between the structure bodies. A plurality of wiring layers can be provided in accordance with the design. Here, a plurality of conductive layers functioning as plugs or wirings are collectively denoted by the same reference numeral in some cases. Furthermore, in this specification and the like, a wiring and a plug electrically connected to the wiring may be a single component. That is, in some cases, part of a conductive layer functions as a wiring or part of a conductive layer functions as a plug.

For example, an insulating layer 320, an insulating layer 322, an insulating layer 324, and an insulating layer 326 are sequentially stacked as interlayer films over the transistor 300. A conductive layer 328 is embedded in the insulating layer 320 and the insulating layer 322, and a conductive layer 330 is embedded in the insulating layer 324 and the insulating layer 326. Note that the conductive layer 328 and the conductive layer 330 each function as a plug or a wiring.

The insulating layers functioning as interlayer films may also function as planarization films that cover uneven shapes therebelow. For example, the top surface of the insulating layer 322 may be planarized by planarization treatment using a CMP method or the like to have improved planarity.

A wiring layer may be provided over the insulating layer 326 and the conductive layer 330. For example, in FIG. 13, an insulating layer 350, an insulating layer 352, and an insulating layer 354 are stacked sequentially. Furthermore, a conductive layer 356 is formed in the insulating layer 350, the insulating layer 352, and the insulating layer 354. The conductive layer 356 functions as a plug or a wiring.

As each of the insulating layer 352, the insulating layer 354, and the like, which function as interlayer films, the above-described insulating layer that can be used for the semiconductor device or the memory device can be used.

For the conductive layer functioning as a plug or a wiring, such as the conductive layer 328, the conductive layer 330, and the conductive layer 356, a conductive material that can be used for the conductive layer 240 can be used. It is preferable to use a high-melting-point material that has both heat resistance and conductivity, such as tungsten or molybdenum, and it is preferable to use tungsten. Alternatively, a low-resistance conductive material such as aluminum or copper is preferably used for formation. The use of a low-resistance conductive material can reduce wiring resistance.

The conductive layer 240 included in the transistor 200 is electrically connected to the low-resistance region 314b functioning as the source region or the drain region of the transistor 300 through a conductive layer 643, a conductive layer 642, a conductive layer 644, a conductive layer 645, a conductive layer 646, the conductive layer 356, the conductive layer 330, and the conductive layer 328.

The conductive layer 643 is embedded in the insulating layer 280. The conductive layer 642 is provided over the insulating layer 130 and is embedded in an insulating layer 641. The conductive layer 642 and the conductive layer 120 can be formed using the same material in the same step. The conductive layer 644 is embedded in the insulating layer 180 and the insulating layer 130. The conductive layer 645 is embedded in an insulating layer 647. The conductive layer 645 and the conductive layer 110 can be formed using the same material in the same step. The conductive layer 646 is embedded in an insulating layer 648. The transistor 300 and the conductive layer 110 are electrically insulated from each other by the insulating layer 648.

As described above, the memory device of this embodiment includes the transistor with reduced parasitic capacitance, and thus can have higher operation speed. In addition, since the memory device of this embodiment includes the capacitor and the transistor that overlap with each other, the footprint of the memory cell in a plan view can be reduced and the memory device can achieve a high degree of integration.

This embodiment can be combined with any of the other embodiments as appropriate.

### Embodiment 3

In this embodiment, the semiconductor device 900 of one embodiment of the present invention will be described. The semiconductor device 900 can function as a memory device.

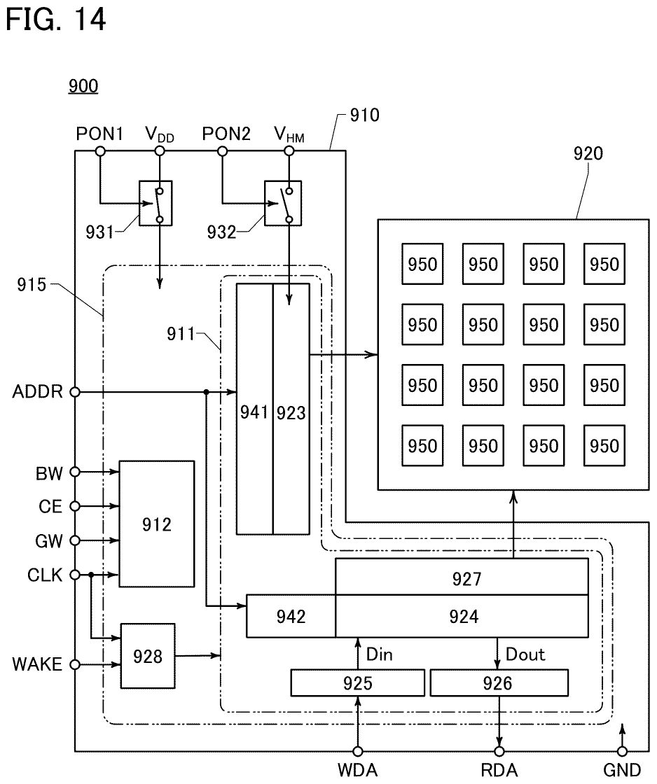

FIG. 14 is a block diagram illustrating a structure example of the semiconductor device 900. The semiconductor device 900 illustrated in FIG. 14 includes a driver circuit 910 and a memory array 920. The memory array 920 includes one or more memory cells 950. FIG. 14 illustrates an example in which the memory array 920 includes a plurality of the memory cells 950 arranged in a matrix.

The memory device (e.g., the memory cell 150) described in Embodiment 2 can be used for the memory cell 950.

The driver circuit 910 includes a PSW 931 (power switch), a PSW 932, and a peripheral circuit 915. The peripheral circuit 915 includes a peripheral circuit 911, a control circuit 912, and a voltage generation circuit 928.

In the semiconductor device 900, the circuits, signals, and voltages can be appropriately selected as needed. Another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside. The signal CLK is a clock signal.

The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. Note that the signal PON1 and the signal PON2 may be generated in the control circuit 912.

The control circuit 912 is a logic circuit having a function of controlling the overall operation of the semiconductor device 900. For example, the control circuit 912 performs logical operation on the signal CE, the signal GW, and the signal BW to determine the operating mode (e.g., write operation or read operation) of the semiconductor device 900. The control circuit 912 generates a control signal for the peripheral circuit 911 so that the operating mode is executed.

The voltage generation circuit 928 has a function of generating a negative voltage. The signal WAKE has a function of controlling the input of the signal CLK to the voltage generation circuit 928. For example, when an H-level signal is applied as the signal WAKE, the signal CLK is input to the voltage generation circuit 928, and the voltage generation circuit 928 generates a negative voltage.

The peripheral circuit 911 is a circuit for writing and reading data to/from the memory cell 950. The peripheral circuit 911 includes a row decoder 941, a column decoder 942, a row driver 923, a column driver 924, an input circuit 925, an output circuit 926, and the sense amplifier 927.

The row decoder 941 and the column decoder 942 have a function of decoding the signal ADDR. The row decoder 941 is a circuit for specifying a row to be accessed. The column decoder 942 is a circuit for specifying a column to be accessed. The row driver 923 has a function of selecting the row specified by the row decoder 941. The column driver 924 has a function of writing data to the memory cell 950, reading data from the memory cell 950, and retaining the read data, for example.

The input circuit 925 has a function of retaining the signal WDA. Data retained in the input circuit 925 is output to the column driver 924. Data output from the input circuit 925 is data (Din) written to the memory cell 950. Data (Dout) read from the memory cell 950 by the column driver 924 is output to the output circuit 926. The output circuit 926 has a function of retaining Dout. Moreover, the output circuit 926 has a function of outputting Dout to the outside of the semiconductor device 900. The data output from the output circuit 926 is the signal RDA.

The PSW 931 has a function of controlling the supply of VDD to the peripheral circuit 915. The PSW 932 has a function of controlling the supply of VHM to the row driver 923. Here, in the semiconductor device 900, a high power supply voltage is VDD and a low power supply voltage is GND (ground potential). In addition, VHM is a high power supply voltage used for setting a word line at a high level, and is higher than VDD. The on/off state of the PSW 931 is controlled by the signal PON1, and the on/off state of the PSW 932 is controlled by the signal PON2. The number of power domains to which VDD is supplied is one in the peripheral circuit 915 in FIG. 14 but can be more than one. In that case, a power switch is provided for each power domain.

Structure examples of a memory cell that can be used for the memory cell 950 are described with reference to FIG. 15A to FIG. 15H.

In the following description, the expression “two components are connected to each other” includes the case where the two components are electrically connected through a circuit element (a transistor, a switch, a diode, a resistor, or the like). The term “electrical connection” means a state where a current can flow between two components. Note that the term “electrical connection” encompasses the case where two components are connected through a switch or a transistor because a current can flow when the switch or the transistor is in an on state.

### [DOSRAM]

FIG. 15A illustrates a circuit structure example of a memory cell for a DRAM. In this specification and the like, a DRAM including an OS transistor is referred to as a DOSRAM (Dynamic Oxide Semiconductor Random Access Memory). The memory cell 951 includes the transistor M1 and the capacitor CA.

Note that the transistor M1 may include a front gate (simply referred to as a gate in some cases) and a back gate. Here, the back gate may be connected to a wiring supplied with a constant potential or a signal, and the front gate and the back gate may be connected to each other.

A first terminal of the transistor M1 is connected to a first terminal of the capacitor CA. A second terminal of the transistor M1 is connected to the wiring BIL. The gate of the transistor M1 is connected to the wiring WOL. A second terminal of the capacitor CA is connected to the wiring CAL.

The wiring BIL functions as a bit line, and the wiring WOL functions as a word line. The wiring CAL functions as a wiring for applying a predetermined potential to the second terminal of the capacitor CA. At the time of data writing and reading, a low-level potential (sometimes referred to as a reference potential) is preferably applied to the wiring CAL.

Data writing and reading are performed in the following manner: a high-level potential is applied to the wiring WOL to turn on the transistor M1 and establish electrical continuity between the wiring BIL and the first terminal of the capacitor CA (make a state where a current can flow therebetween).

The memory cell that can be used as the memory cell 950 is not limited to the memory cell 951, and the circuit structure can be changed. For example, a memory cell 952 illustrated in FIG. 15B may be used. The memory cell 952 is an example including neither the capacitor CA nor the wiring CAL. The first terminal of the transistor M1 is in an electrically floating state.

In the memory cell 952, a potential written through the transistor M1 is retained in a capacitor (also referred to as parasitic capacitance) between the first terminal and the gate, which is shown by a dashed line. Such a structure can greatly simplify the structure of the memory cell.

Note that an OS transistor is preferably used as the transistor M1. An OS transistor has a characteristic of an extremely low off-state current. The use of an OS transistor as the transistor M1 enables an extremely low leakage current of the transistor M1. That is, written data can be retained for a long time with the transistor M1, and thus, the frequency of refresh operation for the memory cell can be reduced. Alternatively, refresh operation for the memory cell can be unnecessary. In addition, the extremely low leakage current allows multi-level data or analog data to be retained in the memory cell 951 and the memory cell 952.

### [NOSRAM]

FIG. 15C illustrates a circuit structure example of a gain-cell memory cell including two transistors and one capacitor. A memory cell 953 includes a transistor M2, a transistor M3, and a capacitor CB. In this specification and the like, a memory device with a gain-cell memory cell including an OS transistor as the transistor M2 is referred to as a NOSRAM (Nonvolatile Oxide Semiconductor RAM).

A first terminal of the transistor M2 is connected to a first terminal of the capacitor CB. A second terminal of the transistor M2 is connected to a wiring WBL. A gate of the transistor M2 is connected to the wiring WOL. A second terminal of the capacitor CB is connected to the wiring CAL. A first terminal of the transistor M3 is connected to a wiring RBL. A second terminal of the transistor M3 is connected to a wiring SL. A gate of the transistor M3 is connected to the first terminal of the capacitor CB.

The wiring WBL functions as a write bit line, the wiring RBL functions as a read bit line, and the wiring WOL functions as a word line. The wiring CAL functions as a wiring for applying a predetermined potential to the second terminal of the capacitor CB. At the time of data writing, during data retention, and at the time of data reading, a low-level potential (sometimes referred to as a reference potential) is preferably applied to the wiring CAL.

Data writing is performed in the following manner: a high-level potential is applied to the wiring WOL to turn on the transistor M2 and establish electrical continuity between the wiring WBL and the first terminal of the capacitor CB. Specifically, when the transistor M2 is in an on state, a potential corresponding to information to be stored is applied to the wiring WBL, whereby the potential is written to the first terminal of the capacitor CB and the gate of the transistor M3. Then, a low-level potential is applied to the wiring WOL to turn off the transistor M2, whereby the potential of the first terminal of the capacitor CB and the potential of the gate of the transistor M3 are retained.

Data reading is performed by applying a predetermined potential to the wiring SL. A current flowing between a source and a drain of the transistor M3 and the potential of the first terminal of the transistor M3 are determined by the potential of the gate of the transistor M3 and the potential of the second terminal of the transistor M3. Accordingly, by reading the potential of the wiring RBL connected to the first terminal of the transistor M3, the potential retained in the first terminal of the capacitor CB (or the gate of the transistor M3) can be read. In other words, information written into this memory cell can be read out from the potential retained in the first terminal of the capacitor CB (or the gate of the transistor M3).

Alternatively, for example, the wiring WBL and the wiring RBL may be collectively connected to be one as the wiring BIL. A circuit structure example of the memory cell is illustrated in FIG. 15D. In a memory cell 954, one wiring BIL corresponds to the wiring WBL and the wiring RBL in the memory cell 953, and the second terminal of the transistor M2 and the first terminal of the transistor M3 are connected to the wiring BIL. In other words, the memory cell 954 has a structure in which one wiring BIL operates as a write bit line and a read bit line.

A memory cell 955 illustrated in FIG. 15E is an example in which the capacitor CB and the wiring CAL in the memory cell 953 are omitted. A memory cell 956 illustrated in FIG. 15F is an example in which the capacitor CB and the wiring CAL in the memory cell 954 are omitted. Such structures enable high integration of memory cells.

Note that an OS transistor is preferably used as at least the transistor M2. In particular, an OS transistor is preferably used as each of the transistor M2 and the transistor M3.

Since an OS transistor has a characteristic of an extremely low off-state current, written data can be retained for a long time with the transistor M2, and thus, the frequency of refresh operation for the memory cell can be reduced. Alternatively, refresh operation for the memory cell can be unnecessary. In addition, the extremely low leakage current allows multi-level data or analog data to be retained in the memory cell 953, the memory cell 954, the memory cell 955, and the memory cell 956.

The memory cell 953, the memory cell 954, the memory cell 955, and the memory cell 956 each including an OS transistor as the transistor M2 are embodiments of a NOSRAM.

Note that a Si transistor may be used as the transistor M3. A Si transistor can have high field-effect mobility and can be a p-channel transistor, so that circuit design flexibility can be increased.

In the case where an OS transistor is used as the transistor M3, the memory cell can be composed of a single-polarity circuit.

FIG. 15G illustrates a gain-cell memory cell 957 including three transistors and one capacitor. The memory cell 957 includes a transistor M4 to a transistor M6 and a capacitor CC.

A first terminal of the transistor M4 is connected to a first terminal of the capacitor CC. A second terminal of the transistor M4 is connected to the wiring BIL. A gate of the transistor M4 is connected to the wiring WOL. A second terminal of the capacitor CC is connected to a first terminal of the transistor M5 and a wiring GNDL. A second terminal of the transistor M5 is connected to a first terminal of the transistor M6. A gate of the transistor M5 is connected to the first terminal of the capacitor CC. A second terminal of the transistor M6 is electrically connected to the wiring BIL. A gate of the transistor M6 is connected to a wiring RWL.

The wiring BIL functions as a bit line. The wiring WOL functions as a write word line. The wiring RWL functions as a read word line. The wiring GNDL is a wiring for supplying a low-level potential.

Data writing is performed in the following manner: a high-level potential is applied to the wiring WOL to turn on the transistor M4 and establish electrical continuity between the wiring BIL and the first terminal of the capacitor CC. Specifically, when the transistor M4 is in an on state, a potential corresponding to information to be stored is applied to the wiring BIL, whereby the potential is written to the first terminal of the capacitor CC and the gate of the transistor M5. Then, a low-level potential is applied to the wiring WOL to turn off the transistor M4, whereby the potential of the first terminal of the capacitor CC and the potential of the gate of the transistor M5 are retained.

Data reading is performed in the following manner: after a predetermined potential is precharged to the wiring BIL, the wiring BIL is brought into an electrically floating state, and a high-level potential is applied to the wiring RWL. Since the wiring RWL has the high-level potential, the transistor M6 is turned on, so that electrical continuity is established between the wiring BIL and the second terminal of the transistor M5. At this time, the potential of the wiring BIL is applied to the second terminal of the transistor M5; the potential of the second terminal of the transistor M5 and the potential of the wiring BIL change depending on the potential retained in the first terminal of the capacitor CC (or the gate of the transistor M5). Here, the potential retained in the first terminal of the capacitor CC (or the gate of the transistor M5) can be read by reading the potential of the wiring BIL. In other words, information written into the memory cell can be read out from the potential retained in the first terminal of the capacitor CC (or the gate of the transistor M5).

Note that an OS transistor is preferably used as at least the transistor M4.

Note that Si transistors may be used as the transistors M5 and M6. As described above, a Si transistor may have higher field-effect mobility than the OS transistor depending on the crystal state of silicon used in a semiconductor layer, for example.

In the case where OS transistors are used as the transistors M5 and M6, the memory cell can be composed of a single-polarity circuit.

### [OS-SRAM]

FIG. 15H illustrates an example of an SRAM (Static Random Access Memory) including an OS transistor. In this specification and the like, an SRAM including an OS transistor is referred to as an OS-SRAM (Oxide Semiconductor-SRAM). A memory cell 958 illustrated in FIG. 15H is a memory cell of an SRAM capable of backup.

The memory cell 958 includes a transistor M7 to a transistor M10, a transistor MS1 to a transistor MS4, a capacitor CD1, and a capacitor CD2. The transistor MS1 and the transistor MS2 are p-channel transistors, and the transistor MS3 and the transistor MS4 are n-channel transistors.

A first terminal of the transistor M7 is connected to the wiring BIL. A second terminal of the transistor M7 is connected to a first terminal of the transistor MS1, a first terminal of the transistor MS3, a gate of the transistor MS2, a gate of the transistor MS4, and a first terminal of the transistor M10. A gate of the transistor M7 is connected to the wiring WOL. A first terminal of the transistor M8 is connected to a wiring BILB. A second terminal of the transistor M8 is connected to a first terminal of the transistor MS2, a first terminal of the transistor MS4, a gate of the transistor MS1, a gate of the transistor MS3, and a first terminal of the transistor M9. A gate of the transistor M8 is connected to the wiring WOL.

A second terminal of the transistor MS1 is connected to a wiring VDL. A second terminal of the transistor MS2 is connected to the wiring VDL. A second terminal of the transistor MS3 is connected to the wiring GNDL. A second terminal of the transistor MS4 is connected to the wiring GNDL.

A second terminal of the transistor M9 is connected to a first terminal of the capacitor CD1. A gate of the transistor M9 is connected to a wiring BRL. A second terminal of the transistor M10 is connected to a first terminal of the capacitor CD2. A gate of the transistor M10 is connected to the wiring BRL.

A second terminal of the capacitor CD1 is connected to the wiring GNDL. A second terminal of the capacitor CD2 is connected to the wiring GNDL.

The wiring BIL and the wiring BILB function as bit lines. The wiring WOL functions as a word line. The wiring BRL controls the on state and the off state of the transistor M9 and the transistor M10.

The wiring VDL supplies a high-level potential. The wiring GNDL supplies a low-level potential.

Data writing is performed by applying a high-level potential to the wiring WOL and applying a high-level potential to the wiring BRL. Specifically, when the transistor M10 is in an on state, a potential corresponding to information to be stored is applied to the wiring BIL, whereby the potential is written to the second terminal side of the transistor M10.

In the memory cell 958, an inverter loop is constructed by the transistor MS1 to the transistor MS2; thus, an inverted signal of a data signal corresponding to the potential is input to the second terminal side of the transistor M8. Since the transistor M8 is in an on state, an inverted signal of the potential applied to the wiring BIL, i.e., the signal input to the wiring BIL, is output to the wiring BILB. Since the transistor M9 and the transistor M10 are in an on state, the potential of the second terminal of the transistor M7 and the potential of the second terminal of the transistor M8 are respectively retained in the first terminal of the capacitor CD2 and the first terminal of the capacitor CD1. Then, a low-level potential is applied to the wiring WOL and a low-level potential is applied to the wiring BRL to turn off the transistor M7 to the transistor M10, so that the potentials of the first terminal of the capacitor CD1 and the first terminal of the capacitor CD2 are retained.

Data reading is performed in the following manner: after the wiring BIL and the wiring BILB are precharged at a predetermined potential in advance, a high-level potential is applied to the wiring WOL and a high-level potential is applied to the wiring BRL, whereby the potential of the first terminal of the capacitor CD1 is refreshed by the inverter loop in the memory cell 958 and is output to the wiring BILB. Furthermore, the potential of the first terminal of the capacitor CD2 is refreshed by the inverter loop in the memory cell 958 and output to the wiring BIL. Since the potentials of the wiring BIL and the wiring BILB are changed from the precharged potentials to the potential of the first terminal of the capacitor CD2 and the potential of the first terminal of the capacitor CD1, respectively, the potential retained in the memory cell can be read out from the potential of the wiring BIL or the wiring BILB.

Note that OS transistors are preferably used as the transistor M7 to the transistor M10. In that case, written data can be retained for a long time with the transistor M7 to the transistor M10, and thus, the frequency of refresh operation for the memory cell can be reduced. Alternatively, refresh operation for the memory cell can be unnecessary.

As the transistor MS1 to the transistor MS4, Si transistors may be used.

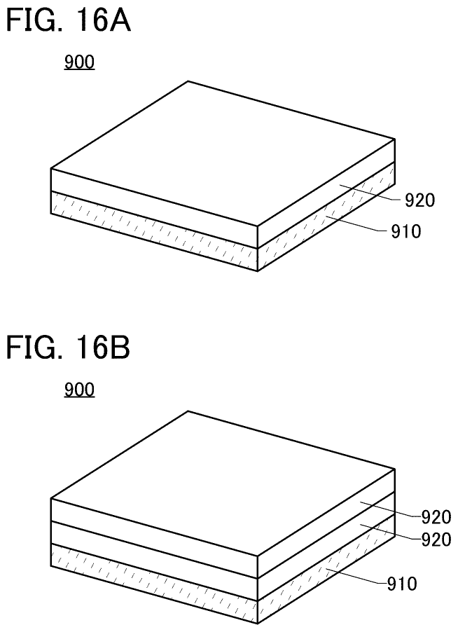

The driver circuit 910 and the memory array 920 included in the semiconductor device 900 may be provided on the same plane. Alternatively, as illustrated in FIG. 16A, the driver circuit 910 and the memory array 920 may be provided to overlap with each other. When the driver circuit 910 and the memory array 920 are provided to overlap with each other, the signal transmission distance can be shortened. As illustrated in FIG. 16B, a plurality of the memory arrays 920 may be stacked over the driver circuit 910.

Next, description is made on an example of an arithmetic processing device that can include a semiconductor device such as the memory device described above.

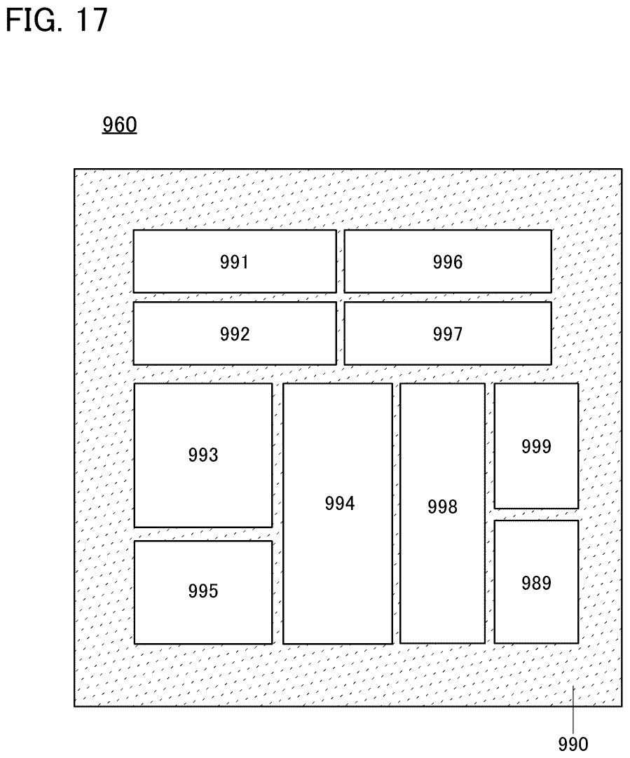

FIG. 17 is a block diagram of an arithmetic device 960. The arithmetic device 960 illustrated in FIG. 17 can be used for a CPU (Central Processing Unit), for example. The arithmetic device 960 can also be used for a processor including a larger number of (several tens to several hundreds of) processor cores capable of parallel processing than a CPU, such as a GPU (Graphics Processing Unit), a TPU (Tensor Processing Unit), or an NPU (Neural Processing Unit).

The arithmetic device 960 illustrated in FIG. 17 includes, over a substrate 990, an ALU 991 (Arithmetic logic unit, arithmetic circuit), an ALU controller 992, an instruction decoder 993, an interrupt controller 994, a timing controller 995, a register 996, a register controller 997, a bus interface 998, a cache 999, and a cache interface 989. A semiconductor substrate, an SOI substrate, a glass substrate, or the like is used as the substrate 990. The arithmetic device 960 may also include a rewritable ROM and a ROM interface. The cache 999 and the cache interface 989 may be provided in a separate chip.

The cache 999 is connected via the cache interface 989 to a main memory provided in another chip. The cache interface 989 has a function of supplying part of data retained in the main memory to the cache 999. The cache interface 989 also has a function of outputting part of data retained in the cache 999 to the ALU 991, the register 996, or the like through the bus interface 998.

As described later, the memory array 920 can be stacked over the arithmetic device 960. The memory array 920 can be used as a cache. Here, the cache interface 989 may have a function of supplying data retained in the memory array 920 to the cache 999. Moreover, in that case, the driver circuit 910 is preferably included in part of the cache interface 989.

Note that it is also possible that the cache 999 is not provided and only the memory array 920 is used as a cache.

The arithmetic device 960 illustrated in FIG. 17 is only an example with a simplified structure, and the actual arithmetic device 960 has a variety of structures depending on the application. For example, what is called a multicore structure is preferably employed in which a plurality of cores each including the arithmetic device 960 in FIG. 17 operate in parallel. A larger number of cores can further enhance the arithmetic performance. The number of cores is preferably larger; for example, the number is preferably 2, further preferably 4, still further preferably 8, yet still further preferably 12, yet still further preferably 16 or larger. For application requiring extremely high arithmetic performance, e.g., a server, it is preferable to employ the multicore structure including 16 or more, preferably 32 or more, further preferably 64 or more cores. The number of bits that the arithmetic device 960 can handle with an internal arithmetic circuit, a data bus, or the like can be 8, 16, 32, or 64, for example.

An instruction input to the arithmetic device 960 through the bus interface 998 is input to the instruction decoder 993 and decoded, and then input to the ALU controller 992, the interrupt controller 994, the register controller 997, and the timing controller 995.

The ALU controller 992, the interrupt controller 994, the register controller 997, and the timing controller 995 conduct various controls in accordance with the decoded instruction. Specifically, the ALU controller 992 generates signals for controlling the operation of the ALU 991. While the arithmetic device 960 is executing a program, the interrupt controller 994 judges an interrupt request from an external input/output device, a peripheral circuit, or the like on the basis of its priority, a mask state, or the like, and processes the request. The register controller 997 generates the address of the register 996, and reads and writes data from/to the register 996 in accordance with the state of the arithmetic device 960.

The timing controller 995 generates signals for controlling operation timings of the ALU 991, the ALU controller 992, the instruction decoder 993, the interrupt controller 994, and the register controller 997. For example, the timing controller 995 includes an internal clock generator portion for generating an internal clock signal on the basis of a reference clock signal, and supplies the internal clock signal to the above various circuits.

In the arithmetic device 960 illustrated in FIG. 17, the register controller 997 selects a retention operation in the register 996 in accordance with an instruction from the ALU 991. That is, the register controller 997 selects whether data is retained by a flip-flop or by a capacitor in a memory cell included in the register 996. When data retention by the flip-flop is selected, a power supply voltage is supplied to the memory cell in the register 996. When data retention by the capacitor is selected, the data is rewritten into the capacitor, and supply of the power supply voltage to the memory cell in the register 996 can be stopped.

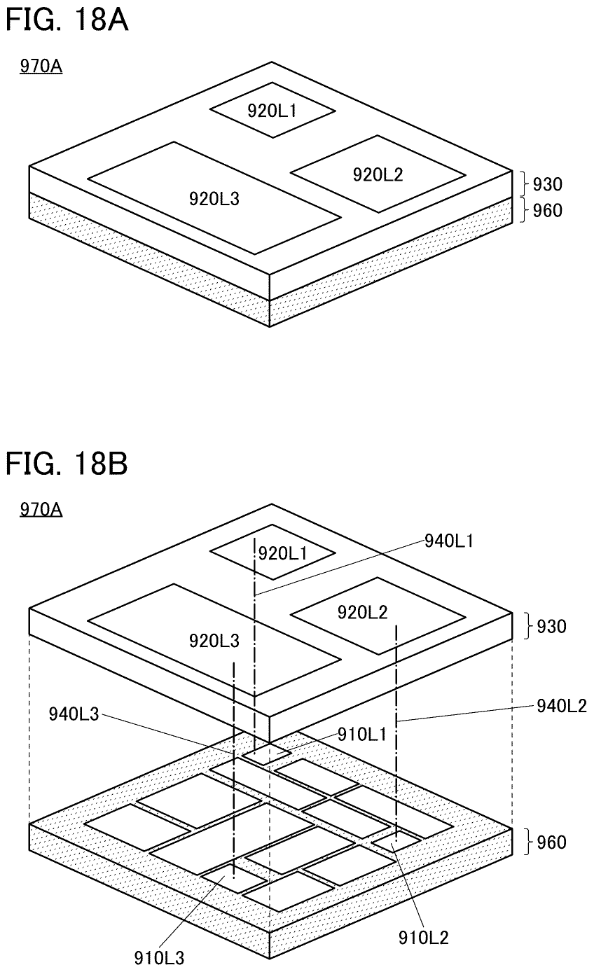

The memory array 920 and the arithmetic device 960 can be provided to overlap with each other. FIG. 18A and FIG. 18B are perspective views of a semiconductor device 970A. The semiconductor device 970A includes a layer 930 provided with memory arrays over the arithmetic device 960. A memory array 920L1, a memory array 920L2, and a memory array 920L3 are provided in the layer 930. The arithmetic device 960 includes regions overlapping with the memory arrays. For easy understanding of the structure of the semiconductor device 970A, the arithmetic device 960 and the layer 930 are separately illustrated in FIG. 18B.

When the arithmetic device 960 and the layer 930 including the memory arrays are provided to overlap with each other, the connection distance therebetween can be shortened. Accordingly, the communication speed therebetween can be increased. Moreover, since the connection distance is short, power consumption can be reduced.

As a method for stacking the layer 930 including the memory arrays and the arithmetic device 960, either of the following methods may be employed: a method in which the layer 930 including the memory arrays is stacked directly on the arithmetic device 960 (which is also referred to as monolithic stacking) and a method in which the arithmetic device 960 and the layer 930 are formed over different substrates, the two substrates are bonded to each other, and the arithmetic device 960 and the layer 930 are electrically connected to each other using a through via or a technique for bonding conductive films (e.g., Cu—Cu bonding). The former method does not require consideration of misalignment in bonding; thus, not only the chip size but also the manufacturing cost can be reduced.

Here, it is possible that the arithmetic device 960 does not include the cache 999 and the memory arrays 920L1, 920L2, and 920L3 provided in the layer 930 are each used as a cache. In that case, for example, the memory array 920L1 can be used as an L1 cache (also referred to as a level 1 cache), the memory array 920L2 can be used as an L2 cache (also referred to as a level 2 cache), and the memory array 920L3 can be used as an L3 cache (also referred to as a level 3 cache). Among the three memory arrays, the memory array 920L3 has the highest capacity and the lowest access frequency. The memory array 920L1 has the lowest capacity and the highest access frequency.

Note that in the case where the cache 999 provided in the arithmetic device 960 is used as the L1 cache, the memory arrays provided in the layer 930 can each be used as the lower-level cache or the main memory. The main memory has a higher capacity and lower access frequency than the cache.

As illustrated in FIG. 18B, a driver circuit 910L1, a driver circuit 910L2, and a driver circuit 910L3 are provided. The driver circuit 910L1 is connected to the memory array 920L1 through a connection electrode 940L1. Similarly, the driver circuit 910L2 is connected to the memory array 920L2 through a connection electrode 940L2, and the driver circuit 910L3 is connected to the memory array 920L3 through a connection electrode 940L3.

Note that although the case where three memory arrays function as caches is described here, the number of memory arrays may be one, two, or four or more.

In the case where the memory array 920L1 is used as a cache, the driver circuit 910L1 may function as part of the cache interface 989, or the driver circuit 910L1 may be connected to the cache interface 989. Similarly, each of the driver circuit 910L2 and the driver circuit 910L3 may function as part of the cache interface 989 or be connected thereto.

Whether the memory array 920 functions as the cache or the main memory is determined by the control circuit 912 included in each of the driver circuits 910. The control circuit 912 can make some of the plurality of memory cells 950 in the semiconductor device 900 function as a RAM in accordance with a signal supplied from the arithmetic device 960.

In the semiconductor device 900, some of the plurality of memory cells 950 can function as the cache and the other memory cells 950 can function as the main memory. That is, the semiconductor device 900 can have both the function of the cache and the function of the main memory. The semiconductor device 900 of one embodiment of the present invention can function as a universal memory, for example.

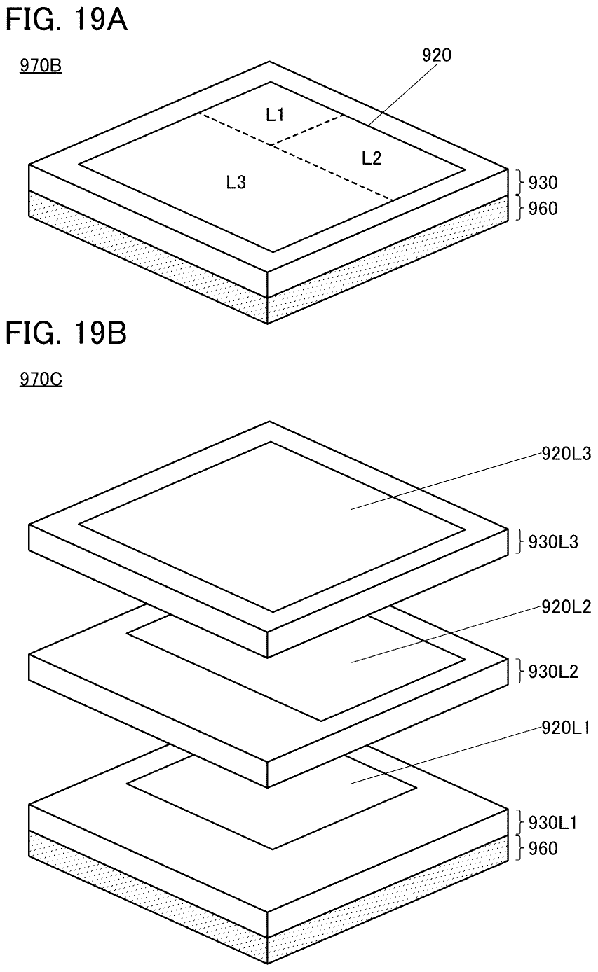

The layer 930 including one memory array 920 may be provided to overlap with the arithmetic device 960. FIG. 19A is a perspective view of a semiconductor device 970B.

In the semiconductor device 970B, one memory array 920 can be divided into a plurality of areas having different functions. FIG. 19A illustrates an example in which a region L1, a region L2, and a region L3 are used as the L1 cache, the L2 cache, and the L3 cache, respectively.

In the semiconductor device 970B, the capacity of each of the region L1 to the region L3 can be changed depending on circumstances. For example, the capacity of the L1 cache can be increased by increasing the area of the region L1. With such a structure, the arithmetic processing efficiency can be improved and the processing speed can be improved.

Alternatively, a plurality of memory arrays may be stacked. FIG. 19B is a perspective view of a semiconductor device 970C.

In the semiconductor device 970C, a layer 930L1 including the memory array 920L1, a layer 930L2 including the memory array 920L2 over the layer 930L1, and a layer 930L3 including the memory array 920L3 over the layer 930L2 are stacked. The memory array 920L1 physically closest to the arithmetic device 960 can be used as a high-level cache, and the memory array 920L3 physically farthest from the arithmetic device 960 can be used as a low-level cache or a main memory. Such a structure can increase the capacity of each memory array, leading to higher processing capability.

This embodiment can be combined with any of the other embodiments as appropriate.

### Embodiment 4

In this embodiment, application examples of the memory device of one embodiment of the present invention will be described.

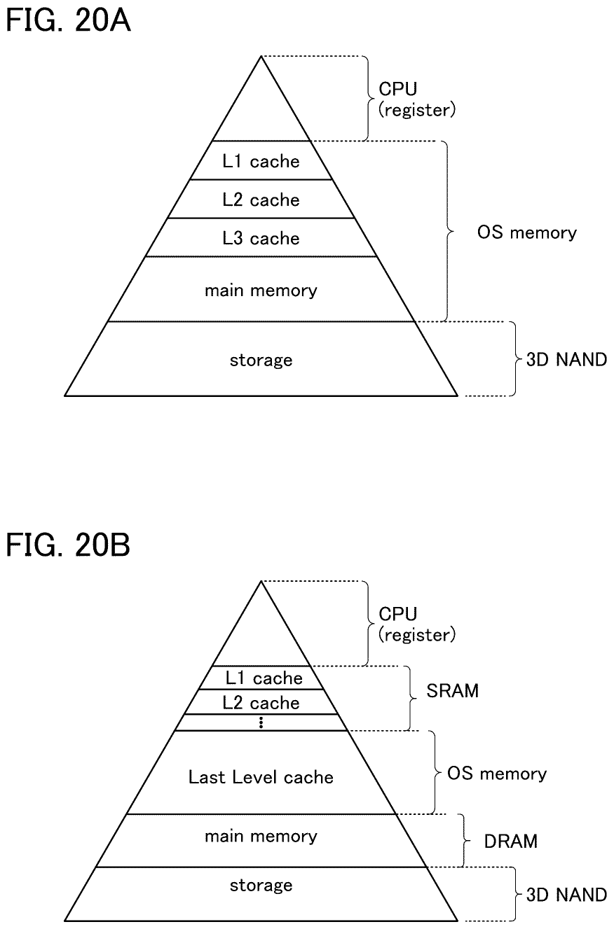

In general, a variety of memory devices are used in semiconductor devices such as computers in accordance with the intended use. FIG. 20A illustrates the hierarchy of various memory devices used in a semiconductor device. The memory devices at the upper levels require a higher operation speed, whereas the memory devices at the lower levels require a higher storage capacity and a higher memory density. In FIG. 20A, sequentially from the top level, a memory included as a register in an arithmetic processing device such as a CPU, the L1 cache, the L2 cache, the L3 cache, a main memory, a storage, and the like are shown. Although an example including the caches up to the L3 cache is described here, a lower-level cache may further be included.

A memory included as a register in an arithmetic processing device such as a CPU is used for temporary storage of arithmetic operation results, for example, and thus is very frequently accessed by the arithmetic processing device. Accordingly, a high operation speed is required rather than a storage capacity. In addition, the register also has a function of retaining settings information of the arithmetic processing device, for example.

The cache has a function of duplicating and retaining part of data retained in the main memory. Duplicating frequently used data and retaining the duplicated data in the cache can increase the speed of access to data. The cache requires a lower storage capacity than the main memory but a higher operation speed than the main memory. Data that is rewritten in the cache is duplicated, and the duplicated data is supplied to the main memory.

The main memory has a function of retaining a program, data, and the like that are read from the storage.

The storage has a function of retaining data that needs to be stored for a long time and various kinds of programs used in the arithmetic processing device, for example. Therefore, the storage needs to have a high storage capacity and a high memory density rather than operation speed. For example, a high-capacity nonvolatile memory device such as a 3D NAND can be used.

The memory device including an oxide semiconductor (the OS memory) of one embodiment of the present invention operates at high speed and can retain data for a long time. Thus, as illustrated in FIG. 20A, the memory device of one embodiment of the present invention can be suitably used at both the level where the cache is positioned and the level where the main memory is positioned. The memory device of one embodiment of the present invention can also be used at the level where the storage is positioned.

FIG. 20B illustrates an example in which an SRAM is used as some caches and the OS memory of one embodiment of the present invention is used as the other caches.

Among the caches, the lowest-level cache can be referred to as an LLC (Last Level cache). The LLC does not require a higher operation speed than a higher-level cache, but desirably has a high storage capacity. The OS memory of one embodiment of the present invention operates at high speed and can retain data for a long time, and thus can be suitably used as the LLC. Note that the OS memory of one embodiment of the present invention can also be used as an FLC (Final Level cache).

For example, as illustrated in FIG. 20B, an SRAM can be used as the higher-level caches (the L1 cache, the L2 cache, and the like), and the OS memory of one embodiment of the present invention can be used as the LLC. Moreover, instead of the OS memory, a DRAM can be used as the main memory as illustrated in FIG. 20B.

This embodiment can be combined with any of the other embodiments as appropriate.

### Embodiment 5

In this embodiment, a display device of one embodiment of the present invention will be described.

The semiconductor device of one embodiment of the present invention can be used for a display device or a module including the display device. Examples of the module including the display device include a module in which a connector such as a flexible printed circuit board (hereinafter referred to as an FPC) or a TCP (Tape Carrier Package) is attached to the display device and a module in which the display device is mounted with an integrated circuit (IC) by a COG (Chip On Glass) method, a COF (Chip On Film) method, or the like.

The display device in this embodiment may have a function of a touch panel. The display device can employ any of a variety of sensing elements (also referred to as sensor elements) that can sense proximity or touch of a sensing target such as a finger, for example.

Examples of a sensor type include a capacitive type, a resistive type, a surface acoustic wave type, an infrared type, an optical type, and a pressure-sensitive type.

Examples of the capacitive type include a surface capacitive type and a projected capacitive type. Examples of the projected capacitive type include a self-capacitive type and a mutual capacitive type. The mutual capacitive type is preferably used, in which case multiple points can be sensed simultaneously.

Examples of a touch panel include an out-cell touch panel, an on-cell touch panel, and an in-cell touch panel. An in-cell touch panel has a structure where an electrode included in a sensing element is provided on one or both of a substrate supporting a display element and a counter substrate.

### [Display Module]

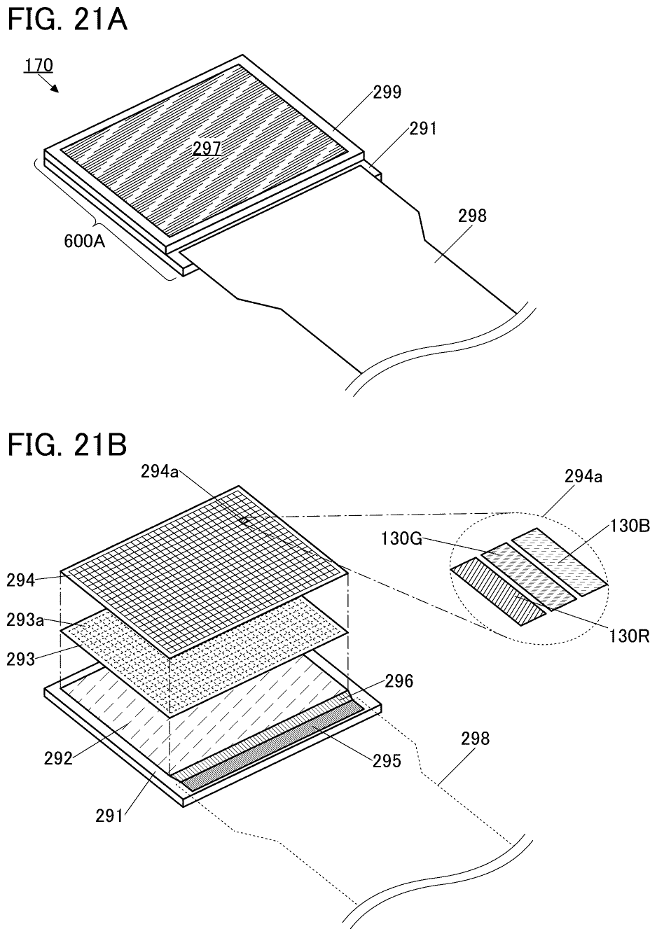

FIG. 21A is a perspective view of a display module 170. The display module 170 includes a display device 600A and an FPC 298. Note that the display device included in the display module 170 is not limited to the display device 600A and may be a display device 600B described later.

The display module 170 includes a substrate 291 and a substrate 299. The display module 170 includes a display portion 297. The display portion 297 is the region of the display module 170 where an image is displayed, and is the region where light emitted from pixels provided in a pixel portion 294 described later can be seen.

FIG. 21B is a perspective view schematically illustrating the structure on the substrate 291 side. Over the substrate 291, a circuit portion 292, a pixel circuit portion 293 over the circuit portion 292, and the pixel portion 294 over the pixel circuit portion 293 are stacked. In addition, a terminal portion 295 for connection to the FPC 298 is provided in a portion over the substrate 291 that does not overlap with the pixel portion 294. The terminal portion 295 and the circuit portion 292 are electrically connected to each other through a wiring portion 296 formed of a plurality of wirings.

The semiconductor device of one embodiment of the present invention can be used for one or both of the circuit portion 292 and the pixel circuit portion 293.

The pixel portion 294 includes a plurality of pixels 294a arranged periodically. An enlarged view of one pixel 294a is illustrated on the right side in FIG. 21B. FIG. 21B illustrates an example where one pixel 294a includes a subpixel 130R emitting red light, a subpixel 130G emitting green light, and a subpixel 130B emitting blue light.

The subpixel includes a display element. Any of a variety of elements can be used as the display element, and a liquid crystal element or a light-emitting element can be used, for example. Alternatively, a MEMS (Micro Electro Mechanical Systems) shutter element, an optical interference type MEMS element, or a display element using a microcapsule method, an electrophoretic method, an electrowetting method, an Electronic Liquid Powder (registered trademark) method, or the like can be used. Alternatively, a QLED (quantum-dot LED) employing a light source and color conversion technology using quantum dot materials may be used.

Examples of the light-emitting element include a self-luminous light-emitting element such as an LED (Light Emitting Diode), an OLED (Organic LED), and a semiconductor laser. As the LED, for example, a mini LED, a micro LED, or the like can be used.

There is no particular limitation on the arrangement of pixels in the display device of this embodiment, and any of a variety of arrangements can be employed. Examples of the arrangement of pixels include stripe arrangement, S-stripe arrangement, matrix arrangement, delta arrangement, Bayer arrangement, and PenTile arrangement. In the example illustrated in FIG. 21B, stripe arrangement is employed as the pixel arrangement.

The pixel circuit portion 293 includes a plurality of pixel circuits 293a arranged periodically.

One pixel circuit 293a is a circuit that controls driving of a plurality of elements included in one pixel 294a. One pixel circuit 293a can be provided with three circuits each of which controls light emission of one light-emitting element. For example, the pixel circuit 293a can include at least one selection transistor, one current control transistor (driving transistor), and a capacitor for one light-emitting element. In that case, a gate signal is input to a gate of the selection transistor, and a source signal is input to a source of the selection transistor. Thus, an active-matrix display device is achieved.

The circuit portion 292 includes a circuit for driving the pixel circuits 293a in the pixel circuit portion 293. For example, one or both of a gate line driver circuit and a source line driver circuit are preferably included. The circuit portion 292 may also include at least one of an arithmetic circuit, a memory circuit, a power supply circuit, and the like.

The FPC 298 functions as a wiring for supplying a video signal, a power supply potential, or the like to the circuit portion 292 from the outside. An IC may be mounted on the FPC 298.

The display module 170 can have a structure where one or both of the pixel circuit portion 293 and the circuit portion 292 are stacked below the pixel portion 294; thus, the aperture ratio (the effective display area ratio) of the display portion 297 can be significantly high. Furthermore, the pixels 294a can be arranged extremely densely, and thus, the display portion 297 can have a significantly high resolution.

Such a display module 170 has an extremely high resolution, and thus can be suitably used for a device for VR such as an HMD or a glasses-type device for AR. For example, even in the case of a structure where the display portion of the display module 170 is seen through a lens, pixels of the extremely-high-resolution display portion 297 included in the display module 170 are prevented from being seen when the display portion is enlarged by the lens, so that display providing a high sense of immersion can be performed. Without being limited thereto, the display module 170 can be suitably used for electronic appliances including a relatively small display portion. For example, the display module 170 can be favorably used in a display portion of a wearable electronic appliance, such as a wrist watch.

### Structure Example 1 of Display Device

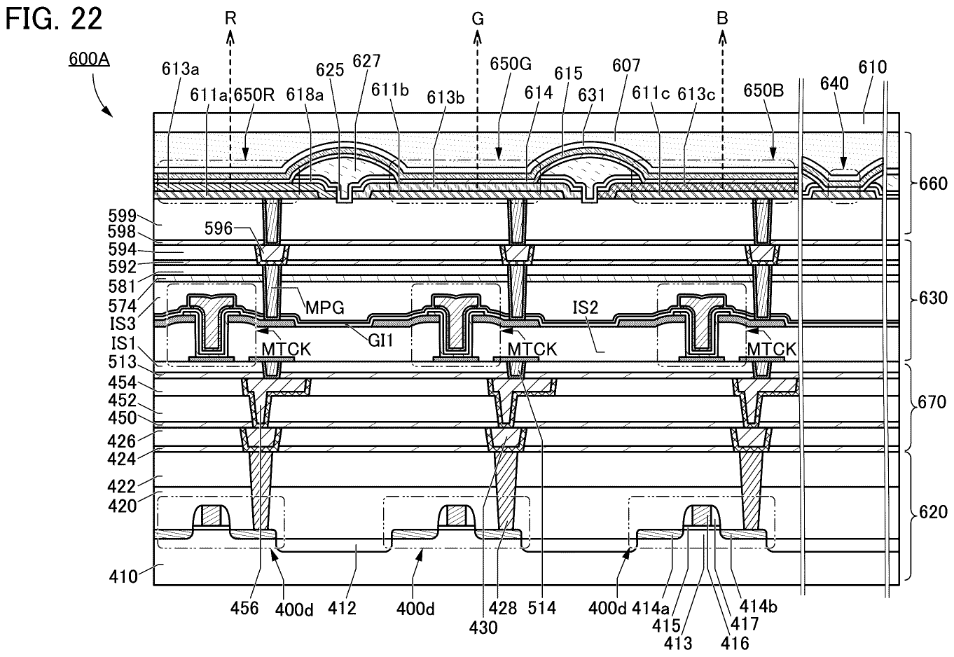

FIG. 22 is a cross-sectional view of the display device 600A. The display device 600A is an example of a display device having an MML (metal maskless) structure. In other words, the display device 600A includes a light-emitting element that is formed without using a fine metal mask.

An island-shaped light-emitting layer of the light-emitting element included in the display device having the MML structure is formed in the following manner: a light-emitting layer is formed on the entire surface, and then, the light-emitting layer is processed by a photolithography method. Accordingly, a high-resolution display device or a display device with a high aperture ratio, which has been difficult to achieve, can be obtained. Moreover, light-emitting layers can be formed separately for the respective colors, enabling the display device to perform extremely clear display with high contrast and high display quality. For example, in the case where the display device includes three kinds of light-emitting elements, which are a light-emitting element emitting blue light, a light-emitting element emitting green light, and a light-emitting element emitting red light, three kinds of island-shaped light-emitting layers can be formed by repeating formation of a light-emitting layer and processing by photolithography three times.

A device having the MML structure can be manufactured without using a metal mask, and thus can break through the resolution limit due to alignment accuracy of the metal mask. Furthermore, manufacturing a device without using a metal mask can eliminate the need for the manufacturing equipment of a metal mask and the cleaning step of the metal mask. Furthermore, for processing by photolithography, an apparatus that is the same as or similar to that used for manufacturing a transistor can be used; thus, there is no need to introduce a special apparatus to manufacture the device having the MML structure. The MML structure can reduce the manufacturing cost as described above, and thus is suitable for mass production of the device.

A display device having the MML structure does not require a pseudo improvement in resolution by employing a unique pixel arrangement such as a PenTile arrangement; thus, the display device can achieve a high resolution (e.g., higher than or equal to 500 ppi, higher than or equal to 1000 ppi, higher than or equal to 2000 ppi, higher than or equal to 3000 ppi, or higher than or equal to 5000 ppi) while having what is called a stripe arrangement where R, G, and B subpixels are arranged in one direction.

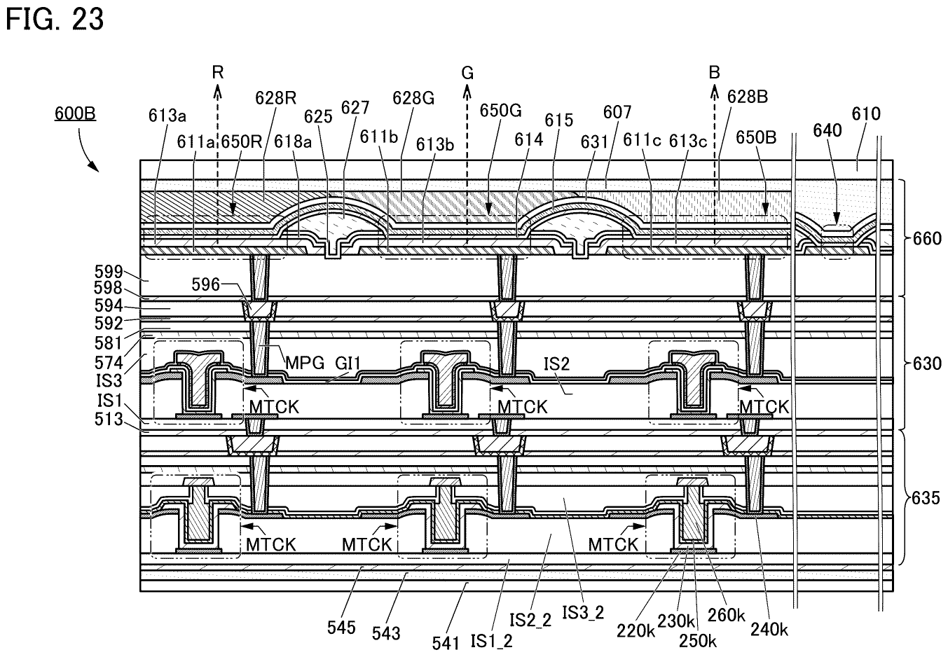

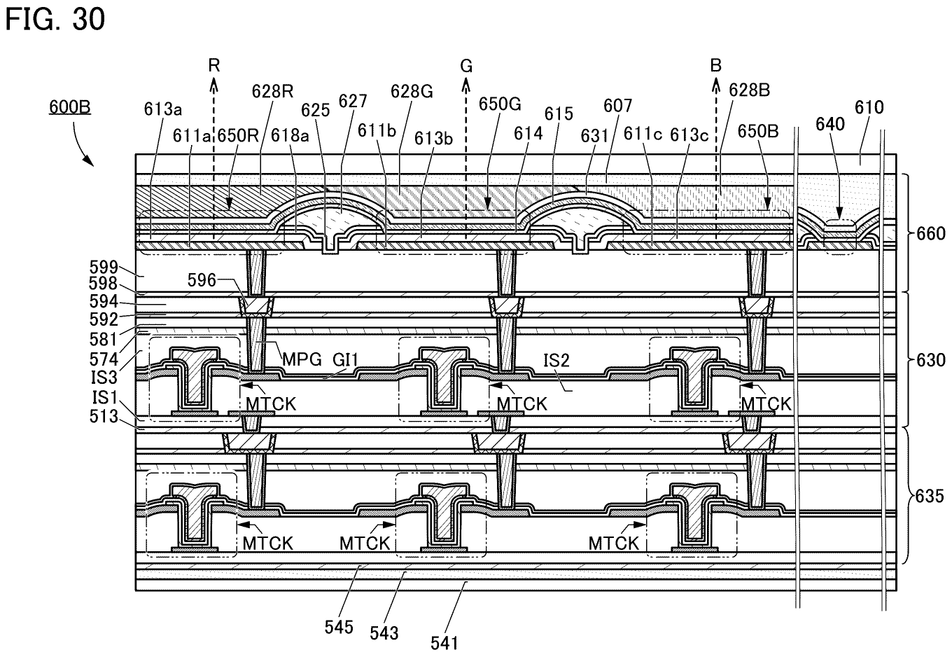

Moreover, providing a sacrificial layer over the light-emitting layer can reduce damage to the light-emitting layer in the manufacturing process of the display device, resulting in an increase in reliability of the light-emitting element. Note that the sacrificial layer may remain in the completed display device or may be removed in the manufacturing process. For example, a sacrificial layer 618a illustrated in FIG. 22, FIG. 23 described later, and FIG. 30 described later is part of the sacrificial layer provided over the light-emitting layer.

Employing a film formation step using an area mask and a processing step using a resist mask enables a light-emitting element to be manufactured by a relatively easy process.

FIG. 22 is a schematic cross-sectional view of the display device 600A that is a display device (a semiconductor device) of one embodiment of the present invention. The display device 600A is provided with a pixel circuit, a driver circuit, and the like over a substrate 410. Note that in the display device 600A in FIG. 22, a wiring layer 670 is illustrated in addition to an element layer 620, an element layer 630, and an element layer 660. The wiring layer 670 is a layer provided with a wiring.

A pixel circuit of the display device is preferably provided in the element layer 630. A driver circuit (one or both of a gate driver and a source driver) of the display device is preferably provided in the element layer 620. One or more of a variety of circuits such as an arithmetic circuit and a memory circuit may be provided in the element layer 620.

The element layer 620 includes the substrate 410, for example, and a transistor 400d is formed over the substrate 410. The wiring layer 670 is provided above the transistor 400d, and a wiring for electrically connecting the transistor 400d to a conductive layer, a transistor, or the like provided in the element layer 630 (a conductive layer 514 in FIG. 22) is provided in the wiring layer 670. The element layer 630 and the element layer 660 are provided above the wiring layer 670, and the element layer 630 includes a transistor MTCK and the like, for example. The element layer 660 includes light-emitting elements 650 (a light-emitting element 650R, a light-emitting element 650G, and a light-emitting element 650B in FIG. 22) and the like.

The transistor 400d is an example of a transistor included in the element layer 620. The transistor MTCK is an example of a transistor included in the element layer 630. The light-emitting elements (the light-emitting element 650R, the light-emitting element 650G, and the light-emitting element 650B) are examples of the light-emitting elements included in the element layer 660.

As the transistor MTCK, an OS transistor can be used, for example. FIG. 22 illustrates an example in which the transistor 200 described in the above embodiments is used as the transistor MTCK.

As the substrate 410, a semiconductor substrate (e.g., a single crystal substrate formed of silicon or germanium) can be used, for example. Besides the semiconductor substrate, for example, an SOI (Silicon On Insulator) substrate, a glass substrate, a quartz substrate, a plastic substrate, a sapphire glass substrate, a metal substrate, a stainless steel substrate, a substrate including stainless steel foil, a tungsten substrate, a substrate including tungsten foil, a flexible substrate, an attachment film, or paper or a base material film containing a fibrous material can be used as the substrate 410. In the description of this embodiment, the substrate 410 is a semiconductor substrate including silicon as a material. Therefore, a transistor included in the element layer 620 can be a Si transistor.

The transistor 400d includes an element isolation layer 412, a conductive layer 416, an insulating layer 415, an insulating layer 417, a semiconductor region 413 that is part of the substrate 410, and a low-resistance region 414a and a low-resistance region 414b functioning as a source region and a drain region. Thus, the transistor 400d is a Si transistor. Although one of a source and a drain of the transistor 400d is electrically connected to the conductive layer 514 provided in the element layer 630 through a conductive layer 428, a conductive layer 430, and a conductive layer 456 in the structure illustrated in FIG. 22, the electrical connection structure of the display device of one embodiment of the present invention is not limited thereto.

The transistor 400d can be a Fin type when, for example, the top surface of the semiconductor region 413 and the side surface thereof in the channel width direction are covered with the conductive layer 416 with the insulating layer 415 functioning as a gate insulating layer therebetween. The effective channel width can be increased in the Fin-type transistor 400d, so that the on-state characteristics of the transistor 400d can be improved. In addition, contribution of the electric field of a gate electrode can be increased, so that the off-state characteristics of the transistor 400d can be improved. The transistor 400d may have a planar structure instead of a Fin-type structure.

Note that the transistor 400d can be either a p-channel transistor or an n-channel transistor. Alternatively, a plurality of the transistors 400d may be provided and both the p-channel transistor and the n-channel transistor may be used.

The region of the semiconductor region 413 where a channel is formed, a region in the vicinity thereof, and the low-resistance region 414a and the low-resistance region 414b functioning as the source region and the drain region preferably include a silicon-based semiconductor, specifically, preferably include single crystal silicon. Alternatively, the above-described regions may be formed using germanium, silicon germanium, gallium arsenide, aluminum gallium arsenide, or gallium nitride, for example. A structure including silicon whose effective mass is controlled by applying stress to a crystal lattice and changing lattice spacing may be employed. Alternatively, the transistor 400d may be a HEMT (High Electron Mobility Transistor) including gallium arsenide and aluminum gallium arsenide, for example.

For the conductive layer 416 functioning as a gate electrode, a semiconductor material such as silicon that contains an element imparting n-type conductivity, e.g., arsenic or phosphorus, or an element imparting p-type conductivity, e.g., boron or aluminum, can be used. Alternatively, for the conductive layer 416, a conductive material such as a metal material, an alloy material, or a metal oxide material can be used.

Note that since a work function depends on the material for the conductive layer, the threshold voltage of the transistor can be adjusted by selecting the material for the conductive layer. Specifically, one or both of titanium nitride and tantalum nitride are preferably used for the conductive layer. Moreover, for both conductivity and embeddability, it is preferable to use stacked layers of metal materials of one or both of tungsten and aluminum as the conductive layer, and it is particularly preferable to use tungsten in terms of heat resistance.

The element isolation layer 412 is provided to separate a plurality of transistors formed on the substrate 410 from each other. The element isolation layer can be formed by, for example, a LOCOS (Local Oxidation of Silicon) method, an STI (Shallow Trench Isolation) method, or a mesa isolation method.

Over the transistor 400d illustrated in FIG. 22, an insulating layer 420 and an insulating layer 422 are stacked in this order from the substrate 410 side.

For the insulating layer 420 and the insulating layer 422, one or more selected from silicon oxide, silicon oxynitride, silicon nitride oxide, silicon nitride, aluminum oxide, aluminum oxynitride, aluminum nitride oxide, and aluminum nitride can be used, for example.

The insulating layer 422 may have a function of a planarization film for eliminating a level difference caused by the transistor 400d or the like covered with the insulating layer 420 and the insulating layer 422. For example, the top surface of the insulating layer 422 may be planarized by planarization treatment using a CMP method or the like to have improved planarity.

The conductive layer 428 connected to the transistor MTCK and the like provided above the insulating layer 422 is embedded in the insulating layer 420 and the insulating layer 422. Note that the conductive layer 428 has a function of a plug or a wiring.

In the display device 600A, the wiring layer 670 is provided over the transistor 400d. The wiring layer 670 includes, for example, an insulating layer 424, an insulating layer 426, the conductive layer 430, an insulating layer 450, an insulating layer 452, an insulating layer 454, and the conductive layer 456.

For example, over the insulating layer 422 and the conductive layer 428, the insulating layer 424 and the insulating layer 426 are stacked in this order. An opening is formed in the insulating layer 424 and the insulating layer 426 in a region overlapping with the conductive layer 428. In addition, the opening is filled with the conductive layer 430.

The insulating layer 450, the insulating layer 452, and the insulating layer 454 are sequentially stacked over the insulating layer 426 and the conductive layer 430. An opening is formed in the insulating layer 450, the insulating layer 452, and the insulating layer 454 in a region overlapping with the conductive layer 430. The opening is filled with the conductive layer 456.

The conductive layer 430 and the conductive layer 456 have a function of a plug or a wiring that is connected to the transistor 400d.

Note that for example, the insulating layer 424 and the insulating layer 450 are preferably formed using an insulating layer having a barrier property against one or more selected from hydrogen, oxygen, and water, like an insulating layer 592 described later. The insulating layer 426, the insulating layer 452, and the insulating layer 454 are preferably formed using an insulating layer having relatively low relative permittivity to reduce the parasitic capacitance generated between wirings, like an insulating layer 594 described later. The insulating layer 426, the insulating layer 452, and the insulating layer 454 each have functions of an interlayer insulating film and a planarization film.

The conductive layer 456 preferably includes a conductive layer having a barrier property against one or more selected from hydrogen, oxygen, and water.

For the insulating layer having a barrier property against hydrogen, tantalum nitride is preferably used, for example. By stacking tantalum nitride and tungsten, which has high conductivity, diffusion of hydrogen from the transistor 400d can be inhibited while the conductivity of a wiring is kept. In that case, the tantalum nitride layer having a barrier property against hydrogen is preferably in contact with the insulating layer 450 having a barrier property against hydrogen.

An insulating layer 513 is provided above the insulating layer 454 and the conductive layer 456. An insulating layer IS1 is provided over the insulating layer 513. A conductive layer functioning as a plug or a wiring is embedded in the insulating layer IS1 and the insulating layer 513. Thus, the transistor 400d can be electrically connected to the conductive layer 514 provided in the element layer 630. Alternatively, one of a source and a drain of the transistor MTCK and the one of the source and the drain of the transistor 400d may be electrically connected to each other.

The transistor MTCK and an insulating layer IS2 are provided over the insulating layer IS1. A semiconductor layer of the transistor MTCK, an insulating layer functioning as a gate insulating layer, a conductive layer functioning as a gate electrode, and the like are provided in an opening of the insulating layer IS2. An insulating layer IS3, an insulating layer 574, and an insulating layer 581 are stacked in this order over the transistor MTCK. A conductive layer MPG functioning as a plug or a wiring is embedded in the insulating layer IS3, the insulating layer 574, and the insulating layer 581.

The insulating layer 574 preferably has a function of inhibiting diffusion of impurities such as water and hydrogen (e.g., one or both of a hydrogen atom and a hydrogen molecule). In other words, the insulating layer 574 preferably functions as a barrier insulating film that inhibits entry of the impurities into the transistor MTCK. The insulating layer 574 also preferably has a function of inhibiting diffusion of oxygen (e.g., one or both of an oxygen atom and an oxygen molecule). For example, the insulating layer 574 preferably has lower oxygen permeability than the insulating layer IS2 and the insulating layer IS3.

Thus, the insulating layer 574 preferably functions as a barrier insulating film that inhibits diffusion of impurities such as water and hydrogen. Accordingly, the insulating layer 574 is preferably formed using an insulating material having a function of inhibiting diffusion of impurities such as a hydrogen atom, a hydrogen molecule, a water molecule, a nitrogen atom, a nitrogen molecule, a nitrogen oxide molecule (e.g., N₂O, NO, or NO₂), and a copper atom (an insulating material through which the above impurities are less likely to pass). Alternatively, it is preferable to use an insulating material having a function of inhibiting diffusion of oxygen (e.g., one or both of an oxygen atom and an oxygen molecule) (an insulating material through which the above oxygen is less likely to pass).

For the insulating layer having a function of inhibiting passage of oxygen and impurities such as water and hydrogen, it is possible to use any of the materials that can be used for the insulating layer having a function of inhibiting passage of oxygen and impurities and described in Embodiment 1.

In particular, aluminum oxide or silicon nitride is preferably used for the insulating layer 574. In that case, it is possible to inhibit diffusion of impurities such as water and hydrogen into the transistor MTCK from above the insulating layer 574. Alternatively, oxygen included in the insulating layer IS3 and the like can be inhibited from diffusing to above the insulating layer 574.

The insulating layer 581 is preferably a film functioning as an interlayer film and having lower permittivity than the insulating layer 574. When a material with low permittivity is used for an interlayer film, the parasitic capacitance generated between wirings can be reduced. For example, the relative permittivity of the insulating layer 581 is preferably lower than 4, further preferably lower than 3. For example, the relative permittivity of the insulating layer 581 is preferably less than or equal to 0.7 times that of the insulating layer 574, further preferably less than or equal to 0.6 times that of the insulating layer 574. When a material with low permittivity is used for the insulating layer 581 functioning as an interlayer film, parasitic capacitance generated between wirings can be reduced.

The concentration of impurities such as water and hydrogen in the insulating layer 581 is preferably reduced. In that case, the insulating layer 581 can be formed using silicon oxide, silicon oxynitride, silicon nitride oxide, or silicon nitride, for example. The insulating layer 581 can be formed using silicon oxide to which fluorine is added, silicon oxide to which carbon is added, silicon oxide to which carbon and nitrogen are added, or porous silicon oxide, for example. In particular, silicon oxide and silicon oxynitride are preferable because they are thermally stable. In particular, materials such as silicon oxide, silicon oxynitride, and porous silicon oxide are preferably used, in which case a region containing oxygen released by heating can be easily formed. Moreover, the insulating layer 581 can be formed using a resin. A material that can be used for the insulating layer 581 may be an appropriate combination of the above-described materials.

The insulating layer 592 and the insulating layer 594 are stacked in this order over the insulating layer 574 and the insulating layer 581.

For the insulating layer 592, it is preferable to use an insulating film with a barrier property (referred to as a barrier insulating film) that prevents diffusion of impurities such as water and hydrogen from the substrate 410 and the transistor MTCK into a region above the insulating layer 592 (e.g., the region where the light-emitting element 650R, the light-emitting element 650G, the light-emitting element 650B, and the like are provided). Accordingly, the insulating layer 592 is preferably formed using an insulating material having a function of inhibiting diffusion of impurities such as a hydrogen atom, a hydrogen molecule, and a water molecule (an insulating material through which the above impurities are less likely to pass). Furthermore, depending on circumstances, the insulating layer 592 is preferably formed using an insulating material having a function of inhibiting diffusion of impurities such as a nitrogen atom, a nitrogen molecule, a nitrogen oxide molecule (e.g., N₂O, NO, or NO₂), and a copper atom (an insulating material through which the above oxygen is less likely to pass). The insulating layer 592 preferably has a function of inhibiting diffusion of oxygen (e.g., one or both of an oxygen atom and an oxygen molecule).

For the film having a barrier property against hydrogen, for example, silicon nitride formed by a CVD method can be used.

The amount of released hydrogen can be analyzed by thermal desorption spectrometry (TDS), for example. For example, the amount of hydrogen released from the insulating layer 424 that is converted into hydrogen atoms per unit area of the insulating layer 424 is less than or equal to 10×10¹⁵ atoms/cm², preferably less than or equal to 5×10¹⁵ atoms/cm² in the TDS in the film-surface temperature range of 50° C. to 500° C.

Like the insulating layer 581, the insulating layer 594 is preferably an interlayer film with low permittivity. Thus, the insulating layer 594 can be formed using any of the materials that can be used for the insulating layer 581.

Note that the insulating layer 594 preferably has lower permittivity than the insulating layer 592. For example, the relative permittivity of the insulating layer 594 is preferably lower than 4, further preferably lower than 3. For example, the relative permittivity of the insulating layer 594 is preferably less than or equal to 0.7 times that of the insulating layer 592, further preferably less than or equal to 0.6 times that of the insulating layer 592. When a material with low permittivity is used for the insulating layer 594 functioning as an interlayer film, parasitic capacitance generated between wirings can be reduced.

The conductive layer MPG functioning as a plug or a wiring is embedded in an insulating layer GI1 and the insulating layer IS3, and a conductive layer 596 functioning as a plug or a wiring is embedded in the insulating layer 592 and the insulating layer 594. Specifically, the conductive layer MPG and the conductive layer 596 are electrically connected to the light-emitting element or the like provided above the insulating layer 594. A plurality of conductive layers having functions of plugs or wirings are collectively denoted by the same reference numeral in some cases. In this specification and the like, a wiring and a plug connected to the wiring may be a single component. That is, in some cases, part of a conductive layer functions as a wiring or part of a conductive layer functions as a plug.

As a material of each of plugs and wirings (the conductive layer MPG, the conductive layer 428, the conductive layer 430, the conductive layer 456, the conductive layer 514, and the conductive layer 596), a single layer or stacked layers of one or more conductive materials selected from a metal material, an alloy material, a metal nitride material, and a metal oxide material can be used. It is preferable to use a high-melting-point material that has both heat resistance and conductivity, such as tungsten or molybdenum, and it is preferable to use tungsten. Alternatively, a low-resistance conductive material such as aluminum or copper is preferably used for formation. The use of a low-resistance conductive material can reduce wiring resistance.

An insulating layer 598 and an insulating layer 599 are sequentially formed over the insulating layer 594 and the conductive layer 596.

For example, the insulating layer 598 is preferably formed using an insulating layer having a barrier property against one or more selected from hydrogen, oxygen, and water, like the insulating layer 592. The insulating layer 599 is preferably formed using an insulating layer having relatively low relative permittivity to reduce the parasitic capacitance generated between wirings, like the insulating layer 594. The insulating layer 599 has functions of an interlayer insulating film and a planarization film.

The light-emitting elements 650 and a connection portion 640 are formed over the insulating layer 599.

The connection portion 640 is referred to as a cathode contact portion in some cases, and is electrically connected to cathode electrodes of the light-emitting element 650R, the light-emitting element 650G, and the light-emitting element 650B. In the connection portion 640 illustrated in FIG. 22, a conductive layer formed using the same material in the same step as a conductive layer 611a to a conductive layer 611c is electrically connected to a common electrode 615 described later. Although the conductive layer is electrically connected to the common electrode 615 through a later-described common layer 614 in the example illustrated in FIG. 22, the conductive layer and the common electrode 615 may be in direct contact with each other.

Note that the connection portion 640 may be provided to surround four sides of the display portion in a plan view or may be provided in the display portion (e.g., between adjacent light-emitting elements 650) (not illustrated).

The light-emitting element 650R includes the conductive layer 611a as a pixel electrode. Similarly, the light-emitting element 650G includes the conductive layer 611b as a pixel electrode, and the light-emitting element 650B includes the conductive layer 611c as a pixel electrode.

The conductive layer 611a, the conductive layer 611b, and the conductive layer 611c are connected to the conductive layer 596 embedded in the insulating layer 594 through a conductive layer (plug) embedded in the insulating layer 599.

The light-emitting element 650R includes a layer 613a, the common layer 614 over the layer 613a, and the common electrode 615 over the common layer 614. The light-emitting element 650G includes a layer 613b, the common layer 614 over the layer 613b, and the common electrode 615 over the common layer 614. The light-emitting element 650B includes a layer 613c, the common layer 614 over the layer 613c, and the common electrode 615 over the common layer 614.

As a material that forms the pair of electrodes (the pixel electrode and the common electrode) of the light-emitting element, a metal, an alloy, an electrically conductive compound, a mixture thereof, and the like can be used as appropriate. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing any of these metals in appropriate combination. Other examples of the material include indium tin oxide (also referred to as In—Sn oxide or ITO), In—Si—Sn oxide (also referred to as ITSO), indium zinc oxide (In—Zn oxide), and In—W—Zn oxide. Other examples of the material include an alloy containing aluminum (aluminum alloy), such as an alloy of aluminum, nickel, and lanthanum (Al—Ni—La), and an alloy containing silver, such as an alloy of silver and magnesium and an alloy of silver, palladium, and copper (also referred to as Ag—Pd—Cu or APC). Other examples of the material include an element belonging to Group 1 or Group 2 of the periodic table that is not described above (e.g., lithium, cesium, calcium, or strontium), a rare earth metal such as europium or ytterbium, an alloy containing an appropriate combination of any of these elements, and graphene.

The display device 600A employs an SBS structure. The SBS structure can optimize materials and structures of light-emitting elements and thus can extend the freedom of choice of materials and structures, whereby the luminance and the reliability can be easily improved.

The display device 600A has a top-emission structure. The aperture ratio of pixels in a top-emission structure can be higher than that of pixels in a bottom-emission structure because a transistor and the like can be provided to overlap with a light-emitting region of a light-emitting element in the top-emission structure.

Note that the layer 613a is formed to cover the top surface and the side surface of the conductive layer 611a. Similarly, the layer 613b is formed to cover the top surface and the side surface of the conductive layer 611b. Similarly, the layer 613c is formed to cover the top surface and the side surface of the conductive layer 611c. Accordingly, regions provided with the conductive layer 611a, the conductive layer 611b, and the conductive layer 611c can be entirely used as the light-emitting regions of the light-emitting element 650R, the light-emitting element 650G, and the light-emitting element 650B, thereby increasing the aperture ratio of the pixels.

In the light-emitting element 650R, the layer 613a and the common layer 614 can be collectively referred to as an EL layer. Similarly, in the light-emitting element 650G, the layer 613b and the common layer 614 can be collectively referred to as an EL layer. Similarly, in the light-emitting element 650B, the layer 613c and the common layer 614 can be collectively referred to as an EL layer.

The EL layer includes at least a light-emitting layer. The light-emitting layer includes one or more kinds of light-emitting substances. As the light-emitting substance, a substance emitting light of an emission color of blue, violet, bluish violet, green, yellowish green, yellow, orange, red, or the like is appropriately used. Alternatively, as the light-emitting substance, a substance emitting near-infrared light can be used.

Examples of a light-emitting substance included in the light-emitting element include a substance that emits fluorescent light (a fluorescent material), a substance that emits phosphorescent light (a phosphorescent material), a substance that exhibits thermally activated delayed fluorescence (a TADF material), and an inorganic compound (e.g., a quantum dot material).

The light-emitting layer may include one or more kinds of organic compounds (e.g., a host material or an assist material) in addition to the light-emitting substance (a guest material). As one or more kinds of organic compounds, one or both of a substance with a high hole-transport property (a hole-transport material) and a substance with a high electron-transport property (an electron-transport material) can be used. As the one or more kinds of organic compounds, a substance with a bipolar property (a substance with a high electron-transport property and a high hole-transport property) or a TADF material may be used.

In addition to the light-emitting layer, the EL layer can include one or more of a layer including a substance having a high hole-injection property (a hole-injection layer), a layer including a hole-transport material (a hole-transport layer), a layer including a substance having a high electron-blocking property (an electron-blocking layer), a layer including a substance having a high electron-injection property (an electron-injection layer), a layer including an electron-transport material (an electron-transport layer), and a layer including a substance having a high hole-blocking property (a hole-blocking layer). The EL layer may further include one or both of a bipolar substance and a TADF material.

Either a low molecular compound or a high molecular compound can be used in the light-emitting element, and an inorganic compound may also be included. Each layer included in the light-emitting element can be formed by any of the following methods: an evaporation method (including a vacuum evaporation method), a transfer method, a printing method, an ink-jet method, a coating method, and the like.

The light-emitting element may employ a single structure (a structure including only one light-emitting unit) or a tandem structure (a structure including a plurality of light-emitting units). The light-emitting unit includes at least one light-emitting layer. In a tandem structure, a plurality of light-emitting units are connected in series with a charge-generation layer therebetween. The charge-generation layer has a function of injecting electrons into one of two light-emitting units and injecting holes to the other when a voltage is applied between the pair of electrodes. The tandem structure enables a light-emitting element capable of high-luminance light emission. Furthermore, the amount of current needed for obtaining a predetermined luminance can be smaller in the tandem structure than in the single structure; thus, the tandem structure enables higher reliability. The tandem structure may be referred to as a stack structure.

When the light-emitting element has a microcavity structure, higher color purity can be achieved.

The layer 613a, the layer 613b, and the layer 613c are each processed into an island shape by a photolithography method. At each of the end portions of the layer 613a, the layer 613b, and the layer 613c, the angle between the top surface and the side surface is approximately 90°. By contrast, for example, an organic film formed using an FMM (Fine Metal Mask) tends to have a thickness that gradually decreases with decreasing distance to an end portion, and has a sloped top surface in an area ranging from 1 μm to 10 μm, both inclusive, toward the end portion, for example; thus, such an organic film has a shape whose top surface and side surface cannot be easily distinguished from each other.

The top surface and the side surface of each of the layer 613a, the layer 613b, and the layer 613c are clearly distinguished from each other. Accordingly, as for the layer 613a and the layer 613b that are adjacent to each other, one of the side surfaces of the layer 613a and one of the side surfaces of the layer 613b are placed to face each other. This applies to a combination of any two of the layer 613a, the layer 613b, and the layer 613c.

The layer 613a, the layer 613b, and the layer 613c each include at least a light-emitting layer. It is preferable that the layer 613a include a red-light-emitting layer, the layer 613b include a green-light-emitting layer, and the layer 613c include a blue-light-emitting layer, for example. Other than the above colors, cyan, magenta, yellow, or white can be employed for the light-emitting layers.

The layer 613a, the layer 613b, and the layer 613c each preferably include a light-emitting layer and a carrier-transport layer (an electron-transport layer or a hole-transport layer) over the light-emitting layer. Since the surfaces of the layer 613a, the layer 613b, and the layer 613c are exposed in the manufacturing process of the display device in some cases, providing the carrier-transport layer over the light-emitting layer inhibits the light-emitting layer from being exposed on the outermost surface, so that damage to the light-emitting layers can be reduced. Thus, the reliability of the light-emitting elements can be increased.

The common layer 614 includes, for example, an electron-injection layer or a hole-injection layer. Alternatively, the common layer 614 may include a stack of an electron-transport layer and an electron-injection layer, or may include a stack of a hole-transport layer and a hole-injection layer. The common layer 614 is shared by the light-emitting element 650R, the light-emitting element 650G, and the light-emitting element 650B. Note that the common layer 614 is not necessarily provided, and the whole EL layer included in the light-emitting element may be provided in an island shape like the layer 613a, the layer 613b, and the layer 613c.

The common electrode 615 is shared by the light-emitting element 650R, the light-emitting element 650G, and the light-emitting element 650B. As illustrated in FIG. 22, the common electrode 615 shared by a plurality of the light-emitting elements is electrically connected to the conductive layer included in the connection portion 640.

An insulating layer 625 preferably has a function of a barrier insulating layer against one or both of water and oxygen. Alternatively, the insulating layer 625 preferably has a function of inhibiting diffusion of one or both of water and oxygen. Alternatively, the insulating layer 625 preferably has a function of capturing or fixing (also referred to as gettering) one or both of water and oxygen. When the insulating layer 625 has a function of a barrier insulating layer or a gettering function, entry of impurities (typically, one or both of water and oxygen) that would diffuse into the light-emitting elements from the outside can be inhibited. With this structure, highly reliable light-emitting elements and a highly reliable display device can be provided.

The insulating layer 625 preferably has a low impurity concentration. In that case, degradation of the EL layer due to entry of impurities from the insulating layer 625 into the EL layer can be inhibited. In addition, when having a lower impurity concentration, the insulating layer 625 can have a higher barrier property against one or both of water and oxygen. For example, the insulating layer 625 preferably has a sufficiently low hydrogen concentration or a sufficiently low carbon concentration, and further preferably has both a sufficiently low hydrogen concentration and a sufficiently low carbon concentration.

As an insulating layer 627, an insulating layer including an organic material can be favorably used. As the organic material, a photosensitive organic resin is preferably used, and for example, a photosensitive resin composite containing an acrylic resin is used. Note that in this specification and the like, an acrylic resin refers to not only a polymethacrylic acid ester or a methacrylic resin, but also all the acrylic polymers in a broad sense in some cases.

An organic material that can be used for the insulating layer 627 is not limited to the above. For example, for the insulating layer 627, an acrylic resin, a polyimide resin, an epoxy resin, a polyamide resin, a polyimide-amide resin, a silicone resin, a siloxane resin, a benzocyclobutene-based resin, a phenol resin, or precursors of these resins can be used in some cases. An organic material such as polyvinyl alcohol (PVA), polyvinyl butyral (PVB), polyvinylpyrrolidone, polyethylene glycol, polyglycerin, pullulan, water-soluble cellulose, or an alcohol-soluble polyamide resin can be used for the insulating layer 627 in some cases. A photoresist, which is a photosensitive resin, can be used for the insulating layer 627 in some cases. Examples of the photosensitive resin include positive-type materials and negative-type materials.

The insulating layer 627 may be formed using a material absorbing visible light. When the insulating layer 627 absorbs light emitted from the light-emitting element, light leakage (stray light) from the light-emitting element to an adjacent light-emitting element through the insulating layer 627 can be suppressed. Thus, the display quality of the display device can be improved. Since no polarizing plate is required to improve the display quality of the display device, the weight and thickness of the display device can be reduced.

Examples of the material absorbing visible light include materials containing pigment of black or the like, materials containing dye, light-absorbing resin materials (e.g., polyimide), and resin materials that can be used for color filters (color filter materials). A resin material obtained by stacking or mixing color filter materials of two or three or more colors is particularly preferably used to enhance the effect of blocking visible light. In particular, mixing color filter materials of three or more colors enables a black or nearly black resin layer.

For example, the insulating layer 627 can be formed by a wet film-formation method such as spin coating, dipping, spray coating, ink-jetting, dispensing, screen printing, offset printing, doctor blade coating, slit coating, roll coating, curtain coating, or knife coating. Specifically, an organic insulating film that is to be the insulating layer 627 is preferably formed by spin coating.

The insulating layer 627 is formed at a temperature lower than the upper temperature limit of the EL layer. A typical substrate temperature in formation of the insulating layer 627 is lower than or equal to 200° C., preferably lower than or equal to 180° C., further preferably lower than or equal to 160° C., still further preferably lower than or equal to 150° C., yet still further preferably lower than or equal to 140° C.

Note that the side surface of the insulating layer 627 preferably has a tapered shape. When the end portion of the side surface of the insulating layer 627 has a forward tapered shape (with an angle less than 90°, preferably less than or equal to 60°, further preferably less than or equal to) 45°, the common layer 614 and the common electrode 615 that are provided over the end portion of the side surface of the insulating layer 627 can be formed with good coverage without disconnection, local thinning, or the like. Consequently, the in-plane uniformity of the common layer 614 and the common electrode 615 can be increased, so that the display quality of the display device can be improved.

In the cross-sectional view of the display device, the top surface of the insulating layer 627 preferably has a convex shape. The top surface of the insulating layer 627 preferably has a convex shape that bulges gradually toward the center. When the insulating layer 627 has such a shape, the common layer 614 and the common electrode 615 can be formed with good coverage over the whole insulating layer 627.

The insulating layer 627 is formed in a region between two EL layers (e.g., a region between the layer 613a and the layer 613b). Here, part of the insulating layer 627 is placed at a position sandwiched between the end portion of the side surface of one of the EL layers (e.g., the layer 613a) and the end portion of the side surface of the other of the EL layers (e.g., the layer 613b).

One end portion of the insulating layer 627 preferably overlaps with the conductive layer 611a functioning as the pixel electrode, and the other end portion of the insulating layer 627 preferably overlaps with the conductive layer 611b functioning as the pixel electrode. Such a structure enables the end portion of the insulating layer 627 to be formed over a flat or substantially flat region of the layer 613a (the layer 613b). This makes it relatively easy to process the tapered shape of the insulating layer 627 as described above.

By providing the insulating layer 627 and the like in the above manner, a disconnected portion and a locally thinned portion can be prevented from being formed in the common layer 614 and the common electrode 615 from a flat or substantially flat region of the layer 613a to a flat or substantially flat region of the layer 613b. Thus, a connection defect due to a disconnected portion and an increase in electrical resistance due to a locally thinned portion can be inhibited from occurring in the common layer 614 and the common electrode 615 between the light-emitting elements.

In the display device of this embodiment, the distance between the light-emitting elements can be short. Specifically, the distance between the light-emitting elements, the distance between the EL layers, or the distance between the pixel electrodes can be less than 10 μm, less than or equal to 8 μm, less than or equal to 5 μm, less than or equal to 3 μm, less than or equal to 2 μm, less than or equal to 1 μm, less than or equal to 500 nm, less than or equal to 200 nm, less than or equal to 100 nm, less than or equal to 90 nm, less than or equal to 70 nm, less than or equal to 50 nm, less than or equal to 30 nm, less than or equal to 20 nm, less than or equal to 15 nm, or less than or equal to 10 nm. In other words, the display device of this embodiment includes a region where the distance between two adjacent island-shaped EL layers is less than or equal to 1 μm, preferably less than or equal to 0.5 μm (500 nm), further preferably less than or equal to 100 nm. Shortening the distance between the light-emitting elements in this manner enables a display device with a high definition and a high aperture ratio to be provided.

A protective layer 631 is provided over the light-emitting elements 650. The protective layer 631 functions as a passivation film for protecting the light-emitting elements 650. Providing the protective layer 631 that covers the light-emitting elements can inhibit entry of impurities such as water and oxygen into the light-emitting elements and increase the reliability of the light-emitting elements 650. The protective layer 631 preferably has a single-layer structure or a stacked-layer structure including at least an inorganic insulating film. Examples of the inorganic insulating film include an oxide film or a nitride film such as a silicon oxide film, a silicon oxynitride film, a silicon nitride oxide film, a silicon nitride film, an aluminum oxide film, an aluminum oxynitride film, or a hafnium oxide film. Alternatively, a semiconductor material such as indium gallium oxide or indium gallium zinc oxide (IGZO) may be used for the protective layer 631. The protective layer 631 can be formed by an ALD method, a CVD method, a sputtering method, or the like. Although the protective layer 631 includes an inorganic insulating film in this example, one embodiment of the present invention is not limited thereto. For example, the protective layer 631 may have a stacked-layer structure of an inorganic insulating film and an organic insulating film.

The protective layer 631 and a substrate 610 are bonded to each other with an adhesive layer 607. A solid sealing structure, a hollow sealing structure, or the like can be employed to seal the light-emitting elements. In FIG. 22, a solid sealing structure is employed, in which a space between the substrate 410 and the substrate 610 is filled with the adhesive layer 607. Alternatively, a hollow sealing structure may be employed, in which the space is filled with an inert gas (e.g., nitrogen or argon). In that case, the adhesive layer 607 may be provided not to overlap with the light-emitting elements. Furthermore, the space may be filled with a resin other than the frame-like adhesive layer 607.

For the adhesive layer 607, any of a variety of curable adhesives such as a reactive curable adhesive, a thermosetting adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene-vinyl acetate) resin. In particular, a material with low moisture permeability, such as an epoxy resin, is preferable. A two-component-mixture-type resin may be used. An adhesive sheet may be used.

The display device 600A has a top-emission structure. Light from the light-emitting element is emitted to the substrate 610 side. For this reason, a material having a high visible-light-transmitting property is preferably used for the substrate 610. For example, as the substrate 610, a substrate having a high visible-light-transmitting property may be selected from substrates usable as the substrate 410. The pixel electrode includes a material reflecting visible light, and the counter electrode (the common electrode 615) includes a material transmitting visible light.

Note that the display device of one embodiment of the present invention may be not a top-emission display device but a bottom-emission display device where light from the light-emitting element is emitted to the substrate 410 side. In that case, a substrate having a high visible-light-transmitting property is selected as the substrate 410.

### Structure Example 2 of Display Device

FIG. 30 is a cross-sectional view of the display device 600B. The element layer 660 of the display device 600B is different from the element layer 660 of the display device 600A in that the layer 613a, the layer 613b, and the layer 613c have the same structure and that a coloring layer 628R, a coloring layer 628G, and a coloring layer 628B are provided. Furthermore, the display device 600B is different from the display device 600A in not including the element layer 620 and in including an element layer 635. The element layer 635 illustrated in FIG. 30 has a structure similar to that of the element layer 630.

As a modification example of FIG. 30, FIG. 23 illustrates an example in which the transistor MTCK included in the element layer 635 is an OS transistor and has a structure different from that of the transistor MTCK included in the element layer 630 in FIG. 22 and the element layer 635 in FIG. 30.

The element layer 635 illustrated in FIG. 23 includes an insulating layer IS1_2, the transistor MTCK and an insulating layer IS2_2 over the insulating layer IS1_2, and an insulating layer IS3_2 over the transistor MTCK. An oxide semiconductor layer 230k of the transistor MTCK, an insulating layer 250k functioning as the gate insulating layer, and a conductive layer 260k functioning as the gate electrode are provided in an opening of the insulating layer IS2_2. A conductive layer 220k functioning as one of a source electrode and a drain electrode of the transistor MTCK is positioned over the insulating layer IS1_2, and a conductive layer 240k functioning as the other is positioned over the insulating layer IS2_2.

In the element layer 635 illustrated in FIG. 23, the conductive layer 260k of the transistor MTCK includes a region positioned in a first opening provided in the insulating layer IS2_2 and a region positioned in a second opening provided in the insulating layer IS3_2, and the second opening includes a region overlapping with the first opening.

The display device 600B can be a display device having flexibility (also referred to as a flexible display) when a flexible substrate is used as each of a substrate 541 and the substrate 610. The substrate 541 is bonded to an insulating layer 545 with an adhesive layer 543. The substrate 610 is bonded to the protective layer 631 with the adhesive layer 607.

In the element layer 660 of the display device 600B, the layer 613a, the layer 613b, and the layer 613c have the same structure and the coloring layer 628R, the coloring layer 628G, and the coloring layer 628B are included.

The layer 613a, the layer 613b, and the layer 613c are formed using the same material in the same step. The layer 613a, the layer 613b, and the layer 613c are apart from each other. When the EL layer is provided in an island shape for each light-emitting element, a leakage current between adjacent light-emitting elements (sometimes referred to as horizontal-direction leakage current, horizontal leakage current, or lateral leakage current) can be inhibited. Accordingly, unintentional light emission due to crosstalk can be prevented, and color mixture between adjacent light-emitting elements can be inhibited, so that the display device can achieve extremely high contrast.

The light-emitting elements 650R, 650G, and 650B illustrated in FIG. 23 and FIG. 30 emit white light, for example. White light emitted from the light-emitting elements 650R, 650G, and 650B passes through the coloring layer 628R, the coloring layer 628G, and the coloring layer 628B, whereby light of a desired color can be obtained.

In the case where the light-emitting element configured to emit white light has a microcavity structure, light with a specific wavelength such as red, green, or blue is sometimes intensified and emitted.

Light emitted from the light-emitting element 650R is extracted as red light to the outside of the display device 600B through the coloring layer 628R. Similarly, light emitted from the light-emitting element 650G is extracted as green light to the outside of the display device 600B through the coloring layer 628G. Light emitted from the light-emitting element 650B is extracted as blue light to the outside of the display device 600B through the coloring layer 628B.

A light-emitting element emitting white light preferably has a tandem structure.

Alternatively, the light-emitting elements 650R, 650G, and 650B illustrated in FIG. 23 and FIG. 30 emit blue light, for example. In this case, the layer 613a, the layer 613b, and the layer 613c each include one or more light-emitting layers emitting blue light. In the subpixel that emits blue light, blue light emitted from the light-emitting element 650B can be extracted. In each of the subpixel emitting red light and the subpixel emitting green light, a color conversion layer is provided between the light-emitting element 650R and the coloring layer 628R and between the light-emitting element 650G and the coloring layer 628G, so that blue light emitted from the light-emitting element 650R or the light-emitting element 650G is converted into light with a longer wavelength, whereby red light or green light can be extracted. When light passing through the color conversion layer is extracted through the coloring layer, light other than light of a desired color can be absorbed by the coloring layer, and color purity of light emitted from a subpixel can be improved.

The coloring layer is a colored layer that selectively transmits light in a specific wavelength range and absorbs light in the other wavelength ranges. For example, a red (R) color filter for transmitting light in the red wavelength range, a green (G) color filter for transmitting light in the green wavelength range, a blue (B) color filter for transmitting light in the blue wavelength range, or the like can be used. Each coloring layer can be formed using one or more of a metal material, a resin material, a pigment, and a dye. Each coloring layer is formed in a desired position by a printing method, an ink-jet method, an etching method using a photolithography method, or the like.

The element layer 630 of the display device 600B has a structure similar to that of the element layer 630 of the display device 600A; thus, the detailed description thereof is omitted.

The display device 600B includes the element layer 635 and the element layer 630 over the element layer 635. The element layer 635 has a structure similar to that of the element layer 630.

At least part of the transistor included in the element layer 635 is electrically connected to a conductive layer or a transistor included in the element layer 630 through a plug, a wiring, and the like. Note that the wiring layer 670 may be provided between the element layer 630 and the element layer 635.

One or both of a pixel circuit and a driver circuit of the display device are preferably provided in the element layer 635.

Although two element layers (the element layer 630 and the element layer 635) including OS transistors are stacked in each of the examples illustrated in FIG. 23 and FIG. 30, the number of stacked element layers is not limited thereto, and may be three or more. For example, in the case where three or more element layers including OS transistors are stacked, it is preferable that the lowermost layer be used for the driver circuit (one or both of the gate driver and the source driver) of the display device, the uppermost layer be used for the pixel circuit of the display device, and the layer(s) between them be used for the pixel circuit or the driver circuit.

A Si transistor is typically formed over a single crystal Si wafer, making it difficult to obtain a flexible structure. Meanwhile, in the case where the display device is formed using only OS transistors without using a Si transistor as illustrated in FIG. 23 and FIG. 30, a flexible structure can be obtained through a relatively simple manufacturing process.

### Structure Example of Light-Emitting Element

Next, light-emitting elements that can be used for the display device of one embodiment of the present invention are described. Structure examples of a light-emitting element different from the structures illustrated in FIG. 22, FIG. 23, and FIG. 30 are mainly described below.

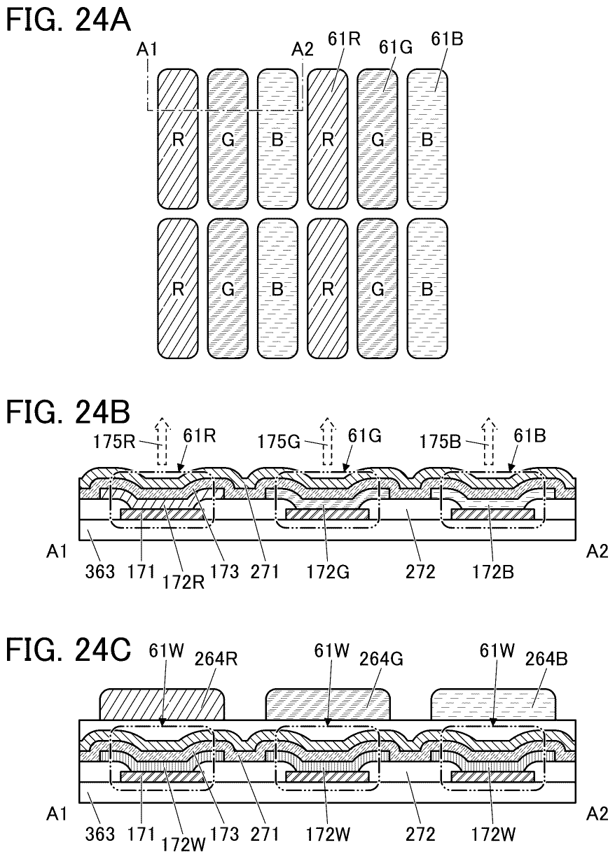

FIG. 24A is a schematic top view of part of a display portion including a plurality of light-emitting elements. The display portion includes a plurality of light-emitting elements 61R emitting red light, a plurality of light-emitting elements 61G emitting green light, and a plurality of light-emitting elements 61B emitting blue light. In FIG. 24A, light-emitting regions of the light-emitting elements are denoted by R, G, and B to easily differentiate the light-emitting elements. Although the structure illustrated in FIG. 24A has three emission colors of red (R), green (G), and blue (B), one embodiment of the present invention is not limited thereto. For example, the structure may have four or more colors.

FIG. 24B is a cross-sectional view taken along a dashed-dotted line A1-A2 in FIG. 24A. The light-emitting element 61R, the light-emitting element 61G, and the light-emitting element 61B illustrated in FIG. 24B are provided over an insulating layer 363, and include a conductive layer 171 functioning as a pixel electrode and a conductive layer 173 functioning as a common electrode. For the insulating layer 363, one or both of an inorganic insulating film and an organic insulating film can be used.

The light-emitting element 61R includes an EL layer 172R between the conductive layer 171 functioning as the pixel electrode and the conductive layer 173 functioning as the common electrode. The EL layer 172R includes at least a light-emitting compound that emits light having a peak in the red wavelength range. An EL layer 172G included in the light-emitting element 61G includes at least a light-emitting compound that emits light having a peak in the green wavelength range. An EL layer 172B included in the light-emitting element 61B includes at least a light-emitting compound that emits light having a peak in the blue wavelength range.

The conductive layer 171 functioning as the pixel electrode is provided for each light-emitting element. The conductive layer 173 functioning as the common electrode is provided as a continuous layer shared by the light-emitting elements. A conductive film having a visible-light-transmitting property is used for either the conductive layer 171 functioning as the pixel electrode or the conductive layer 173 functioning as the common electrode, and a reflective conductive film is used for the other.

For example, in the case where the light-emitting element 61R has a top-emission structure, light 175R is emitted from the light-emitting element 61R to the conductive layer 173 side. In the case where the light-emitting element 61R has a top-emission structure, light 175G is emitted from the light-emitting element 61G to the conductive layer 173 side. In the case where the light-emitting element 61B has a top-emission structure, light 175B is emitted from the light-emitting element 61B to the conductive layer 173 side.

An insulating layer 272 is provided to cover the end portion of the conductive layer 171 functioning as the pixel electrode. The end portion of the insulating layer 272 preferably has a tapered shape. For the insulating layer 272, one or both of an inorganic insulating film and an organic insulating film can be used.

The insulating layer 272 is provided to prevent an unintentional electric short-circuit between adjacent light-emitting elements and unintended light emission therefrom. In the case where a metal mask is used for formation of the EL layer, the insulating layer 272 also has a function of preventing the contact of the metal mask with the conductive layer 171.

The EL layer 172R, the EL layer 172G, and the EL layer 172B each include a region in contact with the top surface of the conductive layer 171 functioning as the pixel electrode and a region in contact with a surface of the insulating layer 272. The end portions of the EL layer 172R, the EL layer 172G, and the EL layer 172B are positioned over the insulating layer 272.

As illustrated in FIG. 24B, there is a gap between the two EL layers of the light-emitting elements with different emission colors. In this manner, the EL layer 172R, the EL layer 172G, and the EL layer 172B are preferably provided not to be in contact with each other. This can favorably prevent unintentional light emission (also referred to as crosstalk) due to a current flowing through two adjacent EL layers. As a result, the contrast can be increased, enabling the display device to have high display quality.

The EL layer 172R, the EL layer 172G, and the EL layer 172B can be formed separately by a vacuum evaporation method or the like using a shadow mask such as a metal mask. Alternatively, these layers may be formed separately by a photolithography method. The use of a photolithography method enables the display device to have a high resolution, which is difficult to achieve in the case of using a metal mask.

A protective layer 271 is provided over the conductive layer 173 functioning as the common electrode to cover the light-emitting element 61R, the light-emitting element 61G, and the light-emitting element 61B. The protective layer 271 has a function of preventing diffusion of impurities such as water into each light-emitting element from the above. For the material of the protective layer 271, the above-described material of the protective layer 631 can be referred to.

FIG. 24C illustrates a light-emitting element 61W emitting white light. The light-emitting element 61W includes an EL layer 172W emitting white light between the conductive layer 171 functioning as the pixel electrode and the conductive layer 173 functioning as the common electrode.

The EL layer 172W can have, for example, a structure in which two or more light-emitting layers that are selected such that their emission colors have a relationship of complementary colors are stacked. It is also possible to use a tandem EL layer in which a charge-generation layer is provided between light-emitting layers.

FIG. 24C illustrates three of the light-emitting elements 61W arranged side by side. A coloring layer 264R is provided above the left light-emitting element 61W. The coloring layer 264R functions as a band-pass filter transmitting red light. Similarly, a coloring layer 264G transmitting green light is provided above the middle light-emitting element 61W, and a coloring layer 264B transmitting blue light is provided above the right light-emitting element 61W. This enables the display device to display a color image.

Here, the EL layer 172W is separated between two of the light-emitting elements 61W adjacent to each other. This can prevent unintentional light emission due to a current flowing through the EL layers 172W of the two adjacent light-emitting elements 61W. Particularly when the EL layer 172W is a stacked EL layer in which a charge-generation layer is provided between two light-emitting layers, the effect of crosstalk becomes more significant as the resolution increases, i.e., as the distance between adjacent pixels decreases, leading to lower contrast. Thus, the above structure enables the display device to have both high resolution and high contrast.

The EL layers 172W are preferably separated by a photolithography method. This can reduce the distance between the light-emitting elements, enabling the display device to have a higher aperture ratio than that formed using, for example, a shadow mask such as a metal mask.

This embodiment can be combined with any of the other embodiments as appropriate.

### Embodiment 6

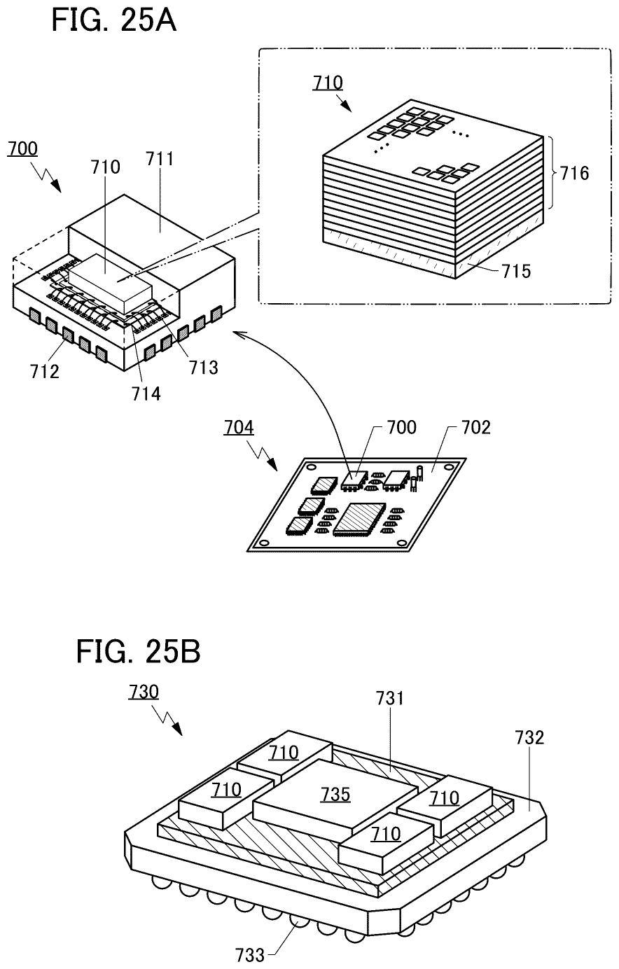

In this embodiment, application examples of the semiconductor device of one embodiment of the present invention are described with reference to FIG. 25 to FIG. 29.

The semiconductor device of one embodiment of the present invention can be used for an electronic component, a large computer, a device for space, a data center (also referred to as DC), and a variety of electronic appliances, for example. With the use of the semiconductor device of one embodiment of the present invention, an electronic component, a large computer, a device for space, a data center, and a variety of electronic appliances can have lower power consumption and higher performance.

A display device including the semiconductor device of one embodiment of the present invention can be used for a display portion of any of a variety of electronic appliances. The display device including the semiconductor device of one embodiment of the present invention can be easily increased in resolution and definition.

Examples of the electronic appliances include a digital camera, a digital video camera, a digital photo frame, a mobile phone, a portable game console, a portable information terminal, and an audio reproducing device, in addition to electronic appliances with a relatively large screen, such as a television device, desktop and notebook personal computers, a monitor of a computer and the like, digital signage, and a large game machine such as a pachinko machine.

In particular, the display device of one embodiment of the present invention can have a high resolution, and thus can be favorably used for an electronic appliance having a relatively small display portion. Examples of such an electronic appliance include watch-type and bracelet-type information terminal devices (wearable devices) and wearable devices capable of being worn on the head, such as a VR device like a head-mounted display, a glasses-type AR device, and an MR device.

The definition of the display device of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840× 2160), or 8K (number of pixels: 7680× 4320). In particular, a definition of 4K, 8K, or higher is preferable. The pixel density (resolution) of the display device of one embodiment of the present invention is preferably higher than or equal to 100 ppi, further preferably higher than or equal to 300 ppi, still further preferably higher than or equal to 500 ppi, yet still further preferably higher than or equal to 1000 ppi, yet still further preferably higher than or equal to 2000 ppi, yet still further preferably higher than or equal to 3000 ppi, yet still further preferably higher than or equal to 5000 ppi, yet still further preferably higher than or equal to 7000 ppi. The use of the display device having one or both of such a high definition and a high resolution can further increase realistic sensation, sense of depth, and the like. There is no particular limitation on the screen ratio (aspect ratio) of the display device of one embodiment of the present invention. For example, the display device is compatible with a variety of screen ratios such as 1:1 (a square), 4:3, 16:9, and 16:10.

The electronic appliance in this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic appliance in this embodiment can have a variety of functions. For example, the electronic appliance in this embodiment can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

### [Electronic Component]

FIG. 25A is a perspective view of a substrate (a mounting board 704) provided with an electronic component 700. The electronic component 700 illustrated in FIG. 25A includes a semiconductor device 710 in a mold 711. FIG. 25A omits some components to show the inside of the electronic component 700. The electronic component 700 includes a land 712 outside the mold 711. The land 712 is electrically connected to an electrode pad 713, and the electrode pad 713 is electrically connected to the semiconductor device 710 through a wire 714. The electronic component 700 is mounted on a printed circuit board 702, for example. A plurality of such electronic components are combined and electrically connected to each other on the printed circuit board 702, so that the mounting board 704 is completed.

The semiconductor device 710 includes a driver circuit layer 715 and a memory layer 716. The memory layer 716 has a structure where a plurality of memory cell arrays are stacked. A stacked-layer structure of the driver circuit layer 715 and the memory layer 716 can be a monolithic stacked-layer structure. In the monolithic stacked-layer structure, layers can be connected without using a through electrode technique such as a TSV (Through Silicon Via) and a bonding technique such as Cu—Cu direct bonding. Monolithically stacking the driver circuit layer 715 and the memory layer 716 enables, for example, what is called an on-chip memory structure where a memory is directly formed on a processor. The on-chip memory structure allows an interface portion between the processor and the memory to operate at high speed.

With the on-chip memory structure, the size of a connection wiring and the like can be made smaller than that when the technique using through electrodes such as TSVs is employed; thus, the number of connection pins can be increased. The increase in the number of connection pins enables parallel operations, which can improve the bandwidth of the memory (also referred to as a memory bandwidth).

It is preferable that the plurality of memory cell arrays included in the memory layer 716 be formed with OS transistors and be monolithically stacked. Monolithically stacking the plurality of memory cell arrays can improve one or both of a memory bandwidth and a memory access latency. Note that the bandwidth refers to the data transfer volume per unit time, and the access latency refers to a period of time from data access to the start of data transmission. Note that in the case where the memory layer 716 is formed with Si transistors, the monolithic stacked-layer structure is difficult to form compared with the case where the memory layer 716 is formed with OS transistors. Therefore, an OS transistor is superior to a Si transistor in the monolithic stacked-layer structure.

The semiconductor device 710 may be called a die. Note that in this specification and the like, a die refers to a chip obtained by, for example, forming a circuit pattern on a disc-like substrate (also referred to as a wafer) or the like and cutting the substrate with the pattern into dices in a process of manufacturing a semiconductor chip. Examples of semiconductor materials that can be used for the die include silicon (Si), silicon carbide (SiC), and gallium nitride (GaN). For example, a die obtained from a silicon substrate (also referred to as a silicon wafer) is referred to as a silicon die in some cases.

FIG. 25B is a perspective view of an electronic component 730. The electronic component 730 is an example of a SiP (System in Package) or an MCM (Multi Chip Module). In the electronic component 730, an interposer 731 is provided over a package substrate 732 (printed circuit board), and a semiconductor device 735 and a plurality of semiconductor devices 710 are provided over the interposer 731.

The electronic component 730 using the semiconductor device 710 as a high bandwidth memory (HBM) is illustrated as an example. The semiconductor device 735 can be used for an integrated circuit such as a CPU, a GPU, or an FPGA (Field Programmable Gate Array).

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. The plurality of wirings are provided in a single layer or multiple layers. In addition, the interposer 731 has a function of electrically connecting an integrated circuit provided on the interposer 731 to an electrode provided on the package substrate 732. Accordingly, the interposer is referred to as a “redistribution substrate” or an “intermediate substrate” in some cases. A through electrode may be provided in the interposer 731 to be used for electrically connecting the integrated circuit and the package substrate 732. In a silicon interposer, a TSV can also be used as the through electrode.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In a SiP, an MCM, or the like using a silicon interposer, a decrease in reliability due to a difference in the coefficient of expansion between an integrated circuit and the interposer is less likely to occur. Furthermore, a surface of a silicon interposer has high planarity; thus, poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

In the case where a plurality of integrated circuits with different terminal pitches are electrically connected using a silicon interposer, a TSV, and the like, a space for a width of the terminal pitch and the like is needed. Accordingly, in the case where the size of the electronic component 730 is to be reduced, the width of the terminal pitch becomes an issue, which sometimes makes it difficult to provide a large number of wirings for achieving a wide memory bandwidth. For this reason, the monolithic stacked-layer structure using the OS transistors is suitable, as described above. A composite structure where memory cell arrays stacked using a TSV and monolithically stacked memory cell arrays are combined may be employed.

In addition, a heat sink (a radiator plate) may be provided to overlap with the electronic component 730. In the case of providing a heat sink, the heights of integrated circuits provided on the interposer 731 are preferably equal to each other. For example, in the electronic component 730 described in this embodiment, the heights of the semiconductor devices 710 and the semiconductor device 735 are preferably equal to each other.

To mount the electronic component 730 on another substrate, an electrode 733 may be provided on the bottom part of the package substrate 732. In the example illustrated in FIG. 25B, the electrode 733 is formed of a solder ball. When the solder balls are provided in a matrix on the bottom part of the package substrate 732, BGA (Ball Grid Array) mounting can be achieved. Alternatively, the electrode 733 may be formed of a conductive pin. When the conductive pins are provided in a matrix on the bottom part of the package substrate 732, PGA (Pin Grid Array) mounting can be achieved.

The electronic component 730 can be mounted on another substrate by various mounting methods other than BGA and PGA. Examples of mounting methods include SPGA (Staggered Pin Grid Array), LGA (Land Grid Array), QFP (Quad Flat Package), QFJ (Quad Flat J-leaded package), and QFN (Quad Flat Non-leaded package).

### [Large Computer]

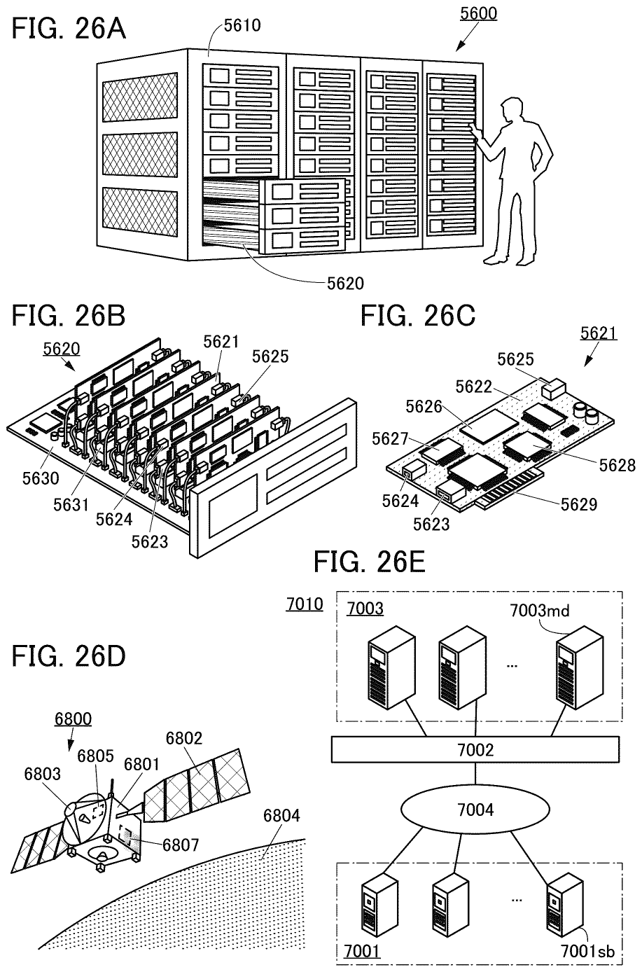

Next, FIG. 26A is a perspective view of a large computer 5600. In the large computer 5600 illustrated in FIG. 26A, a plurality of rack mount computers 5620 are stored in a rack 5610. Note that the large computer 5600 may be referred to as a supercomputer.

The computer 5620 can have a structure illustrated in a perspective view in FIG. 26B, for example. In FIG. 26B, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 26C is an example of a processing board provided with a CPU, a GPU, a memory device, and the like. The PC card 5621 includes a board 5622. The board 5622 includes a connection terminal 5623, a connection terminal 5624, a connection terminal 5625, a semiconductor device 5626, a semiconductor device 5627, a semiconductor device 5628, and a connection terminal 5629. Note that FIG. 26C also illustrates semiconductor devices other than the semiconductor device 5626, the semiconductor device 5627, and the semiconductor device 5628, and the following description of the semiconductor device 5626, the semiconductor device 5627, and the semiconductor device 5628 can be referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can each serve as, for example, an interface for performing power supply, signal input, or the like to the PC card 5621. For another example, they can each serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), and SCSI (Small Computer System Interface). In the case where video signals are output from the connection terminal 5623, the connection terminal 5624, and the connection terminal 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device or the like. As the semiconductor device 5628, the electronic component 700 can be used, for example.

The large computer 5600 can also function as a parallel computer. When the large computer 5600 is used as a parallel computer, large-scale computation necessary for artificial intelligence learning and inference can be performed, for example.

### [Device for Space]

The semiconductor device of one embodiment of the present invention can be suitably used as a device for space.

The semiconductor device of one embodiment of the present invention includes an OS transistor. A change in electrical characteristics of the OS transistor due to radiation irradiation is small. That is, the OS transistor is highly resistant to radiation, and thus can be suitably used in an environment where radiation can enter. For example, the OS transistor can be suitably used in outer space. Specifically, the OS transistor can be used as a transistor in a semiconductor device provided in a space shuttle, an artificial satellite, or a space probe. Examples of radiation include X-rays and a neutron beam. Note that although outer space refers to, for example, space at an altitude greater than or equal to 100 km, outer space described in this specification may include one or more of thermosphere, mesosphere, and stratosphere.

FIG. 26D illustrates an artificial satellite 6800 as an example of a device for space. The artificial satellite 6800 includes a body 6801, a solar panel 6802, an antenna 6803, a secondary battery 6805, and a control device 6807. In FIG. 26D, a planet 6804 in outer space is illustrated as an example.

Although not illustrated in FIG. 26D, a battery management system (also referred to as BMS) or a battery control circuit may be provided in the secondary battery 6805. The battery management system or the battery control circuit preferably includes the OS transistor, in which case low power consumption and high reliability are achieved even in outer space.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beam, proton beam, heavy-ion beams, and meson beams.

When the solar panel 6802 is irradiated with sunlight, electric power required for operation of the artificial satellite 6800 is generated. However, for example, in the situation where the solar panel is not irradiated with sunlight or the situation where the amount of sunlight with which the solar panel is irradiated is small, the amount of generated electric power is small. Accordingly, electric power required for the operation of the artificial satellite 6800 might not be generated. In order to operate the artificial satellite 6800 even in the situation where the amount of generated electric power is small, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a memory device, for example. Note that the semiconductor device including the OS transistor of one embodiment of the present invention is suitably used for the control device 6807. A change in electrical characteristics due to radiation irradiation is smaller in an OS transistor than in a Si transistor. Accordingly, the OS transistor has high reliability and thus can be suitably used even in an environment where radiation can enter.

The artificial satellite 6800 can include a sensor. For example, with a structure including a visible light sensor, the artificial satellite 6800 can have a function of detecting sunlight reflected by a ground-based object. Alternatively, with a structure including a thermal infrared sensor, the artificial satellite 6800 can have a function of detecting thermal infrared rays emitted from the surface of the earth. Thus, the artificial satellite 6800 can have a function of an earth observing satellite, for example.

Although the artificial satellite is described as an example of a device for space in this embodiment, one embodiment of the present invention is not limited to this example. The semiconductor device of one embodiment of the present invention can be suitably used for a device for space such as a spacecraft, a space capsule, or a space probe, for example.

As described above, an OS transistor has excellent effects of achieving a wide memory bandwidth and high radiation tolerance as compared with a Si transistor.

### [Data Center]

The semiconductor device of one embodiment of the present invention can be suitably used for, for example, a storage system employed in a data center or the like. Long-term management of data, such as guarantee of data immutability, is required for the data center. The long-term management of data needs an increase in building size for, for example, setting a storage and a server for storing an enormous amount of data, ensuring a stable power supply for data retention, or ensuring cooling equipment necessary for data retention.

With the use of the semiconductor device of one embodiment of the present invention for a storage system employed in a data center, electric power required for retaining data can be reduced and a semiconductor device for retaining data can be downsized. Accordingly, downsizing of the storage system, downsizing of the power supply for data retention, downscaling of the cooling equipment, and the like can be achieved. Therefore, space saving of the data center can be achieved.

Since the semiconductor device of one embodiment of the present invention has low power consumption, heat generation from a circuit can be reduced. Accordingly, adverse effects of the heat generation on the circuit itself, the peripheral circuit, and the module can be reduced. Furthermore, the use of the semiconductor device of one embodiment of the present invention can achieve a data center that operates stably even in a high temperature environment. Thus, the reliability of the data center can be increased.

FIG. 26E illustrates a storage system that can be used in a data center. A storage system 7010 illustrated in FIG. 26E includes a plurality of servers 7001sb as a host 7001 (indicated as “Host Computer” in the diagram). The storage system 7010 includes a plurality of memory devices 7003md as a storage 7003 (indicated as “Storage” in the diagram). In the illustrated mode, the host 7001 and the storage 7003 are connected to each other through a storage area network 7004 (indicated as “SAN” in the diagram) and a storage control circuit 7002 (indicated as “Storage Controller” in the diagram).

The host 7001 corresponds to a computer that accesses data stored in the storage 7003. The host 7001 may be connected to another host 7001 through a network.

The data access speed, i.e., the time taken for storing and outputting data, of the storage 7003 is shortened by using a flash memory, but is still considerably longer than the data access speed of a DRAM that can be used as a cache memory in a storage. In the storage system, in order to solve the problem of low access speed of the storage 7003, a cache memory is normally provided in the storage to shorten the time taken for data storage and output.

The above-described cache memory is used in the storage control circuit 7002 and the storage 7003. The data transmitted between the host 7001 and the storage 7003 is stored in the cache memories in the storage control circuit 7002 and the storage 7003 and then output to the host 7001 or the storage 7003.

With a structure in which an OS transistor is used as a transistor for storing data in the cache memory to retain a potential based on data, the frequency of refreshing can be reduced, so that power consumption can be reduced. Furthermore, downsizing is possible by stacking memory cell arrays.

### [Electronic Appliance]

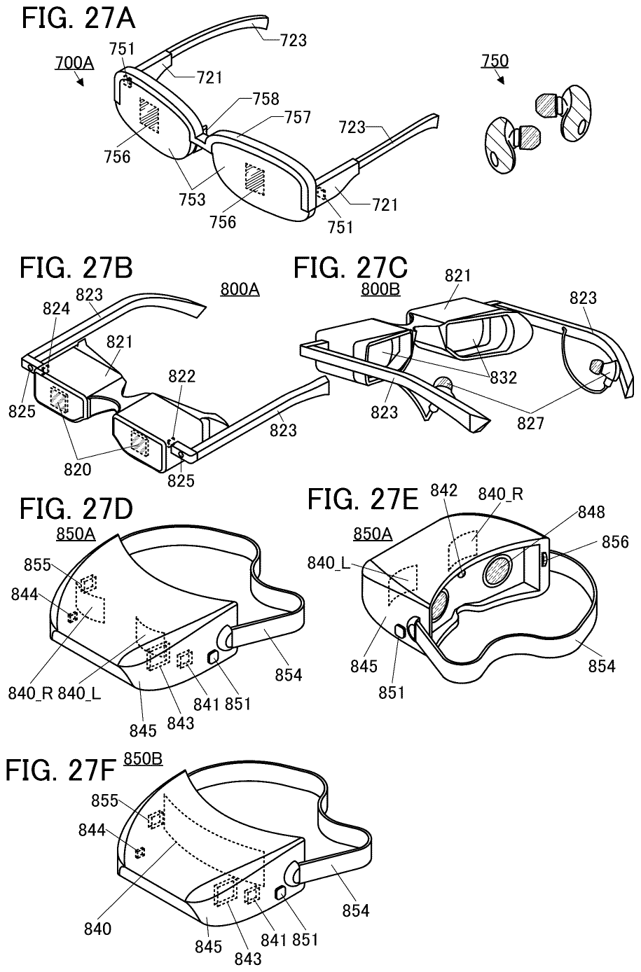

Examples of a wearable device that can be worn on a head are described with reference to FIG. 27A to FIG. 27F. These wearable devices have at least one of a function of displaying AR contents, a function of displaying VR contents, a function of displaying SR contents, and a function of displaying MR contents. The electronic appliance having a function of displaying contents of at least one of AR, VR, SR, MR, and the like enables the user to feel a higher level of immersion.

An electronic appliance 700A illustrated in FIG. 27A includes a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display device of one embodiment of the present invention can be used for the display panels 751. Thus, the electronic appliance is capable of performing ultrahigh-resolution display. The semiconductor device of one embodiment of the present invention can be used for the control portion (not illustrated). In that case, power consumption of the electronic appliance can be reduced.

The electronic appliance 700A can project images displayed on the display panels 751 onto display regions 756 of the optical members 753. Since the optical members 753 have a light-transmitting property, the user can see images displayed on the display regions, which are superimposed on transmission images seen through the optical members 753. Accordingly, the electronic appliance 700A is an electronic appliance capable of AR display.

In the electronic appliance 700A, a camera capable of capturing images of the front side may be provided as the image capturing portion. Furthermore, when the electronic appliance 700A is provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Instead of or in addition to the wireless communication device, a connector that can be connected to a cable for supplying a video signal and a power supply potential may be provided.

The electronic appliance 700A is provided with a battery, and charging can be performed wirelessly and/or by wire.

A touch sensor module may be provided in the housing 721. The touch sensor module has a function of detecting a touch on the outer surface of the housing 721. Detecting a tap operation, a slide operation, or the like by the user with the touch sensor module enables various types of processing. For example, a video can be paused or restarted by a tap operation, and can be fast-forwarded or fast-reversed by a slide operation. When the touch sensor module is provided in each of the two housings 721, the range of the operation can be increased.

An electronic appliance 800A illustrated in FIG. 27B and an electronic appliance 800B illustrated in FIG. 27C each include a pair of display portions 820, a housing 821, a communication portion 822, a pair of wearing portions 823, a control portion 824, a pair of image capturing portions 825, and a pair of lenses 832.

The display device of one embodiment of the present invention can be used for the display portions 820. Thus, the electronic appliances are capable of performing ultrahigh-resolution display. Such electronic appliances can provide a high sense of immersion to the user. The semiconductor device of one embodiment of the present invention can be used for the control portion 824. In that case, power consumption of the electronic appliance can be reduced.

The display portions 820 are positioned inside the housing 821 so as to be seen through the lenses 832. When the pair of display portions 820 display different images, three-dimensional display using parallax can be performed.

The electronic appliance 800A and the electronic appliance 800B can be regarded as electronic appliances for VR. The user wearing the electronic appliance 800A or the electronic appliance 800B can see images displayed on the display portions 820 through the lenses 832.

The electronic appliance 800A and the electronic appliance 800B preferably include a mechanism for adjusting the lateral positions of the lenses 832 and the display portions 820 so that the lenses 832 and the display portions 820 are positioned optimally in accordance with the positions of the user's eyes. Moreover, the electronic appliance 800A and the electronic appliance 800B preferably include a mechanism for adjusting focus by changing the distance between the lenses 832 and the display portions 820.

The electronic appliance 800A or the electronic appliance 800B can be worn on the user's head with the wearing portions 823. The wearing portion 823 has a shape like a temple of glasses in the examples illustrated in FIG. 27B and the like; however, one embodiment of the present invention is not limited thereto. The wearing portion 823 may have any shape with which the user can wear the electronic appliance, such as a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to cover a plurality of fields of view, such as a telescope field of view and a wide field of view.

Note that although an example where the image capturing portion 825 is included is described here, a range sensor that is capable of measuring the distance to an object (hereinafter such a sensor is also referred to as a sensing portion) is provided. In other words, the image capturing portion 825 is one embodiment of the sensing portion. As the sensing portion, an image sensor or a range image sensor such as LIDAR (Light Detection and Ranging) can be used, for example. By using images obtained by the camera and images obtained by the range image sensor, more information can be obtained and a gesture operation with higher accuracy is possible.

The electronic appliance 800A may include a vibration mechanism that functions as bone-conduction earphones. For example, one or more of the display portion 820, the housing 821, and the wearing portion 823 can include the vibration mechanism. Thus, without additionally requiring an audio device such as headphones, earphones, or a speaker, the user can enjoy images and sound only by wearing the electronic appliance 800A.

The electronic appliance 800A and the electronic appliance 800B may each include an input terminal. To the input terminal, a cable for supplying a video signal from a video output device or the like, power for charging the battery provided in the electronic appliance, and the like can be connected.

The electronic appliance of one embodiment of the present invention may have a function of performing wireless communication with earphones 750. The earphones 750 include a communication portion (not illustrated) and have a wireless communication function. The earphones 750 can receive information (e.g., audio data) from the electronic appliance with the wireless communication function. For example, the electronic appliance 700A illustrated in FIG. 27A has a function of transmitting information to the earphones 750 with the wireless communication function.

The electronic appliance may include an earphone portion. The electronic appliance 800B illustrated in FIG. 27C includes earphone portions 827. For example, the earphone portion 827 can be connected to the control portion 824 by wire. Part of a wiring that connects the earphone portion 827 and the control portion 824 may be positioned inside the housing 821 or the wearing portion 823. Alternatively, the earphone portions 827 and the wearing portions 823 may include magnets. This structure is preferably employed, in which case the earphone portions 827 can be fixed to the wearing portions 823 with magnetic force and thus can be easily housed.

The electronic appliance may include an audio output terminal to which earphones, headphones, or the like can be connected. The electronic appliance may include one or both of an audio input terminal and an audio input mechanism. As the audio input mechanism, a sound collecting device such as a microphone can be used, for example. The electronic appliance may have a function of what is called a headset by including the audio input mechanism.

FIG. 27D and FIG. 27E are perspective views of a goggles-type electronic appliance 850A for VR. FIG. 27D and FIG. 27E illustrate an example where a housing 845 includes a pair of curved display devices 840 (a display device 840_R and a display device 840_L). The electronic appliance 850A includes a motion detection portion 841, an eye-gaze detection portion 842, an arithmetic portion 843, a communication portion 844, lenses 848, an operation button 851, a wearing tool 854, a sensor 855, a dial 856, and the like.

When the two display devices 840 are provided, the user's eyes can see the respective display devices. This allows a high-definition image to be displayed even when three-dimensional display using parallax or the like is performed. In addition, the display device 840 is curved around an arc with the user's eye as an approximate center. This keeps a certain distance between the user's eye and the display surface of the display device 840, enabling the user to see a more natural image. Even when having what is called viewing angle dependence where the luminance or chromaticity of light changes depending on the viewing angle, the display device 840 can have a structure where the user's eye is positioned in the normal direction of the display surface of the display device 840; accordingly, the influence of the viewing angle dependence particularly in the horizontal direction can be practically ignored, enabling display of a more realistic image.

As illustrated in FIG. 27E, the lenses 848 are positioned between the display devices 840 and the user's eyes. In the example illustrate in FIG. 27E, the dial 856 for changing the positions of the lenses for visibility adjustment is provided. Note that in the case where the electronic appliance 850A has an autofocus function, the dial 856 for visibility adjustment is not necessarily provided.

FIG. 27F illustrates a goggles-type electronic appliance 850B including one display device 840. Such a structure can reduce the number of components.

The display device 840 can display an image for the right eye and an image for the left eye side by side on a right region and a left region, respectively. Thus, a three-dimensional image using binocular parallax can be displayed. Note that the display device 840 may display two different images side by side using parallax, or may display two same images side by side without using parallax.

One image that can be seen by both eyes may be displayed on the entire display device 840. In that case, a panorama image can be displayed from end to end of the field of view, which can provide a stronger sense of reality.

The display device of one embodiment of the present invention can be used as the display device 840. The display device of one embodiment of the present invention has an extremely high resolution; thus, even when an image is magnified using the lenses 848, the pixels are not seen by the user, and thus a more realistic image can be displayed.

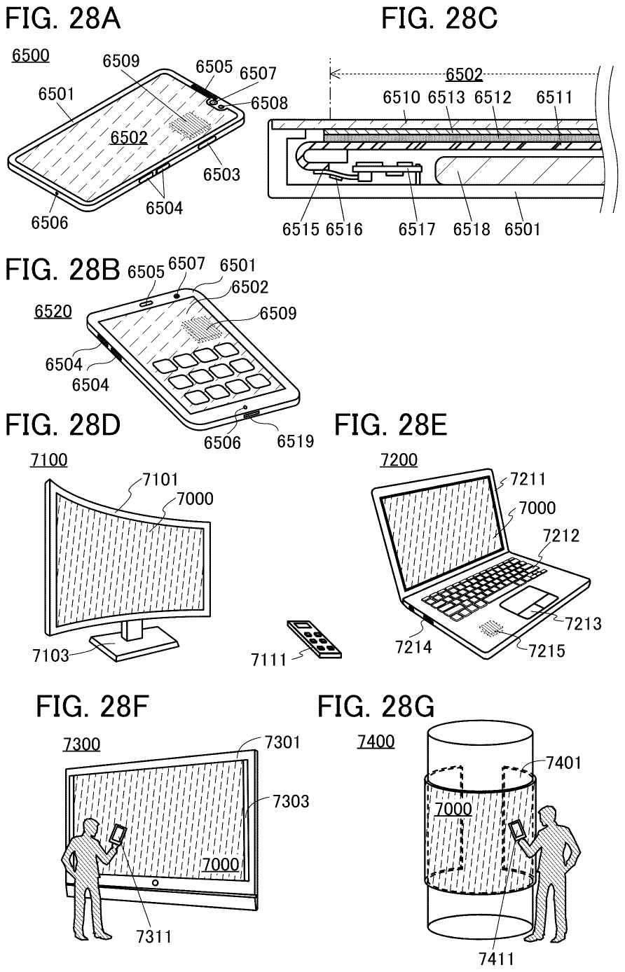

An electronic appliance 6500 illustrated in FIG. 28A is a portable information terminal that can be used as a smartphone.

The electronic appliance 6500 includes a housing 6501, a display portion 6502, a power button 6503, buttons 6504, a speaker 6505, a microphone 6506, a camera 6507, a light source 6508, a control device 6509, and the like.

An electronic appliance 6520 illustrated in FIG. 28B is a portable information terminal that can be used as a tablet terminal.

The electronic appliance 6520 includes the housing 6501, the display portion 6502, the buttons 6504, the speaker 6505, the microphone 6506, the camera 6507, the control device 6509, a connection terminal 6519, and the like.

In each of the electronic appliance 6500 and the electronic appliance 6520, the display portion 6502 has a touch panel function. The control device 6509 includes, for example, one or more selected from a CPU, a GPU, and a memory device. The semiconductor device of one embodiment of the present invention can be used for one or both of the display portion 6502 and the control device 6509.

FIG. 28C is a schematic cross-sectional view including the end portion of the housing 6501 of the electronic appliance 6500 or the electronic appliance 6520 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display panel 6511. In that case, an extremely lightweight electronic appliance can be obtained. Since the display panel 6511 is extremely thin, the battery 6518 with a high capacity can be mounted without an increase in the thickness of the electronic appliance. An electronic appliance with a narrow bezel can be obtained when part of the display panel 6511 is folded back so that the portion connected to the FPC 6515 is provided on the back side of a pixel portion.

FIG. 28D illustrates an example of a television device. In a television device 7100, a display portion 7000 is incorporated in a housing 7101. Here, the housing 7101 is supported by a stand 7103.

The display device of one embodiment of the present invention can be used for the display portion 7000.

Operation of the television device 7100 illustrated in FIG. 28D can be performed with an operation switch provided in the housing 7101 and a separate remote control 7111. Alternatively, the display portion 7000 may include a touch sensor, and the television device 7100 may be operated by touch on the display portion 7000 with a finger or the like. The remote control 7111 may be provided with a display portion for displaying information output from the remote control 7111. With operation keys or a touch panel provided in the remote control 7111, channels and volume can be controlled and images displayed on the display portion 7000 can be controlled.

Note that the television device 7100 includes a receiver, a modem, and the like. A general television broadcast can be received with the receiver. When the television device is connected to a communication network by wire or wirelessly via the modem, one-way (from a transmitter to a receiver) or two-way (between a transmitter and a receiver or between receivers, for example) data communication can be performed.

FIG. 28E illustrates an example of a notebook personal computer. The notebook personal computer 7200 includes a housing 7211, a keyboard 7212, a pointing device 7213, an external connection port 7214, a control device 7215, and the like. The display portion 7000 is incorporated in the housing 7211. The control device 7215 includes, for example, one or more selected from a CPU, a GPU, and a memory device. The semiconductor device of one embodiment of the present invention can be used for one or both of the display portion 7000 and the control device 7215.

FIG. 28F and FIG. 28G illustrate examples of digital signage.

Digital signage 7300 illustrated in FIG. 28F includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 28G is digital signage 7400 attached to a cylindrical pillar 7401. The digital signage 7400 includes the display portion 7000 provided along a curved surface of the pillar 7401.

The display device of one embodiment of the present invention can be used for the display portion 7000 illustrated in each of FIG. 28F and FIG. 28G.

The larger display portion 7000 can provide a larger amount of information at a time. The larger display portion 7000 attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIG. 28F and FIG. 28G, it is preferable that the digital signage 7300 or the digital signage 7400 can work with an information terminal 7311 or an information terminal 7411, such as a smartphone of a user, through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with the use of the screen of the information terminal 7311 or the information terminal 7411 as an operation means (controller). Thus, an unspecified number of users can join in and enjoy the game concurrently.

The semiconductor device and the display device of embodiments of the present invention can be used around a driver's seat in a car, which is a vehicle.

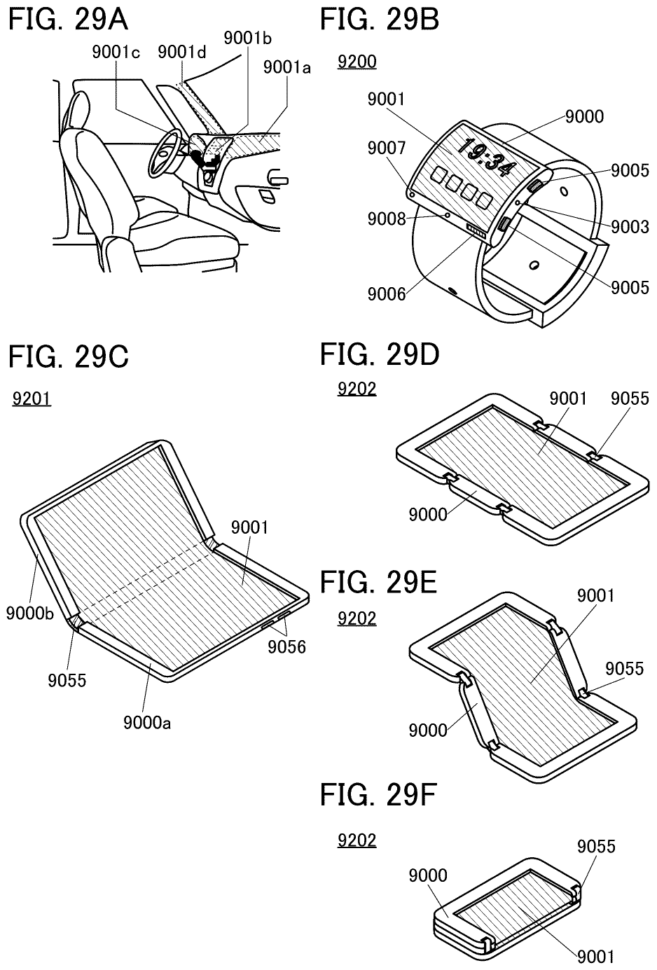

FIG. 29A illustrates the vicinity of a windshield inside a car. FIG. 29A illustrates a display panel 9001a, a display panel 9001b, and a display panel 9001c attached to a dashboard and a display panel 9001d attached to a pillar.

The display panel 9001a to the display panel 9001c can provide various kinds of information by displaying navigation information, a speedometer, a tachometer, a mileage, a fuel meter, a gearshift state, air-conditioning settings, and the like. Items displayed on the display panel, their layout, and the like can be changed as appropriate to suit the user's preferences, resulting in more sophisticated design. The display panel 9001a to the display panel 9001c can also be used as lighting devices.

The display panel 9001d can compensate for the view hindered by the pillar (blind areas) by displaying an image taken by an image capturing means provided for the car body. That is, displaying an image taken by the image capturing means provided on the outside of the car body leads to elimination of blind areas and enhancement of safety. Moreover, showing an image to compensate for the area that a driver cannot see makes it possible for the driver to confirm safety more easily and comfortably. The display panel 9001d can also be used as a lighting device.

FIG. 29B is a perspective view of a watch-type portable information terminal 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With a connection terminal 9006, the portable information terminal 9200 can perform mutual data transmission with another information terminal and charging. Note that the charging operation may be performed by wireless power feeding.

The portable information terminal 9200 illustrated in FIG. 29B includes a housing 9000, the display portion 9001, a speaker 9003, an operation key 9005 (including a power switch or an operation switch), the connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like. FIG. 29C is a perspective view of a foldable portable information terminal 9201. The portable information terminal 9201 includes a housing 9000a, a housing 9000b, the display portion 9001, and operation buttons 9056.

The housing 9000a and the housing 9000b are connected to each other with a hinge 9055, and the hinge 9055 enables folding in half.

The display portion 9001 of the portable information terminal 9201 is supported by two housings (the housing 9000a and the housing 9000b) joined together with the hinge 9055.

FIG. 29D to FIG. 29F are perspective views illustrating a foldable portable information terminal 9202. FIG. 29D is a perspective view of an opened state of the portable information terminal 9202, FIG. 29F is a perspective view of a folded state thereof, and FIG. 29E is a perspective view of a state in the middle of change from one of FIG. 29D and FIG. 29F to the other. In this manner, the portable information terminal 9202 can be folded in three.

The display portion 9001 of the portable information terminal 9202 is supported by three housings 9000 joined together with the hinges 9055.

In FIG. 29C to FIG. 29F, the display device of one embodiment of the present invention can be used for the display portion 9001. The display portion 9001 can be folded with a radius of curvature greater than or equal to 0.1 mm and less than or equal to 150 mm, for example.

The portable information terminal 9201 and the portable information terminal 9202 are each highly portable in the folded state and are each highly browsable in the opened state because of a seamless large display region.

The use of the semiconductor device of one embodiment of the present invention for one or more selected from an electronic component, a large computer, a device for space, a data center, and an electronic appliance can reduce power consumption. While the demand for energy is expected to increase with higher performance or higher integration of semiconductor devices, the emission amount of greenhouse effect gases typified by carbon dioxide (CO₂) can be reduced with the use of the semiconductor device of one embodiment of the present invention. Furthermore, the semiconductor device of one embodiment of the present invention has low power consumption and thus is effective as a global warming countermeasure.

This embodiment can be combined with any of the other embodiments as appropriate.

### REFERENCE NUMERALS

ADDR: signal, BIL: wiring, BILB: wiring, BRL: wiring, BW: signal, CA: capacitor, CAL: wiring, CB: capacitor, CC: capacitor, CE: signal, CLK: signal, D: width, GNDL: wiring, GW: signal, M10: transistor, MPG: conductive layer, MTCK: transistor, RBL: wiring, RDA: signal, RWL: wiring, SL: wiring, VDL: wiring, WAKE: signal, WBL: wiring, WDA: signal, WOL: wiring, 61B: light-emitting element, 61G: light-emitting element, 61R: light-emitting element, 61 W: light-emitting element, 100a: capacitor, 100b: capacitor, 100: capacitor, 110: conductive layer, 115: conductive layer, 120: conductive layer, 130B: subpixel, 130G: subpixel, 130R: subpixel, 130: insulating layer, 140: insulating layer, 150a: memory cell, 150b: memory cell, 150c: memory cell, 150d: memory cell, 150: memory cell, 160: memory layer, 170: display module, 171: conductive layer, 172B: EL layer, 172G: EL layer, 172R: EL layer, 172W: EL layer, 173: conductive layer, 175B: light, 175G: light, 175R: light, 180: insulating layer, 190: opening, 200: transistor, 200a: transistor, 200b: transistor, 210: insulating layer, 220a: conductive layer, 220b: conductive layer, 220c: conductive layer, 220k: conductive layer, 220: conductive layer, 222: insulating layer, 230a: oxide layer, 230b: oxide layer, 230c: oxide layer, 230k: oxide semiconductor layer, 230: oxide semiconductor layer, 240a: conductive layer, 240b: conductive layer, 240k: conductive layer, 240: conductive layer, 245: conductive layer, 246: conductive layer, 247: conductive layer, 248: conductive layer, 250a: insulating layer, 250b: insulating layer, 250k: insulating layer, 250: insulating layer, 260a: conductive layer, 260ae: conductive layer, 260af: conductive layer, 260b: conductive layer, 260bf: conductive layer, 260k: conductive layer, 260: conductive layer, 264B: coloring layer, 264G: coloring layer, 264R: coloring layer, 271: protective layer, 272: insulating layer, 277: region, 278: mask, 280a: insulating layer, 280b: insulating layer, 280c: insulating layer, 280: insulating layer, 283: insulating layer, 285: insulating layer, 290a: opening, 290b: opening, 290: opening, 291: substrate, 292: circuit portion, 293a: pixel circuit, 293: pixel circuit portion, 294a: pixel, 294: pixel portion, 295: terminal portion, 296: wiring portion, 297: display portion, 298: FPC, 299: substrate, 300: transistor, 311: substrate, 313: semiconductor region, 314a: low-resistance region, 314b: low-resistance region, 315: insulating layer, 316: conductive layer, 320: insulating layer, 322: insulating layer, 324: insulating layer, 326: insulating layer, 328: conductive layer, 330: conductive layer, 350: insulating layer, 352: insulating layer, 354: insulating layer, 356: conductive layer, 363: insulating layer, 400d: transistor, 410: substrate, 412: element isolation layer, 413: semiconductor region, 414a: low-resistance region, 414b: low-resistance region, 415: insulating layer, 416: conductive layer, 417: insulating layer, 420: insulating layer, 422: insulating layer, 424: insulating layer, 426: insulating layer, 428: conductive layer, 430: conductive layer, 450: insulating layer, 452: insulating layer, 454: insulating layer, 456: conductive layer, 513: insulating layer, 514: conductive layer, 541: substrate, 543: adhesive layer, 545: insulating layer, 574: insulating layer, 581: insulating layer, 592: insulating layer, 594: insulating layer, 596: conductive layer, 598: insulating layer, 599: insulating layer, 600A: display device, 600B: display device, 607: adhesive layer, 610: substrate, 611a: conductive layer, 611b: conductive layer, 611c: conductive layer, 613a: layer, 613b: layer, 613c: layer, 614: common layer, 615: common electrode, 618a: sacrificial layer, 620: element layer, 625: insulating layer, 627: insulating layer, 628B: coloring layer, 628G: coloring layer, 628R: coloring layer, 630: element layer, 631: protective layer, 635: element layer, 640: connection portion, 641: insulating layer, 642: conductive layer, 643: conductive layer, 644: conductive layer, 645: conductive layer, 646: conductive layer, 647: insulating layer, 648: insulating layer, 650B: light-emitting element, 650G: light-emitting element, 650R: light-emitting element, 650: light-emitting element, 660: element layer, 670: wiring layer, 700A: electronic appliance, 700: electronic component, 702: printed circuit board, 704: mounting board, 710: semiconductor device, 711: mold, 712: land, 713: electrode pad, 714: wire, 715: driver circuit layer, 716: memory layer, 721: housing, 723: wearing portion, 730: electronic component, 731: interposer, 732: package substrate, 733: electrode, 735: semiconductor device, 750: earphone, 751: display panel, 753: optical member, 756: display region, 757: frame, 758: nose pad, 800A: electronic appliance, 800B: electronic appliance, 820: display portion, 821: housing, 822: communication portion, 823: wearing portion, 824: control portion, 825: image capturing portion, 827: earphone portion, 832: lens, 840_L: display device, 840_R: display device, 840: display device, 841: motion detection portion, 842: gaze detection portion, 843: arithmetic portion, 844: communication portion, 845: housing, 848: lens, 850A: electronic appliance, 850B: electronic appliance, 851: operation button, 854: wearing tool, 855: sensor, 856: dial, 900: semiconductor device, 910: driver circuit, 911: peripheral circuit, 912: control circuit, 915: peripheral circuit, 920: memory array, 923: row driver, 924: column driver, 925: input circuit, 926: output circuit, 927: sense amplifier, 928: voltage generation circuit, 930: layer, 931: PSW, 932: PSW, 941: row decoder, 942: column decoder, 950: memory cell, 951: memory cell, 952: memory cell, 953: memory cell, 954: memory cell, 955: memory cell, 956: memory cell, 957: memory cell, 958: memory cell, 960: arithmetic device, 970A: semiconductor device, 970B: semiconductor device, 970C: semiconductor device, 989: cache interface, 990: substrate, 991: ALU, 992: ALU controller, 993: instruction decoder, 994: interrupt controller, 995: timing controller, 996: register, 997: register controller, 998: bus interface, 999: cache, 5600: large computer, 5610: rack, 5620: computer, 5621: PC card, 5622: board, 5623: connection terminal, 5624: connection terminal, 5625: connection terminal, 5626: semiconductor device, 5627: semiconductor device, 5628: semiconductor device, 5629: connection terminal, 5630: motherboard, 5631: slot, 6500: electronic appliance, 6501: housing, 6502: display portion, 6503: power button, 6504: button, 6505: speaker, 6506: microphone, 6507: camera, 6508: light source, 6509: control device, 6510: protection member, 6511: display panel, 6512: optical member, 6513: touch sensor panel, 6515: FPC, 6516: IC, 6517: printed circuit board, 6518: battery, 6519: connection terminal, 6520: electronic appliance, 6800: artificial satellite, 6801: body, 6802: solar panel, 6803: antenna, 6804: planet, 6805: secondary battery, 6807: control device, 7000: display portion, 7001sb: server, 7001: host, 7002: storage control circuit, 7003md: memory device, 7003: storage, 7010: storage system, 7100: television device, 7101: housing, 7103: stand, 7111: remote control, 7200: notebook personal computer, 7211: housing, 7212: keyboard, 7213: pointing device, 7214: external connection port, 7215: control device, 7300: digital signage, 7301: housing, 7303: speaker, 7311: information terminal, 7400: digital signage, 7401: pillar, 7411: information terminal, 9000a: housing, 9000b: housing, 9000: housing, 9001a: display panel, 9001b: display panel, 9001c: display panel, 9001d: display panel, 9001: display portion, 9003: speaker, 9005: operation key, 9006: connection terminal, 9007: sensor, 9008: microphone, 9055: hinge, 9056: operation button, 9200: portable information terminal, 9201: portable information terminal, 9202: portable information terminal

1. A semiconductor device comprising:
a first transistor and a first insulating layer,
wherein the first transistor comprises a first conductive layer, a second conductive layer, a semiconductor layer, a gate insulating layer, and a gate electrode,
wherein the first conductive layer is one of a source electrode and a drain electrode of the first transistor,
wherein the second conductive layer is the other of the source electrode and the drain electrode of the first transistor,
wherein the first conductive layer and the second conductive layer are positioned at different levels,
wherein the first insulating layer is between the first conductive layer and the second conductive layer,
wherein the first insulating layer comprises a first opening reaching the first conductive layer,
wherein the second conductive layer comprises a second opening overlapping with the first opening,
wherein the second conductive layer is over the first insulating layer,
wherein the semiconductor layer comprises a region in contact with a top surface of the first conductive layer in the first opening, a region in contact with a side surface of the first insulating layer in the first opening, a region in contact with a side surface of the second conductive layer in the second opening, and a region in contact with a top surface of the second conductive layer,
wherein the gate insulating layer is over and in contact with the semiconductor layer,
wherein the gate electrode is over the gate insulating layer,
wherein the gate electrode and the semiconductor layer overlap each other,
wherein the gate electrode comprises a third conductive layer and a fourth conductive layer over the third conductive layer,
wherein an end portion of the third conductive layer and the second conductive layer overlap each other,
wherein the fourth conductive layer comprises a region extending outward from the end portion of the third conductive layer, and
wherein in the region extending outward from the end portion of the third conductive layer, the fourth conductive layer comprises a gap between the region and the second conductive layer.

2. The semiconductor device according to claim 1, wherein a relative permittivity of the gap is higher than or equal to 0.8 and lower than or equal to 1.2.

3. A semiconductor device comprising:
a first transistor, a first insulating layer, and a second insulating layer,
wherein the first transistor comprises a first conductive layer, a second conductive layer, a semiconductor layer, a gate insulating layer, and a gate electrode,
wherein the first conductive layer is one of a source electrode and a drain electrode of the first transistor,
wherein the second conductive layer is the other of the source electrode and the drain electrode of the first transistor,
wherein the first conductive layer and the second conductive layer are positioned at different levels,
wherein the first insulating layer is between the first conductive layer and the second conductive layer,
wherein the first insulating layer comprises a first opening reaching the first conductive layer,
wherein the second conductive layer comprises a second opening overlapping with the first opening,
wherein the second conductive layer is over the first insulating layer,
wherein the semiconductor layer comprises a region in contact with a top surface of the first conductive layer in the first opening, a region in contact with a side surface of the first insulating layer in the first opening, a region in contact with a side surface of the second conductive layer in the second opening, and a region in contact with a top surface of the second conductive layer,
wherein the gate insulating layer is over and in contact with the semiconductor layer,
wherein the gate electrode is over the gate insulating layer,
wherein the gate electrode and the semiconductor layer overlap each other,
wherein the gate electrode comprises a third conductive layer and a fourth conductive layer over the third conductive layer,
wherein an end portion of the third conductive layer and the second conductive layer overlap each other,
wherein the fourth conductive layer comprises a region extending outward from the end portion of the third conductive layer,
wherein the second insulating layer covers a top surface and a side surface of the fourth conductive layer, and
wherein in the region where the fourth conductive layer extends outward from the end portion of the third conductive layer, the second insulating layer comprises a region covering a bottom surface of the fourth conductive layer.

4. The semiconductor device according to claim 3,
wherein in the region extending outward from the end portion of the third conductive layer, the fourth conductive layer comprises the second insulating layer between the region and the second conductive layer.

5. The semiconductor device according to claim 1, wherein the third conductive layer is one selected from tantalum nitride, titanium nitride, ruthenium nitride, a nitride comprising molybdenum, a nitride comprising tungsten, titanium, and aluminum, and a nitride comprising tantalum and aluminum.

6. The semiconductor device according to claim 1,
wherein the third conductive layer is one selected from tantalum nitride, titanium nitride, ruthenium nitride, a nitride comprising molybdenum, a nitride comprising tungsten, titanium, and aluminum, and a nitride comprising tantalum and aluminum, and
wherein the fourth conductive layer is tungsten.

7. A method for manufacturing a semiconductor device, the method comprising the steps of:
forming a first insulating layer over a first conductive layer;
forming a second conductive layer over the first insulating layer;
removing a part of the second conductive layer and part of the first insulating layer to form a first opening reaching the first conductive layer and to expose a top surface of the first conductive layer;
forming a first semiconductor layer in contact with the top surface of the first conductive layer, a side surface of the first insulating layer in the first opening, a side surface of the second conductive layer in the first opening, and a top surface of the second conductive layer;
forming a second insulating layer in contact with a top surface of the first semiconductor layer and a top surface of the first insulating layer;
forming a third conductive layer and a fourth conductive layer sequentially over the second insulating layer to stack the third conductive layer and the fourth conductive layer;
forming a first mask by a photolithography method and removing a part of the fourth conductive layer with the first mask to form a fifth conductive layer; and
removing a part of the third conductive layer with the fifth conductive layer as a mask to form a sixth conductive layer,
wherein the part of the third conductive layer is removed by wet etching, and
wherein the part of the fourth conductive layer is removed by dry etching.

8. The method for manufacturing the semiconductor device, according to claim 7,
wherein when the part of the third conductive layer is removed, a region extending outward from an end portion of the sixth conductive layer is formed in the fifth conductive layer,
wherein after the sixth conductive layer is formed, a third insulating layer is formed in contact with a top surface of the fifth conductive layer, a side surface of the fifth conductive layer, and a top surface of the second insulating layer, and
wherein in the region where the fifth conductive layer extends outward from the end portion of the sixth conductive layer, the third insulating layer is provided to comprise a region in contact with a bottom surface of the fifth conductive layer.

9. The semiconductor device according to claim 3, wherein the third conductive layer is one selected from tantalum nitride, titanium nitride, ruthenium nitride, a nitride comprising molybdenum, a nitride comprising tungsten, titanium, and aluminum, and a nitride comprising tantalum and aluminum.

10. The semiconductor device according to claim 3,
wherein the third conductive layer is one selected from tantalum nitride, titanium nitride, ruthenium nitride, a nitride comprising molybdenum, a nitride comprising tungsten, titanium, and aluminum, and a nitride comprising tantalum and aluminum, and
wherein the fourth conductive layer is tungsten.
